(19) United States
(12) Patent Application Publication
(10) Pub. No.: US 2026/0130112 A1
(43) Pub. Date: May 7, 2026

(54) ORGANIC ELECTROLUMINESCENT DEVICE

(71) Applicant: BEIJING SUMMER SPROUT TECHNOLOGY CO., LTD., Beijing (CN)

(72) Inventors: Chunliang Zhao, Beijing (CN); Liuhuan Cai, Beijing (CN); Xuechao Tian, Beijing (CN); Ming Sang, Beijing (CN); Chi Yuen Raymond Kwong, Beijing (CN); Chuanjun Xia, Beijing (CN)

(73) Assignee: BEIJING SUMMER SPROUT TECHNOLOGY CO., LTD., Beijing (CN)

(21) Appl. No.: 19/339,977

(22) Filed: Sep. 25, 2025

(30) Foreign Application Priority Data
Sep. 25, 2024 (CN) 202411344500.7

(51) Int. Cl. H10K 85/60; C09K 11/06; H10K 50/11; H10K 85/30; H10K 101/00; H10K 101/20

(52) U.S. Cl. CPC H10K 85/658; C09K 11/06; H10K 85/346; H10K 85/6572; C09K 2211/1007; C09K 2211/1014; C09K 2211/1018; C09K 2211/1022; C09K 2211/1029; C09K 2211/1044; C09K 2211/185; H10K 50/11; H10K 2101/20; H10K 2101/90

(57) ABSTRACT

Provided is an organic electroluminescent device. The organic electroluminescent device has an organic layer comprising at least a fluorescent material and a metal complex. The fluorescent material has a structure represented by Formula 1, and the metal complex comprises a ligand with a structure represented by Formula 2. The organic electroluminescent device uses a phosphorescent material to sensitize the fluorescent material so that the prepared organic electroluminescent device has a narrower full width at half maximum and higher efficiency. Further provided is a display apparatus comprising the organic electroluminescent device.

### CROSS-REFERENCE TO RELATED APPLICATION(S)

This application claims priority to Chinese Patent Application No. 202411344500.7 filed on Sep. 25, 2024, the disclosure of which is incorporated herein by reference in its entirety.

### TECHNICAL FIELD

The present disclosure relates to organic electronic devices, for example, organic electroluminescent devices. More particularly, the present disclosure relates to an organic electroluminescent device with an organic layer comprising at least a metal complex and a fluorescent material.

### BACKGROUND

Organic electronic devices include, but are not limited to, the following types: organic light-emitting diodes (OLEDs), organic field-effect transistors (O-FETs), organic light-emitting transistors (OLETs), organic photovoltaic devices (OPVs), dye-sensitized solar cells (DSSCs), organic optical detectors, organic photoreceptors, organic field-quench devices (OFQDs), light-emitting electrochemical cells (LECs), organic laser diodes and organic plasmon emitting devices.

In 1987, Tang and Van Slyke of Eastman Kodak reported a bilayer organic electroluminescent device, which comprises an arylamine hole transporting layer and a tris-8-hydroxyquinolato-aluminum layer as the electron and emitting layer (Applied Physics Letters, 1987, 51 (12): 913-915). Once a bias is applied to the device, green light was emitted from the device. This device laid the foundation for the development of modern organic light-emitting diodes (OLEDs). State-of-the-art OLEDs may comprise multiple layers such as charge injection and transporting layers, charge and exciton blocking layers, and one or multiple emissive layers between the cathode and anode. Since the OLED is a self-emitting solid state device, it offers tremendous potential for display and lighting applications. In addition, the inherent properties of organic materials, such as their flexibility, may make them well suited for particular applications such as fabrication on flexible substrates.

The OLED can be categorized as three different types according to its emitting mechanism. The OLED invented by Tang and van Slyke is a fluorescent OLED. It only utilizes singlet emission. The triplets generated in the device are wasted through nonradiative decay channels. Therefore, the internal quantum efficiency (IQE) of the fluorescent OLED is only 25%. This limitation hindered the commercialization of OLED. In 1997, Forrest and Thompson reported phosphorescent OLED, which uses triplet emission from heavy metal containing complexes as the emitter. As a result, both singlet and triplets can be harvested, achieving 100% IQE. The discovery and development of phosphorescent OLED contributed directly to the commercialization of active-matrix OLED (AMOLED) due to its high efficiency. Recently, Adachi achieved high efficiency through thermally activated delayed fluorescence (TADF) of organic compounds. These emitters have small singlet-triplet gap that makes the transition from triplet back to singlet possible. In the TADF device, the triplet excitons can go through reverse intersystem crossing to generate singlet excitons, resulting in high IQE.

OLEDs can also be classified as small molecule and polymer OLEDs according to the forms of the materials used. A small molecule refers to any organic or organometallic material that is not a polymer. The molecular weight of the small molecule can be large as long as it has well defined structure. Dendrimers with well-defined structures are considered as small molecules. Polymer OLEDs include conjugated polymers and non-conjugated polymers with pendant emitting groups. Small molecule OLED can become the polymer OLED if post polymerization occurred during the fabrication process.

There are various methods for OLED fabrication. Small molecule OLEDs are generally fabricated by vacuum thermal evaporation. Polymer OLEDs are fabricated by solution process such as spin-coating, inkjet printing, and slit printing. If the material can be dissolved or dispersed in a solvent, the small molecule OLED can also be produced by solution process.

The emitting color of the OLED can be achieved by emitter structural design. An OLED may comprise one emitting layer or a plurality of emitting layers to achieve desired spectrum. In the case of green, yellow, and red OLEDs, phosphorescent emitters have successfully reached commercialization. Blue phosphorescent device still suffers from non-saturated blue color, short device lifetime, and high operating voltage. Commercial full-color OLED displays normally adopt a hybrid strategy, using fluorescent blue and phosphorescent yellow, or red and green. At present, efficiency roll-off of phosphorescent OLEDs at high brightness remains a problem. In addition, it is desirable to have more saturated emitting color, higher efficiency, and longer device lifetime.

WO2020251049A1 has disclosed a fused ring compound having a general formula of

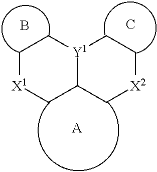

and further disclosed a secondary general formula of

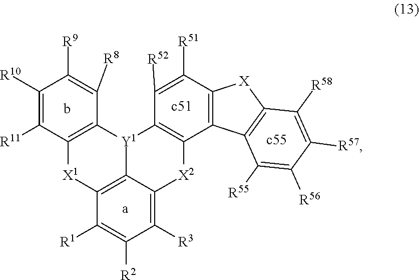

wherein X is selected from —O—, —S—, —Se—, —Te—, —NR, —Si(—R)₂, or —C(—R)₂, Y¹ is selected from B, P, P═O, P═S, Al, Si—R, or Ge—R, and X¹ and X² are each independently selected from —O—, —S—, —Se—, —NR, —Si(—R)₂, or —C(—R)₂. As for specific structures, this application has disclosed compounds such as

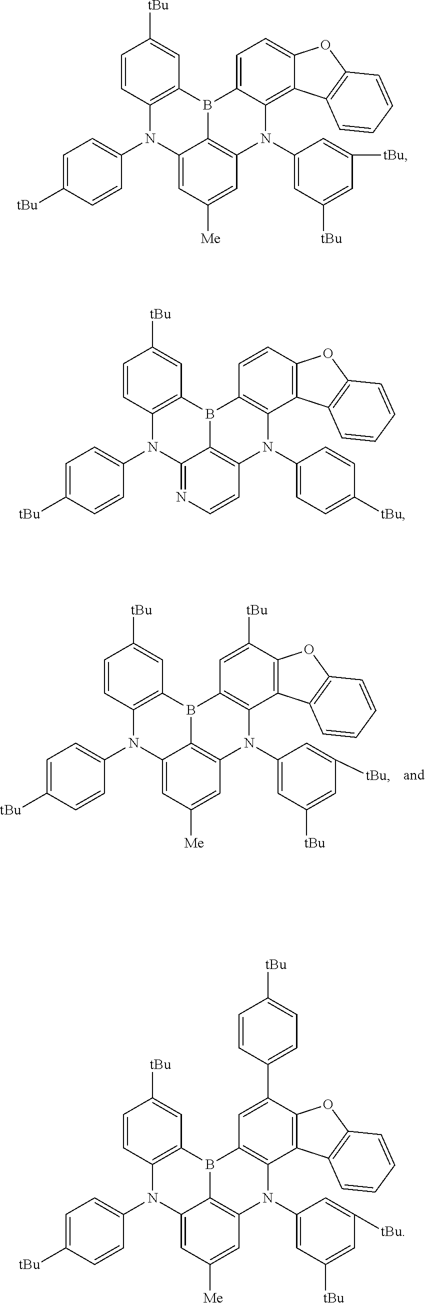 [SMILES: Cc1cc2c3c(c1)N(c1cc(C(C)(C)C)cc(C(C)(C)C)c1)c1c(ccc4oc5ccccc5c14)B3c1cc(C(C)(C)C)ccc1N2c1ccc(C(C)(C)C)cc1 ; CC(C)(C)c1ccc(N2c3ccc(C(C)(C)C)cc3B3c4ccc5oc6ccccc6c5c4N(c4ccc(C(C)(C)C)cc4)c4ccnc2c43)cc1 ; Cc1cc2c3c(c1)N(c1cc(C(C)(C)C)cc(C(C)(C)C)c1)c1c(cc(C(C)(C)C)c4oc5ccccc5c14)B3c1cc(C(C)(C)C)ccc1N2c1ccc(C(C)(C)C)cc1 ; Cc1cc2c3c(c1)N(c1cc(C(C)(C)C)cc(C(C)(C)C)c1)c1c(cc(-c4ccc(C(C)(C)C)cc4)c4oc5ccccc5c14)B3c1cc(C(C)(C)C)ccc1N2c1ccc(C(C)(C)C)cc1]

The fused ring compound disclosed in this application is mainly used alone as a fluorescent material in a device. This application has disclosed or taught neither an application of a combination of the fused ring compound and a metal complex as a phosphorescent sensitizer in an organic electroluminescent device nor an effect of the combination on device performance.

In addition to novel emissive materials, a combination of materials, especially a combination of a phosphorescent sensitizer and a fluorescent material, has a particularly important effect on device performance. To satisfy increasingly high requirements of the industry, especially requirements for performance such as a narrower full width at half maximum, higher device efficiency, and a longer lifetime, combinations of different phosphorescent sensitizers and fluorescent materials still need to be further studied and developed.

### SUMMARY

The present disclosure aims to provide a novel organic electroluminescent device with an organic layer comprising at least a fluorescent material and a metal complex to solve at least part of the preceding problems. The fluorescent material has a particular structure represented by Formula 1, and the metal complex comprises a ligand represented by Formula 2. The organic electroluminescent device of the present disclosure uses a phosphorescent material (the metal complex) to sensitize the fluorescent material so that the prepared organic electroluminescent device has a narrower full width at half maximum and higher efficiency.

According to an embodiment of the present disclosure, disclosed is an electroluminescent device, which comprises:
an anode,
a cathode, and
an organic layer disposed between the anode and the cathode, wherein the organic layer comprises at least a fluorescent material and a metal complex;
wherein the fluorescent material has a structure represented by Formula 1:

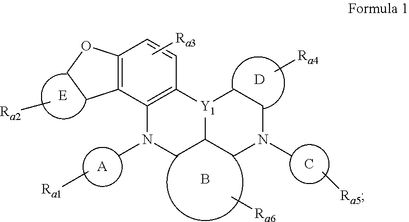

wherein in Formula 1, the ring A, the ring B, the ring C, the ring D, and the ring E are each independently selected from an unsaturated carbocyclic ring having 5 to 30 carbon atoms or an unsaturated heterocyclic ring having 3 to 30 carbon atoms;
Y₁ is selected from B, P═O, P═S, As, As=O, As=S, SiR′, or GeR′;
Rₐ₁, Rₐ₂, Rₐ₃, Rₐ₄, Rₐ₅, and Rₐ₆ represent, at each occurrence identically or differently, mono-substitution, multiple substitutions, or non-substitution;
R′, Rₐ₁, Rₐ₂, Rₐ₃, Rₐ₄, Rₐ₅, and Rₐ₆ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof, and
adjacent substituents Rₐ₁, Rₐ₂, Rₐ₃, Rₐ₄, Rₐ₅, Rₐ₆ can be optionally joined to form a ring; wherein the metal complex comprises a metal M and a ligand Lₐ coordinated to the metal M, the metal M is selected from a metal with a relative atomic mass greater than 40, and the ligand Lₐ has a structure represented by Formula 2:

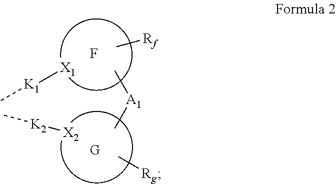

wherein in Formula 2, the ring F and the ring G are each independently selected from an unsaturated carbocyclic ring having 5 to 30 carbon atoms, an unsaturated heterocyclic ring having 1 to 30 carbon atoms, or a combination thereof;
X₁ and X₂ are identically or differently selected from C or N;
K₁ and K₂ are each independently selected from a single bond, O, or S;
A₁ is selected from a single bond, O, S, Se, (SiR_{q}R_{q})_{y}, PR_{q}, NR_{q}, (CR_{q}R_{q})_{y}, substituted or unsubstituted arylene having 6 to 30 carbon atoms, substituted or unsubstituted heteroarylene having 3 to 30 carbon atoms, or a combination thereof, wherein y is, at each occurrence identically or differently, selected from 1, 2, 3, 4, or 5;
R_{f} and R_{g} represent, at each occurrence identically or differently, mono-substitution, multiple substitutions, or non-substitution;
R_{f} and R_{g} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof, and
adjacent substituents R_{f} and R_{g} can be optionally joined to form a ring.

According to another embodiment of the present disclosure, further disclosed is a display apparatus comprising an organic electroluminescent device, wherein a specific structure of the organic electroluminescent device is described in any preceding embodiment.

A novel organic electroluminescent device disclosed in the present disclosure has an organic layer comprising at least a fluorescent material and a metal complex. The fluorescent material has a structure represented by Formula 1, and the metal complex comprises a ligand represented by Formula 2. The organic electroluminescent device of the present disclosure uses a phosphorescent material (the metal complex) to sensitize the fluorescent material having the structure of Formula 1 so that the prepared organic electroluminescent device has a narrower full width at half maximum and higher efficiency.

### BRIEF DESCRIPTION OF DRAWINGS

FIG. 1 is a schematic diagram of an organic light-emitting device that may comprise an organic electroluminescent device disclosed herein.

FIG. 2 is a schematic diagram of another organic light-emitting device that may comprise an organic electroluminescent device disclosed herein.

### DETAILED DESCRIPTION

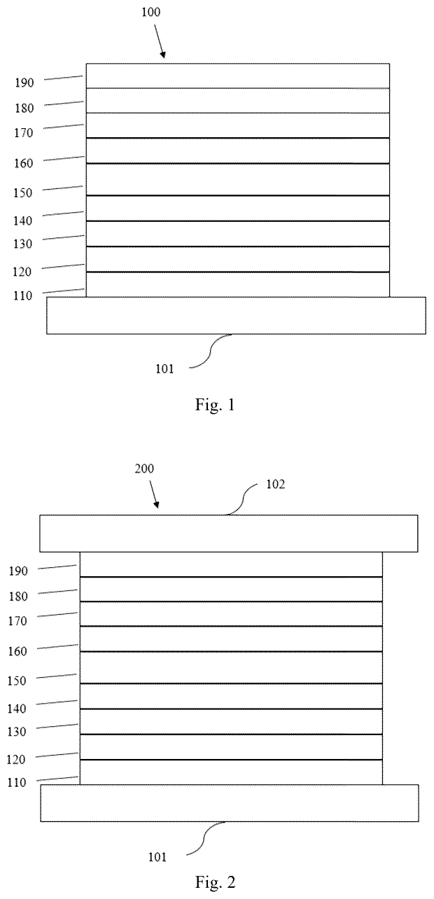

OLEDs can be fabricated on various types of substrates such as glass, plastic, and metal foil. FIG. 1 schematically shows an organic light-emitting device 100 without limitation. The figures are not necessarily drawn to scale. Some of the layers in the figures can also be omitted as needed. Device 100 may include a substrate 101, an anode 110, a hole injection layer 120, a hole transport layer 130, an electron blocking layer 140, an emissive layer 150, a hole blocking layer 160, an electron transport layer 170, an electron injection layer 180 and a cathode 190. Device 100 may be fabricated by depositing the layers described in order. The properties and functions of these various layers, as well as example materials, are described in more detail in U.S. Pat. No. 7,279,704 at cols. 6-10, the contents of which are incorporated by reference herein in its entirety.

More examples for each of these layers are available. For example, a flexible and transparent substrate-anode combination is disclosed in U.S. Pat. No. 5,844,363, which is incorporated by reference herein in its entirety. An example of a p-doped hole transport layer is m-MTDATA doped with F4-TCNQ at a molar ratio of 50:1, as disclosed in U.S. Patent Application Publication No. 2003/0230980, which is incorporated by reference herein in its entirety. Examples of host materials are disclosed in U.S. Pat. No. 6,303,238 to Thompson et al., which is incorporated by reference herein in its entirety. An example of an n-doped electron transport layer is BPhen doped with Li at a molar ratio of 1:1, as disclosed in U.S. Patent Application Publication No. 2003/0230980, which is incorporated by reference herein in its entirety. U.S. Pat. Nos. 5,703,436 and 5,707,745, which are incorporated by reference herein in their entireties, disclose examples of cathodes including composite cathodes having a thin layer of metal such as Mg:Ag with an overlying transparent, electrically-conductive, sputter-deposited ITO layer. The theory and use of blocking layers are described in more detail in U.S. Pat. No. 6,097,147 and U.S. Patent Application Publication No. 2003/0230980, which are incorporated by reference herein in their entireties. Examples of injection layers are provided in U.S. Patent Application Publication No. 2004/0174116, which is incorporated by reference herein in its entirety. A description of protective layers may be found in U.S. Patent Application Publication No. 2004/0174116, which is incorporated by reference herein in its entirety.

The layered structure described above is provided by way of non-limiting examples. Functional OLEDs may be achieved by combining the various layers described in different ways, or layers may be omitted entirely. It may also include other layers not specifically described. Within each layer, a single material or a mixture of multiple materials can be used to achieve optimum performance. Any functional layer may include several sublayers. For example, the emissive layer may have two layers of different emitting materials to achieve desired emission spectrum.

In one embodiment, an OLED may be described as having an “organic layer” disposed between a cathode and an anode. This organic layer may include a single layer or multiple layers.

An OLED can be encapsulated by a barrier layer. FIG. 2 schematically shows an organic light emitting device 200 without limitation. FIG. 2 differs from FIG. 1 in that the organic light emitting device include a barrier layer 102, which is above the cathode 190, to protect it from harmful species from the environment such as moisture and oxygen. Any material that can provide the barrier function can be used as the barrier layer such as glass or organic-inorganic hybrid layers. The barrier layer should be placed directly or indirectly outside of the OLED device. Multilayer thin film encapsulation was described in U.S. Pat. No. 7,968,146, which is incorporated by reference herein in its entirety.

Devices fabricated in accordance with embodiments of the present disclosure can be incorporated into a wide variety of consumer products that have one or more of the electronic component modules (or units) incorporated therein. Some examples of such consumer products include flat panel displays, monitors, medical monitors, televisions, billboards, lights for interior or exterior illumination and/or signaling, heads-up displays, fully or partially transparent displays, flexible displays, smart phones, tablets, phablets, wearable devices, smart watches, laptop computers, digital cameras, camcorders, viewfinders, micro-displays, 3-D displays, vehicles displays, and vehicle tail lights.

The materials and structures described herein may be used in other organic electronic devices listed above.

As used herein, “top” means furthest away from the substrate, while “bottom” means closest to the substrate. Where a first layer is described as “disposed over” a second layer, the first layer is disposed further away from the substrate. There may be other layers between the first and second layers, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

It is believed that the internal quantum efficiency (IQE) of fluorescent OLEDs can exceed the 25% spin statistics limit through delayed fluorescence. As used herein, there are two types of delayed fluorescence, i.e. P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the transition between the triplet states and the singlet excited states. Compounds that are capable of generating E-type delayed fluorescence are required to have very small singlet-triplet gaps to convert between energy states. Thermal energy can activate the transition from the triplet state back to the singlet state. This type of delayed fluorescence is also known as thermally activated delayed fluorescence (TADF). A distinctive feature of TADF is that the delayed component increases as temperature rises. If the reverse intersystem crossing (RISC) rate is fast enough to minimize the non-radiative decay from the triplet state, the fraction of back populated singlet excited states can potentially reach 75%. The total singlet fraction can be 100%, far exceeding 25% of the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (ΔE_{S-T}). Organic, non-metal containing, donor-acceptor luminescent materials may be able to achieve this. The emission in these materials is generally characterized as a donor-acceptor charge-transfer (CT) type emission. The spatial separation of the HOMO and LUMO in these donor-acceptor type compounds generally results in small ΔE_{S-T}. These states may involve CT states. Generally, donor-acceptor luminescent materials are constructed by connecting an electron donor moiety such as amino- or carbazole-derivatives and an electron acceptor moiety such as N-containing six-membered aromatic rings.

### Definition of Terms of Substituents

Halogen or halide—as used herein includes fluorine, chlorine, bromine, and iodine.

Alkyl—as used herein includes both straight and branched chain alkyl groups. Alkyl may be alkyl having 1 to 20 carbon atoms, preferably alkyl having 1 to 12 carbon atoms, and more preferably alkyl having 1 to 6 carbon atoms. Examples of alkyl groups include a methyl group, an ethyl group, a propyl group, an isopropyl group, a n-butyl group, an s-butyl group, an isobutyl group, a t-butyl group, an n-pentyl group, an n-hexyl group, an n-heptyl group, an n-octyl group, an n-nonyl group, an n-decyl group, an n-undecyl group, an n-dodecyl group, an n-tridecyl group, an n-tetradecyl group, an n-pentadecyl group, an n-hexadecyl group, an n-heptadecyl group, an n-octadecyl group, a neopentyl group, a 1-methylpentyl group, a 2-methylpentyl group, a 1-pentylhexyl group, a 1-butylpentyl group, a 1-heptyloctyl group, and a 3-methylpentyl group. Of the above, preferred are a methyl group, an ethyl group, a propyl group, an isopropyl group, a n-butyl group, an s-butyl group, an isobutyl group, a t-butyl group, an n-pentyl group, a neopentyl group, and an n-hexyl group. Additionally, the alkyl group may be optionally substituted.

Cycloalkyl—as used herein includes cyclic alkyl groups. The cycloalkyl groups may be those having 3 to 20 ring carbon atoms, preferably those having 4 to 10 carbon atoms. Examples of cycloalkyl include cyclobutyl, cyclopentyl, cyclohexyl, 4-methylcyclohexyl, 4,4-dimethylcylcohexyl, 1-adamantyl, 2-adamantyl, 1-norbornyl, 2-norbornyl, and the like. Of the above, preferred are cyclopentyl, cyclohexyl, 4-methylcyclohexyl, and 4,4-dimethylcylcohexyl. Additionally, the cycloalkyl group may be optionally substituted.

Heteroalkyl—as used herein, includes a group formed by replacing one or more carbons in an alkyl chain with a hetero-atom(s) selected from the group consisting of a nitrogen atom, an oxygen atom, a sulfur atom, a selenium atom, a phosphorus atom, a silicon atom, a germanium atom, and a boron atom. Heteroalkyl may be those having 1 to 20 carbon atoms, preferably those having 1 to 10 carbon atoms, and more preferably those having 1 to 6 carbon atoms. Examples of heteroalkyl include methoxymethyl, ethoxymethyl, ethoxyethyl, methylthiomethyl, ethylthiomethyl, ethylthioethyl, methoxymethoxymethyl, ethoxymethoxymethyl, ethoxyethoxyethyl, hydroxymethyl, hydroxyethyl, hydroxypropyl, mercaptomethyl, mercaptoethyl, mercaptopropyl, aminomethyl, aminoethyl, aminopropyl, dimethylaminomethyl, trimethylgermanylmethyl, trimethylgermanylethyl, trimethylgermanylisopropyl, dimethylethylgermanylmethyl, dimethylisopropylgermanylmethyl, tert-butyldimethylgermanylmethyl, triethylgermanylmethyl, triethylgermanylethyl, triisopropylgermanylmethyl, triisopropylgermanylethyl, trimethylsilylmethyl, trimethylsilylethyl, trimethylsilylisopropyl, triisopropylsilylmethyl, and triisopropylsilylethyl. Additionally, the heteroalkyl group may be optionally substituted.

Alkenyl—as used herein includes straight chain, branched chain, and cyclic alkene groups. Alkenyl may be those having 2 to 20 carbon atoms, preferably those having 2 to 10 carbon atoms. Examples of alkenyl include vinyl, 1-propenyl group, 1-butenyl, 2-butenyl, 3-butenyl, 1,3-butandienyl, 1-methylvinyl, styryl, 2,2-diphenylvinyl, 1,2-diphenylvinyl, 1-methylallyl, 1,1-dimethylallyl, 2-methylallyl, 1-phenylallyl, 2-phenylallyl, 3-phenylallyl, 3,3-diphenylallyl, 1,2-dimethylallyl, 1-phenyl-1-butenyl, 3-phenyl-1-butenyl, cyclopentenyl, cyclopentadienyl, cyclohexenyl, cycloheptenyl, cycloheptatrienyl, cyclooctenyl, cyclooctatetraenyl, and norbornenyl. Additionally, the alkenyl group may be optionally substituted.

Alkynyl—as used herein includes straight chain alkynyl groups. Alkynyl may be those having 2 to 20 carbon atoms, preferably those having 2 to 10 carbon atoms. Examples of alkynyl groups include ethynyl, propynyl, propargyl, 1-butynyl, 2-butynyl, 3-butynyl, 1-pentynyl, 2-pentynyl, 3,3-dimethyl-1-butynyl, 3-ethyl-3-methyl-1-pentynyl, 3,3-diisopropyl-1-pentynyl, phenylethynyl, phenylpropynyl, etc. Of the above, preferred are ethynyl, propynyl, propargyl, 1-butynyl, 2-butynyl, 3-butynyl, 1-pentynyl, and phenylethynyl. Additionally, the alkynyl group may be optionally substituted.

Aryl or an aromatic group—as used herein includes non-condensed and condensed systems. Aryl may be those having 6 to 30 carbon atoms, preferably those having 6 to 20 carbon atoms, and more preferably those having 6 to 12 carbon atoms. Examples of aryl groups include phenyl, biphenyl, terphenyl, triphenylene, tetraphenylene, naphthalene, anthracene, phenalene, phenanthrene, fluorene, pyrene, chrysene, perylene, and azulene, preferably phenyl, biphenyl, terphenyl, triphenylene, fluorene, and naphthalene. Examples of non-condensed aryl groups include phenyl, biphenyl-2-yl, biphenyl-3-yl, biphenyl-4-yl, p-terphenyl-4-yl, p-terphenyl-3-yl, p-terphenyl-2-yl, m-terphenyl-4-yl, m-terphenyl-3-yl, m-terphenyl-2-yl, o-tolyl, m-tolyl, p-tolyl, p-(2-phenylpropyl)phenyl, 4′-methylbiphenylyl, 4″-t-butyl-p-terphenyl-4-yl, o-cumenyl, m-cumenyl, p-cumenyl, 2,3-xylyl, 3,4-xylyl, 2,5-xylyl, mesityl, and m-quarterphenyl. Additionally, the aryl group may be optionally substituted.

Heterocyclic groups or heterocycle—as used herein include non-aromatic cyclic groups. Non-aromatic heterocyclic groups include saturated heterocyclic groups having 3 to 20 ring atoms and unsaturated non-aromatic heterocyclic groups having 3 to 20 ring atoms, where at least one ring atom is selected from the group consisting of a nitrogen atom, an oxygen atom, a sulfur atom, a selenium atom, a silicon atom, a phosphorus atom, a germanium atom, and a boron atom. Preferred non-aromatic heterocyclic groups are those having 3 to 7 ring atoms, each of which includes at least one hetero-atom such as nitrogen, oxygen, silicon, or sulfur. Examples of non-aromatic heterocyclic groups include oxiranyl, oxetanyl, tetrahydrofuranyl, tetrahydropyranyl, dioxolanyl, dioxanyl, aziridinyl, dihydropyrrolyl, tetrahydropyrrolyl, piperidinyl, oxazolidinyl, morpholinyl, piperazinyl, oxepinyl, thiepinyl, azepinyl, and tetrahydrosilolyl. Additionally, the heterocyclic group may be optionally substituted.

Heteroaryl—as used herein, includes non-condensed and condensed hetero-aromatic groups having 1 to 5 hetero-atoms, where at least one hetero-atom is selected from the group consisting of a nitrogen atom, an oxygen atom, a sulfur atom, a selenium atom, a silicon atom, a phosphorus atom, a germanium atom, and a boron atom. A hetero-aromatic group is also referred to as heteroaryl. Heteroaryl may be those having 3 to 30 carbon atoms, preferably those having 3 to 20 carbon atoms, and more preferably those having 3 to 12 carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridoindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group may be optionally substituted.

Alkoxy—as used herein, is represented by —O-alkyl, —O-cycloalkyl, —O-heteroalkyl, or —O-heterocyclic group. Examples and preferred examples of alkyl, cycloalkyl, heteroalkyl, and heterocyclic groups are the same as those described above. Alkoxy groups may be those having 1 to 20 carbon atoms, preferably those having 1 to 6 carbon atoms. Examples of alkoxy groups include methoxy, ethoxy, propoxy, butoxy, pentyloxy, hexyloxy, cyclopropyloxy, cyclobutyloxy, cyclopentyloxy, cyclohexyloxy, tetrahydrofuranyloxy, tetrahydropyranyloxy, methoxypropyloxy, ethoxyethyloxy, methoxymethyloxy, and ethoxymethyloxy. Additionally, the alkoxy group may be optionally substituted.

Aryloxy—as used herein, is represented by —O-aryl or —O-heteroaryl. Examples and preferred examples of aryl and heteroaryl are the same as those described above. Aryloxy groups may be those having 6 to 30 carbon atoms, preferably those having 6 to 20 carbon atoms. Examples of aryloxy groups include phenoxy and biphenyloxy. Additionally, the aryloxy group may be optionally substituted.

Arylalkyl—as used herein, contemplates alkyl substituted with an aryl group. Arylalkyl may be those having 7 to 30 carbon atoms, preferably those having 7 to 20 carbon atoms, and more preferably those having 7 to 13 carbon atoms. Examples of arylalkyl groups include benzyl, 1-phenylethyl, 2-phenylethyl, 1-phenylisopropyl, 2-phenylisopropyl, phenyl-t-butyl, alpha-naphthylmethyl, 1-alpha-naphthylethyl, 2-alpha-naphthylethyl, 1-alpha-naphthylisopropyl, 2-alpha-naphthylisopropyl, beta-naphthylmethyl, 1-beta-naphthylethyl, 2-beta-naphthylethyl, 1-beta-naphthylisopropyl, 2-beta-naphthylisopropyl, p-methylbenzyl, m-methylbenzyl, o-methylbenzyl, p-chlorobenzyl, m-chlorobenzyl, o-chlorobenzyl, p-bromobenzyl, m-bromobenzyl, o-bromobenzyl, p-iodobenzyl, m-iodobenzyl, o-iodobenzyl, p-hydroxybenzyl, m-hydroxybenzyl, o-hydroxybenzyl, p-aminobenzyl, m-aminobenzyl, o-aminobenzyl, p-nitrobenzyl, m-nitrobenzyl, o-nitrobenzyl, p-cyanobenzyl, m-cyanobenzyl, o-cyanobenzyl, 1-hydroxy-2-phenylisopropyl, and 1-chloro-2-phenylisopropyl. Of the above, preferred are benzyl, p-cyanobenzyl, m-cyanobenzyl, o-cyanobenzyl, 1-phenylethyl, 2-phenylethyl, 1-phenylisopropyl, and 2-phenylisopropyl. Additionally, the arylalkyl group may be optionally substituted.

Alkylsilyl—as used herein, contemplates a silyl group substituted with an alkyl group. Alkylsilyl groups may be those having 3 to 20 carbon atoms, preferably those having 3 to 10 carbon atoms. Examples of alkylsilyl groups include trimethylsilyl, triethylsilyl, methyldiethylsilyl, ethyldimethylsilyl, tripropylsilyl, tributylsilyl, triisopropylsilyl, methyldiisopropylsilyl, dimethylisopropylsilyl, tri-t-butylsilyl, triisobutylsilyl, dimethyl t-butylsilyl, and methyldi-t-butylsilyl. Additionally, the alkylsilyl group may be optionally substituted.

Arylsilyl—as used herein, contemplates a silyl group substituted with an aryl group. Arylsilyl groups may be those having 6 to 30 carbon atoms, preferably those having 8 to 20 carbon atoms. Examples of arylsilyl groups include triphenylsilyl, phenyldibiphenylylsilyl, diphenylbiphenylsilyl, phenyldiethylsilyl, diphenylethylsilyl, phenyldimethylsilyl, diphenylmethylsilyl, phenyldiisopropylsilyl, diphenylisopropylsilyl, diphenylbutylsilyl, diphenylisobutylsilyl, diphenyl t-butylsilyl. Additionally, the arylsilyl group may be optionally substituted.

Alkylgermanyl—as used herein contemplates a germanyl substituted with an alkyl group. The alkylgermanyl may be those having 3 to 20 carbon atoms, preferably those having 3 to 10 carbon atoms. Examples of alkylgermanyl include trimethylgermanyl, triethylgermanyl, methyldiethylgermanyl, ethyldimethylgermanyl, tripropylgermanyl, tributylgermanyl, triisopropylgermanyl, methyldiisopropylgermanyl, dimethylisopropylgermanyl, tri-t-butylgermanyl, triisobutylgermanyl, dimethyl-t-butylgermanyl, and methyldi-t-butylgermanyl. Additionally, the alkylgermanyl may be optionally substituted.

Arylgermanyl—as used herein contemplates a germanyl substituted with at least one aryl group or heteroaryl group. Arylgermanyl may be those having 6 to 30 carbon atoms, preferably those having 8 to 20 carbon atoms. Examples of arylgermanyl include triphenylgermanyl, phenyldibiphenylylgermanyl, diphenylbiphenylgermanyl, phenyldiethylgermanyl, diphenylethylgermanyl, phenyldimethylgermanyl, diphenylmethylgermanyl, phenyldiisopropylgermanyl, diphenylisopropylgermanyl, diphenylbutylgermanyl, diphenylisobutylgermanyl, and diphenyl-t-butylgermanyl. Additionally, the arylgermanyl may be optionally substituted.

The term “aza” in azadibenzofuran, azadibenzothiophene, etc. means that one or more of C—H groups in the respective aromatic fragment are replaced by a nitrogen atom. For example, azatriphenylene encompasses dibenzo[f,h]quinoxaline, dibenzo[f,h]quinoline and other analogs with two or more nitrogens in the ring system. One of ordinary skill in the art can readily envision other nitrogen analogs of the aza-derivatives described above, and all such analogs are intended to be encompassed by the terms as set forth herein.

In the present disclosure, unless otherwise defined, when any term of the group consisting of substituted alkyl, substituted cycloalkyl, substituted heteroalkyl, substituted heterocyclic group, substituted arylalkyl, substituted alkoxy, substituted aryloxy, substituted alkenyl, substituted alkynyl, substituted aryl, substituted heteroaryl, substituted alkylsilyl, substituted arylsilyl, substituted alkylgermanyl, substituted arylgermanyl, substituted amino, substituted acyl, substituted carbonyl, a substituted carboxylic acid group, a substituted ester group, substituted sulfinyl, substituted sulfonyl, and substituted phosphino is used, it means that any group of alkyl, cycloalkyl, heteroalkyl, heterocyclic group, arylalkyl, alkoxy, aryloxy, alkenyl, alkynyl, aryl, heteroaryl, alkylsilyl, arylsilyl, alkylgermanyl, arylgermanyl, amino, acyl, carbonyl, a carboxylic acid group, an ester group, sulfinyl, sulfonyl, and phosphino may be substituted with one or more groups selected from the group consisting of deuterium, halogen, unsubstituted alkyl having 1 to 20 carbon atoms, unsubstituted cycloalkyl having 3 to 20 ring carbon atoms, unsubstituted heteroalkyl having 1 to 20 carbon atoms, an unsubstituted heterocyclic group having 3 to 20 ring atoms, unsubstituted arylalkyl having 7 to 30 carbon atoms, unsubstituted alkoxy having 1 to 20 carbon atoms, unsubstituted aryloxy having 6 to 30 carbon atoms, unsubstituted alkenyl having 2 to 20 carbon atoms, unsubstituted alkynyl having 2 to 20 carbon atoms, unsubstituted aryl having 6 to 30 carbon atoms, unsubstituted heteroaryl having 3 to 30 carbon atoms, unsubstituted alkylsilyl having 3 to 20 carbon atoms, unsubstituted arylsilyl group having 6 to 20 carbon atoms, unsubstituted alkylgermanyl group having 3 to 20 carbon atoms, unsubstituted arylgermanyl group having 6 to 20 carbon atoms, unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or an attached fragment are considered to be equivalent.

In the compounds mentioned in the present disclosure, hydrogen atoms may be partially or fully replaced by deuterium. Other atoms such as carbon and nitrogen may also be replaced by their other stable isotopes. The replacement by other stable isotopes in the compounds may be preferred due to its enhancements of device efficiency and stability.

In the compounds mentioned in the present disclosure, multiple substitutions refer to a range that includes di-substitutions, up to the maximum available substitutions. When substitution in the compounds mentioned in the present disclosure represents multiple substitutions (including di-, tri-, and tetra-substitutions etc.), that means the substituent may exist at a plurality of available substitution positions on its linking structure, the substituents present at a plurality of available substitution positions may have the same structure or different structures.

In the compounds mentioned in the present disclosure, adjacent substituents in the compounds cannot be joined to form a ring unless otherwise explicitly defined, for example, adjacent substituents can be optionally joined to form a ring. In the compounds mentioned in the present disclosure, the expression that adjacent substituents can be optionally joined to form a ring includes a case where adjacent substituents may be joined to form a ring and a case where adjacent substituents are not joined to form a ring. When adjacent substituents can be optionally joined to form a ring, the ring formed may be monocyclic or polycyclic (including spirocyclic, endocyclic, fusedcyclic, and etc.), as well as alicyclic, heteroalicyclic, aromatic, or heteroaromatic. In such expression, adjacent substituents may refer to substituents bonded to the same atom, substituents bonded to carbon atoms which are directly bonded to each other, or substituents bonded to carbon atoms which are more distant from each other. Preferably, adjacent substituents refer to substituents bonded to the same carbon atom and substituents bonded to carbon atoms which are directly bonded to each other.

The expression that adjacent substituents can be optionally joined to form a ring is also intended to mean that two substituents bonded to the same carbon atom are joined to each other via a chemical bond to form a ring, which can be exemplified by the following formula:

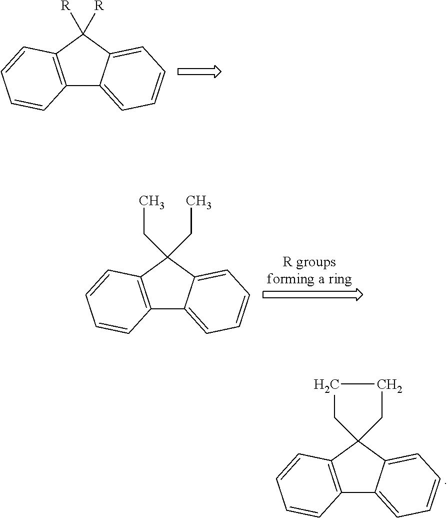

The expression that adjacent substituents can be optionally joined to form a ring is also intended to mean that two substituents bonded to carbon atoms which are directly bonded to each other are joined to each other via a chemical bond to form a ring, which can be exemplified by the following formula:

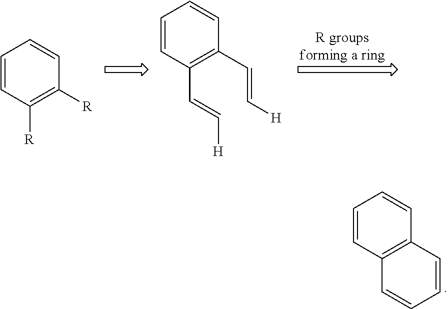

The expression that adjacent substituents can be optionally joined to form a ring is also intended to mean that two substituents bonded to further distant carbon atoms are joined to each other via a chemical bond to form a ring, which can be exemplified by the following formula:

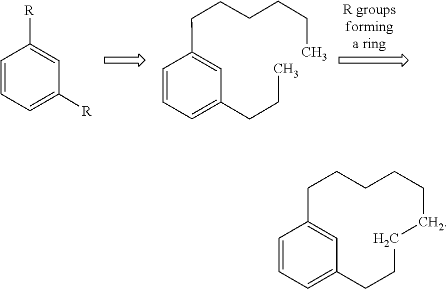

Furthermore, the expression that adjacent substituents can be optionally joined to form a ring is also intended to mean that, in the case where one of the two substituents bonded to carbon atoms which are directly bonded to each other represents hydrogen, the second substituent is bonded at a position at which the hydrogen atom is bonded, thereby forming a ring. This is exemplified by the following formula:

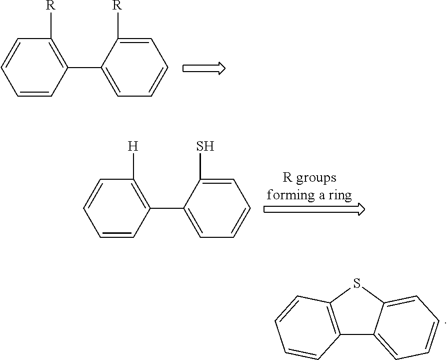

According to an embodiment of the present disclosure, disclosed is an electroluminescent device, which comprises:
an anode,
a cathode, and
an organic layer disposed between the anode and the cathode, wherein the organic layer comprises at least a fluorescent material and a metal complex;
wherein the fluorescent material has a structure represented by Formula 1:

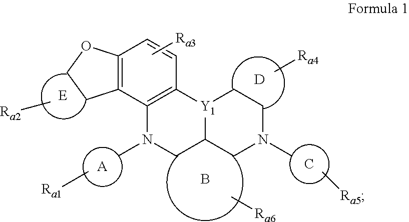

wherein in Formula 1, the ring A, the ring B, the ring C, the ring D, and the ring E are each independently selected from an unsaturated carbocyclic ring having 5 to 30 carbon atoms or an unsaturated heterocyclic ring having 3 to 30 carbon atoms;
Y₁ is selected from B, P═O, P═S, As, As=O, As=S, SiR′, or GeR′;
Rₐ₁, Rₐ₂, Rₐ₃, Rₐ₄, Rₐ₅, and Rₐ₆ represent, at each occurrence identically or differently, mono-substitution, multiple substitutions, or non-substitution;
R′, Rₐ₁, Rₐ₂, Rₐ₃, Rₐ₄, Rₐ₅, and Rₐ₆ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof, and
adjacent substituents Rₐ₁, Rₐ₂, Rₐ₃, Rₐ₄, Rₐ₅, Rₐ₆ can be optionally joined to form a ring;
wherein the metal complex comprises a metal M and a ligand Lₐ coordinated to the metal M, the metal M is selected from a metal with a relative atomic mass greater than 40, and the ligand Lₐ has a structure represented by Formula 2:

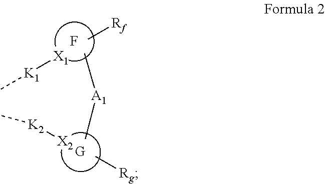

wherein in Formula 2, the ring F and the ring G are each independently selected from an unsaturated carbocyclic ring having 5 to 30 carbon atoms, an unsaturated heterocyclic ring having 1 to 30 carbon atoms, or a combination thereof;
X₁ and X₂ are identically or differently selected from C or N;
K₁ and K₂ are each independently selected from a single bond, O, or S;
A₁ is selected from a single bond, O, S, Se, (SiR_{q}R_{q})_{y}, PR_{q}, NR_{q}, (CR_{q}R_{q})_{y}, substituted or unsubstituted arylene having 6 to 30 carbon atoms, substituted or unsubstituted heteroarylene having 3 to 30 carbon atoms, or a combination thereof, wherein y is, at each occurrence identically or differently, selected from 1, 2, 3, 4, or 5;
R_{f} and R_{g} represent, at each occurrence identically or differently, mono-substitution, multiple substitutions, or non-substitution;
R_{f} and R_{g} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof, and
adjacent substituents R_{f} and R_{g} can be optionally joined to form a ring.

In the present disclosure, a “carbocyclic ring” comprises a saturated carbocyclic ring and an unsaturated carbocyclic ring, the “unsaturated carbocyclic ring” comprises an aromatic unsaturated carbocyclic ring and a non-aromatic unsaturated carbocyclic ring, a “heterocyclic ring” comprises a saturated heterocyclic ring and an unsaturated heterocyclic ring, and the “unsaturated heterocyclic ring” comprises an aromatic unsaturated heterocyclic ring and a non-aromatic unsaturated heterocyclic ring.

In the present disclosure, the expression that “adjacent substituents Rₐ₁, Rₐ₂, Rₐ₃, Rₐ₄, Rₐ₅, Rₐ₆ can be optionally joined to form a ring” is intended to mean that any one or more of groups of adjacent substituents, such as two substituents Rₐ₁, two substituents Rₐ₂, two substituents R₃, two substituents Rₐ₄, two substituents Rₐ₅, two substituents Rₐ₆, substituents Rₐ₁ and Rₐ₂, substituents Rₐ₃ and Rₐ₄, substituents Rₐ₄ and Rₐ₅, substituents Rₐ₅ and Rₐ₆, and substituents Rₐ₆ and Rₐ₁, can be joined to form a ring. Obviously, it is also possible that none of these substituents are joined to form a ring.

In the present disclosure, in Formula 2, when A₁ is selected from a single bond, it indicates that the ring F is directly joined to the ring G via a single bond. When K₁ or K₂ is selected from a single bond, it indicates that the ring F or the ring G is directly joined to the metal M via a single bond.

In the present disclosure, in Formula 2, the connection of A₁ to the ring F or the ring G is intended to mean that in Formula 2, A₁ may be joined to any ring atom in the ring F or the ring G, which not only comprises the case where A₁ is joined to an atom adjacent to X₁ in the ring F or an atom adjacent to X₂ in the ring G.

In the present disclosure, the expression that “adjacent substituents R_{f} and R_{g} can be optionally joined to form a ring” is intended to mean that any one or more of groups of adjacent substituents, such as two substituents R_{f}, two substituents R_{g}, and substituents R_{f} and R_{g}, can be joined to form a ring. Obviously, it is also possible that none of these substituents are joined to form a ring.

According to an embodiment of the present disclosure, the ring A, the ring B, the ring C, the ring D, and the ring E are each independently selected from a five-membered unsaturated carbocyclic ring, an aromatic ring having 6 to 30 carbon atoms, or a heteroaromatic ring having 3 to 30 carbon atoms.

According to an embodiment of the present disclosure, the ring A, the ring B, the ring C, the ring D, and the ring E are, at each occurrence identically or differently, selected from a five-membered unsaturated carbocyclic ring, an aromatic ring having 6 to 18 carbon atoms, or a heteroaromatic ring having 3 to 18 carbon atoms.

According to an embodiment of the present disclosure, the ring A, the ring B, the ring C, the ring D, and the ring E are, at each occurrence identically or differently, selected from a benzene ring, a pyridine ring, a naphthalene ring, a phenanthrene ring, an anthracene ring, an indene ring, a fluorene ring, an indole ring, a carbazole ring, a benzofuran ring, a dibenzofuran ring, a benzosilole ring, a dibenzosilole ring, a benzothiophene ring, a dibenzothiophene ring, a dibenzoselenophene ring, a cyclopentadienyl ring, a furan ring, a thiophene ring, a silole ring, or a combination thereof.

According to an embodiment of the present disclosure, the fluorescent material has a structure represented by Formula 1-1:

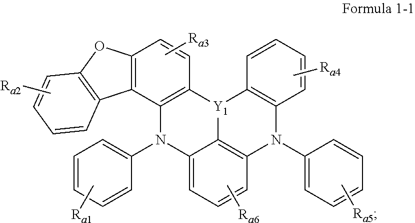

wherein
Y₁ is selected from B, P═O, P═S, As, As=O, As=S, SiR′, or GeR′;
Rₐ₁, Rₐ₂, Rₐ₃, Rₐ₄, Rₐ₅, and Rₐ₆ represent, at each occurrence identically or differently, mono-substitution, multiple substitutions, or non-substitution;
R′, Rₐ₁, Rₐ₂, Rₐ₃, Rₐ₄, Rₐ₅, and Rₐ₆ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof, and
adjacent substituents Rₐ₁, Rₐ₂, Rₐ₃, Rₐ₄, Rₐ₅, Rₐ₆ can be optionally joined to form a ring.

According to an embodiment of the present disclosure, Y₁ is selected from B, P═O, or P═S.

According to an embodiment of the present disclosure, Y₁ is selected from B.

According to an embodiment of the present disclosure, the fluorescent material comprises only one B atom.

According to an embodiment of the present disclosure, the compound of Formula 1 comprises only one B atom.

According to an embodiment of the present disclosure, Rₐ₁, Rₐ₂, Rₐ₃, Rₐ₄, Rₐ₅, and Rₐ₆ are, at each occurrence identically or differently, selected from the group consisting of: hydrogen, deuterium, halogen, cyano, hydroxyl, sulfanyl, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, and combinations thereof.

According to an embodiment of the present disclosure, Rₐ₁, Rₐ₂, Rₐ₃, Rₐ₄, Rₐ₅, and Rₐ₆ are, at each occurrence identically or differently, selected from the group consisting of: hydrogen, deuterium, halogen, cyano, hydroxyl, sulfanyl, substituted or unsubstituted alkyl having 1 to 6 carbon atoms, substituted or unsubstituted cycloalkyl having 3 to 6 ring carbon atoms, substituted or unsubstituted heteroalkyl having 1 to 6 carbon atoms, substituted or unsubstituted heterocyclic group having 3 to 6 ring atoms, substituted or unsubstituted aryl having 6 to 24 carbon atoms, substituted or unsubstituted heteroaryl having 3 to 12 carbon atoms, substituted or unsubstituted alkylsilyl having 3 to 6 carbon atoms, substituted or unsubstituted arylsilyl having 6 to 12 carbon atoms, substituted or unsubstituted alkylgermanyl having 3 to 6 carbon atoms, substituted or unsubstituted arylgermanyl having 6 to 12 carbon atoms, substituted or unsubstituted amino having 0 to 12 carbon atoms, and combinations thereof.

According to an embodiment of the present disclosure, Rₐ₁, Rₐ₂, Rₐ₃, Rₐ₄, Rₐ₅, and Rₐ₆ are, at each occurrence identically or differently, selected from the group consisting of: hydrogen, deuterium, fluorine, cyano, hydroxyl, sulfanyl, methyl, ethyl, n-propyl, isopropyl, cyclopropyl, n-butyl, isobutyl, t-butyl, cyclopentyl, neopentyl, cyclohexyl, trimethylsilyl, trimethylgermanyl, phenyl, biphenyl, terphenyl, tetraphenyl, triphenylenyl, tetraphenylenyl, naphthyl, phenanthryl, anthryl, indenyl, fluorenyl, indolyl, carbazolyl, benzofuryl, dibenzofuryl, benzosilolyl, dibenzosilolyl, benzothienyl, dibenzothienyl, dibenzoselenophenyl, diphenylamino, dibenzofurylphenylamino, and combinations thereof.

According to an embodiment of the present disclosure, at least one of Rₐ₁, Rₐ₂, Rₐ₃, Rₐ₄, Rₐ₅, and Rₐ₆ is, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

According to an embodiment of the present disclosure, at least one of Rₐ₁, Rₐ₂, Rₐ₃, Rₐ₄, Rₐ₅, and Rₐ₆ is, at each occurrence identically or differently, selected from the group consisting of: deuterium, halogen, cyano, hydroxyl, sulfanyl, substituted or unsubstituted alkyl having 1 to 6 carbon atoms, substituted or unsubstituted cycloalkyl having 3 to 6 ring carbon atoms, substituted or unsubstituted heteroalkyl having 1 to 6 carbon atoms, substituted or unsubstituted aryl having 6 to 24 carbon atoms, substituted or unsubstituted heteroaryl having 3 to 12 carbon atoms, substituted or unsubstituted alkylsilyl having 3 to 6 carbon atoms, substituted or unsubstituted arylsilyl having 6 to 12 carbon atoms, substituted or unsubstituted alkylgermanyl having 3 to 6 carbon atoms, substituted or unsubstituted arylgermanyl having 6 to 12 carbon atoms, substituted or unsubstituted amino having 0 to 12 carbon atoms, and combinations thereof.

According to an embodiment of the present disclosure, at least one of Rₐ₁, Rₐ₂, Rₐ₃, Rₐ₄, Rₐ₅, and Rₐ₆ is, at each occurrence identically or differently, selected from the group consisting of: deuterium, fluorine, cyano, hydroxyl, sulfanyl, methyl, ethyl, n-propyl, isopropyl, cyclopropyl, n-butyl, isobutyl, t-butyl, cyclopentyl, neopentyl, cyclohexyl, trimethylsilyl, trimethylgermanyl, phenyl, biphenyl, terphenyl, tetraphenyl, triphenylenyl, tetraphenylenyl, naphthyl, phenanthryl, anthryl, indenyl, fluorenyl, indolyl, carbazolyl, benzofuryl, dibenzofuryl, benzosilolyl, dibenzosilolyl, benzothienyl, dibenzothienyl, dibenzoselenophenyl, diphenylamino, dibenzofurylphenylamino, and combinations thereof.

According to an embodiment of the present disclosure, Rₐ₃ is selected from the group consisting of: substituted or unsubstituted aryl having 6 to 30 carbon atoms, substituted or unsubstituted heteroaryl having 3 to 30 carbon atoms, and combinations thereof.

According to an embodiment of the present disclosure, Rₐ₃ is selected from the group consisting of: substituted or unsubstituted aryl having 6 to 24 carbon atoms, substituted or unsubstituted heteroaryl having 3 to 12 carbon atoms, and combinations thereof.

According to an embodiment of the present disclosure, Rₐ₃ is selected from the group consisting of: phenyl, biphenyl, terphenyl, tetraphenyl, triphenylenyl, tetraphenylenyl, naphthyl, phenanthryl, anthryl, indenyl, fluorenyl, indolyl, carbazolyl, benzofuryl, dibenzofuryl, benzosilolyl, dibenzosilolyl, benzothienyl, dibenzothienyl, dibenzoselenophenyl, and combinations thereof.

According to an embodiment of the present disclosure, Rₐ₄ is selected from the group consisting of: substituted or unsubstituted aryl having 6 to 30 carbon atoms, substituted or unsubstituted heteroaryl having 3 to 30 carbon atoms, and combinations thereof.

According to an embodiment of the present disclosure, Rₐ₄ is selected from the group consisting of: substituted or unsubstituted aryl having 6 to 24 carbon atoms, substituted or unsubstituted heteroaryl having 3 to 12 carbon atoms, and combinations thereof.

According to an embodiment of the present disclosure, Rₐ₄ is selected from the group consisting of: phenyl, biphenyl, terphenyl, tetraphenyl, triphenylenyl, tetraphenylenyl, naphthyl, phenanthryl, anthryl, indenyl, fluorenyl, indolyl, carbazolyl, benzofuryl, dibenzofuryl, benzosilolyl, dibenzosilolyl, benzothienyl, dibenzothienyl, dibenzoselenophenyl, and combinations thereof.

According to an embodiment of the present disclosure, the fluorescent material is selected from the group consisting of Compound BD-1-1 to Compound BD-1-33, Compound BD-2-1 to Compound BD-2-19, Compound BD-3-1 to Compound BD-3-15, Compound BD-4-1 to Compound BD-4-36, and Compound BD-5-1 to Compound BD-5-14, wherein specific structures of Compound BD-1-1 to Compound BD-1-33, Compound BD-2-1 to Compound BD-2-19, Compound BD-3-1 to Compound BD-3-15, Compound BD-4-1 to Compound BD-4-36, and Compound BD-5-1 to Compound BD-5-14 are shown in claim 8.

According to an embodiment of the present disclosure, hydrogens in the structures of Compound BD-1-1 to Compound BD-1-33, Compound BD-2-1 to Compound BD-2-19, Compound BD-3-1 to Compound BD-3-15, Compound BD-4-1 to Compound BD-4-36, and Compound BD-5-1 to Compound BD-5-13 can be partially or fully substituted with deuterium.

According to an embodiment of the present disclosure, a maximum emission wavelength λ_{max-PL-1} of a photoluminescence spectrum of the fluorescent material is 450 nm to 500 nm.

According to an embodiment of the present disclosure, the maximum emission wavelength λ_{max-PL-1} of the photoluminescence spectrum of the fluorescent material is 450 nm to 470 nm.

According to an embodiment of the present disclosure, the maximum emission wavelength λ_{max-PL-1} of the photoluminescence spectrum of the fluorescent material is 455 nm to 465 nm.

According to an embodiment of the present disclosure, a full width at half maximum FWHM-_{PL-1} of the photoluminescence spectrum of the fluorescent material is less than or equal to 45 nm.

According to an embodiment of the present disclosure, the full width at half maximum FWHM-_{PL-1} of the photoluminescence spectrum of the fluorescent material is less than or equal to 35 nm.

According to an embodiment of the present disclosure, the full width at half maximum FWHM-_{PL-1} of the photoluminescence spectrum of the fluorescent material is less than or equal to 30 nm.

According to an embodiment of the present disclosure, the full width at half maximum FWHM-_{PL-1} of the photoluminescence spectrum of the fluorescent material is less than or equal to 25 nm.

According to an embodiment of the present disclosure, the full width at half maximum FWHM-_{PL-1} of the photoluminescence spectrum of the fluorescent material is less than or equal to 20 nm.

According to an embodiment of the present disclosure, the metal complex has a general formula of M(Lₐ)ₘ(L_{b})ₙ(L_{c})_{q};
Lₐ, L_{b}, and L_{c} are a first ligand, a second ligand, and a third ligand coordinated to the metal M, respectively; Lₐ, L_{b}, and L_{c} are identical or different;
the ligands Lₐ, L_{b}, and L_{c} can be optionally joined to form a multidentate ligand; for example, any two of Lₐ, L_{b}, and L_{c} may be joined to form a tetradentate ligand; in another example, Lₐ, L_{b}, and L_{c} may be joined to each other to form a hexadentate ligand; in another example, none of Lₐ, L_{b}, and L_{c} are joined to form a multidentate ligand;
m is 1, 2, or 3, n is 0, 1, or 2, q is 0, 1, or 2, and m+n+q is equal to the oxidation state of the metal M; when m is greater than or equal to 2, multiple Lₐ may be identical or different; when n is 2, two L_{b} may be identical or different; when q is 2, two L_{c} may be identical or different; and
the ligands L_{b} and L_{c} are, at each occurrence identically or differently, selected from a monoanionic bidentate ligand.

According to an embodiment of the present disclosure, the ligands L_{b} and L_{c} are, at each occurrence identically or differently, selected from the group consisting of the following structures:

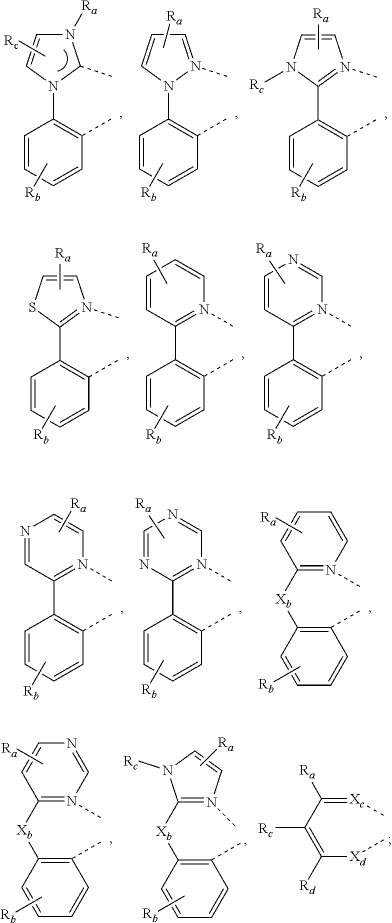

wherein
Rₐ and R_{b} represent, at each occurrence identically or differently, mono-substitution, multiple substitutions, or non-substitution;
X_{b} is, at each occurrence identically or differently, selected from the group consisting of: O, S, Se, NR_{N1}, and CR_{C1}R_{C2};
X_{c} and X_{d} are, at each occurrence identically or differently, selected from the group consisting of: O, S, Se, and NR_{N2};
Rₐ, R_{b}, R_{c}, R_{N1}, R_{N2}, R_{C1}, and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
adjacent substituents Rₐ, R_{b}, R_{c}, R_{N1}, R_{N2}, R_{C1}, and R_{C2} can be optionally joined to form a ring.

In this embodiment, the expression that “adjacent substituents Rₐ, R_{b}, R_{c}, R_{N1}, R_{N2}, R_{C1}, and R_{C2} can be optionally joined to form a ring” is intended to mean that any one or more of groups of adjacent substituents, such as two substituents R, two substituents R_{b}, substituents Rₐ and R_{b}, substituents Rₐ and R_{c}, substituents R_{b} and R_{c}, substituents Rₐ and R_{N1}, substituents R_{b} and R_{N1}, substituents Rₐ and R_{C1}, substituents Rₐ and R_{C2}, substituents R_{b} and R_{C1}, substituents R_{b} and R_{C2}, substituents R_{C1} and R_{C2}, substituents Rₐ and R_{N2}, and substituents R_{b} and R_{N2}, can be joined to form a ring. Obviously, it is also possible that none of these substituents are joined to form a ring.

According to an embodiment of the present disclosure, the metal M is selected from the group consisting of Cu, Ag, Au, Zn, Ru, Rh, Pd, Os, Ir, and Pt.

According to an embodiment of the present disclosure, the metal M is selected from Ir, Pt, or Pd.

According to an embodiment of the present disclosure, the metal M is selected from Ir or Pt.

According to an embodiment of the present disclosure, the metal complex has a structure represented by Formula 3:

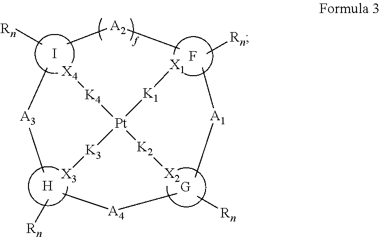

wherein in Formula 3,
the ring F, the ring G, the ring H, and the ring I are each independently selected from an unsaturated carbocyclic ring having 5 to 30 carbon atoms, an unsaturated heterocyclic ring having 1 to 30 carbon atoms, or a combination thereof;
f is selected from 0 or 1;
A₁ to A₄ are, at each occurrence identically or differently, selected from a single bond, O, S, Se, (SiR_{q}R_{q})_{y}, PR_{q}, NR_{q}, (CF_{q})_{y}, substituted or unsubstituted arylene having 6 to 30 carbon atoms, substituted or unsubstituted heteroarylene having 3 to 30 carbon atoms, or a combination thereof, wherein y is, at each occurrence identically or differently, selected from 1, 2, 3, 4, or 5;
X₁ to X₄ are each independently selected from C or N;
K₁ to K₄ are each independently selected from a single bond, O, or S;
Rₙ represents, at each occurrence identically or differently, mono-substitution, multiple substitutions, or non-substitution;
R_{q} and Rₙ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof, and
adjacent substituents R_{q}, Rₙ can be optionally joined to form a ring.

In this embodiment, the expression that “adjacent substituents R_{q}, Rₙ can be optionally joined to form a ring” is intended to mean that any one or more of groups of adjacent substituents, such as two substituents R_{q}, two substituents Rₙ, and substituents R_{q} and Rₙ, can be joined to form a ring. Obviously, it is also possible that none of these groups of adjacent substituents are joined to form a ring.

According to an embodiment of the present disclosure, the metal complex has a structure represented by Formula 3-A:

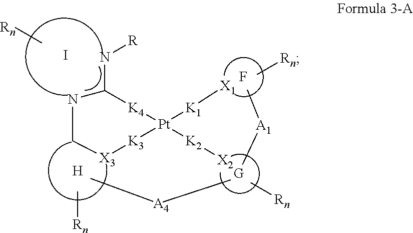

wherein in Formula 3-A,
the ring F, the ring G, and the ring H are each independently selected from an unsaturated carbocyclic ring having 5 to 30 carbon atoms, an unsaturated heterocyclic ring having 3 to 30 carbon atoms, or a combination thereof, and the ring I is selected from an unsaturated heterocyclic ring having 1 to 30 carbon atoms;
A₁ and A₄ are each independently selected from a single bond, O, S, Se, (SiR_{q}R_{q})_{y}, PR_{q}, NR_{q}, (CR_{q}R_{q})_{y}, substituted or unsubstituted arylene having 6 to 30 carbon atoms, substituted or unsubstituted heteroarylene having 3 to 30 carbon atoms, or a combination thereof, wherein y is, at each occurrence identically or differently, selected from 1, 2, 3, 4, or 5;
K₁ to K₄ are each independently selected from a single bond, O, or S;
X₁ to X₃ are each independently selected from C or N;
Rₙ represents, at each occurrence identically or differently, mono-substitution, multiple substitutions, or non-substitution;
R, R_{q}, and Rₙ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof, and
adjacent substituents R, R_{q}, Rₙ can be optionally joined to form a ring.

In this embodiment, the expression that “adjacent substituents R, R_{q}, Rₙ can be optionally joined to form a ring” is intended to mean that any one or more of groups of adjacent substituents, such as two substituents R_{q}, two substituents Rₙ, substituents R_{q} and Rₙ, and substituents R and Rₙ, can be joined to form a ring. Obviously, it is also possible that none of these groups of adjacent substituents are joined to form a ring.

According to an embodiment of the present disclosure, in Formula 3 or Formula 3-A, the ring F, the ring G, and the ring H are each independently selected from a five-membered unsaturated carbocyclic ring, an aromatic ring having 6 to 30 carbon atoms, or a heteroaromatic ring having 3 to 30 carbon atoms, and the ring I is, at each occurrence identically or differently, selected from an unsaturated heterocyclic ring having 3 to 30 carbon atoms.

According to an embodiment of the present disclosure, in Formula 3 or Formula 3-A, the ring F, the ring G, and the ring H are each independently selected from a five-membered unsaturated carbocyclic ring, an aromatic ring having 6 to 18 carbon atoms, or a heteroaromatic ring having 3 to 18 carbon atoms, and the ring I is, at each occurrence identically or differently, selected from an unsaturated heterocyclic ring having 3 to 18 carbon atoms.

According to an embodiment of the present disclosure, in Formula 3 or Formula 3-A, the ring F, the ring G, and the ring H are each independently selected from a benzene ring, a pyridine ring, an indene ring, a fluorene ring, an indole ring, a carbazole ring, a benzofuran ring, a dibenzofuran ring, a benzosilole ring, a dibenzosilole ring, a benzothiophene ring, a dibenzothiophene ring, a dibenzoselenophene ring, a cyclopentadienyl ring, a furan ring, a thiophene ring, or a silole ring, and the ring I is, at each occurrence identically or differently, selected from an imidazole-carbene ring or a benzimidazole-carbene ring.

According to an embodiment of the present disclosure, K₁ to K₄ are each selected from a single bond.

According to an embodiment of the present disclosure, the metal complex has a structure represented by one of Formula 3-1 to Formula 3-20:

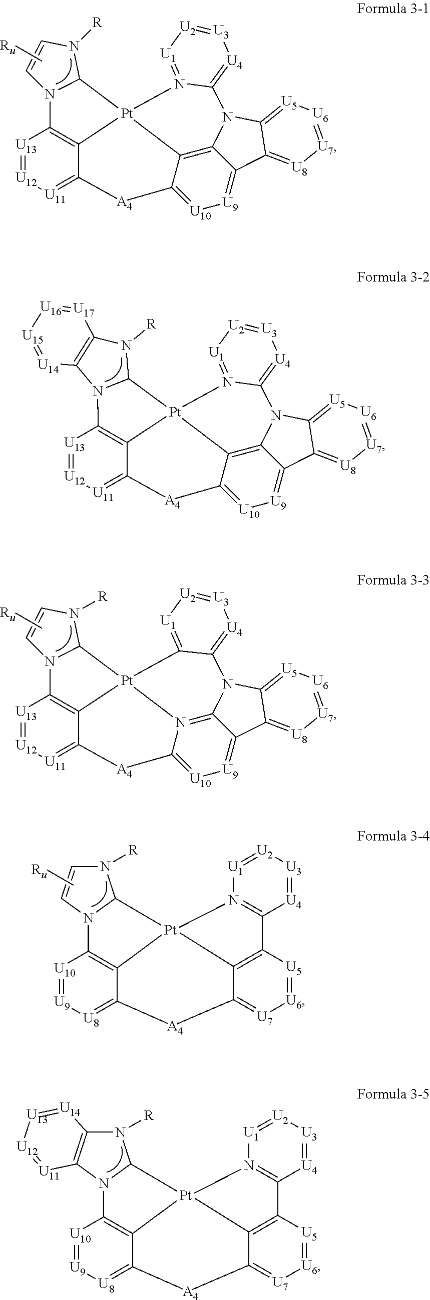

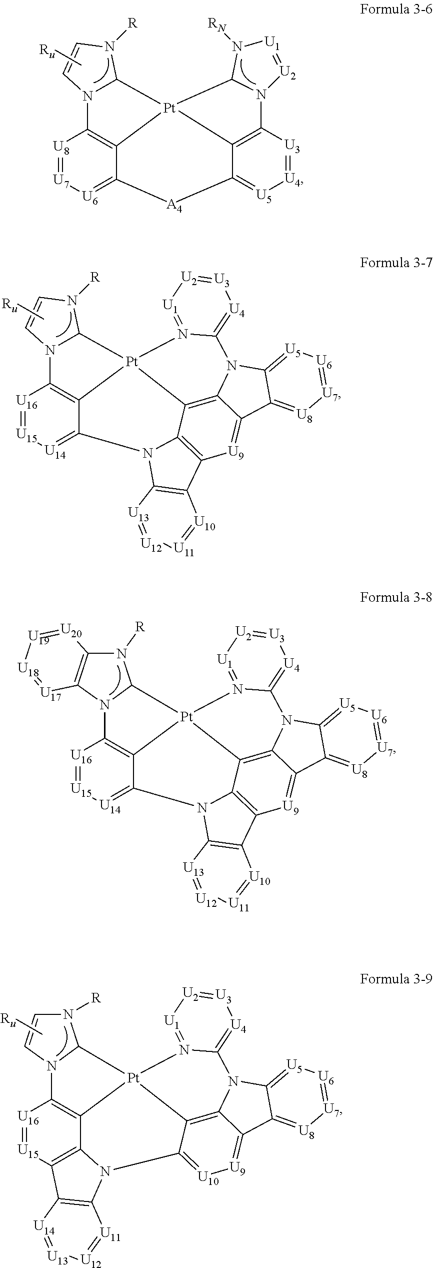

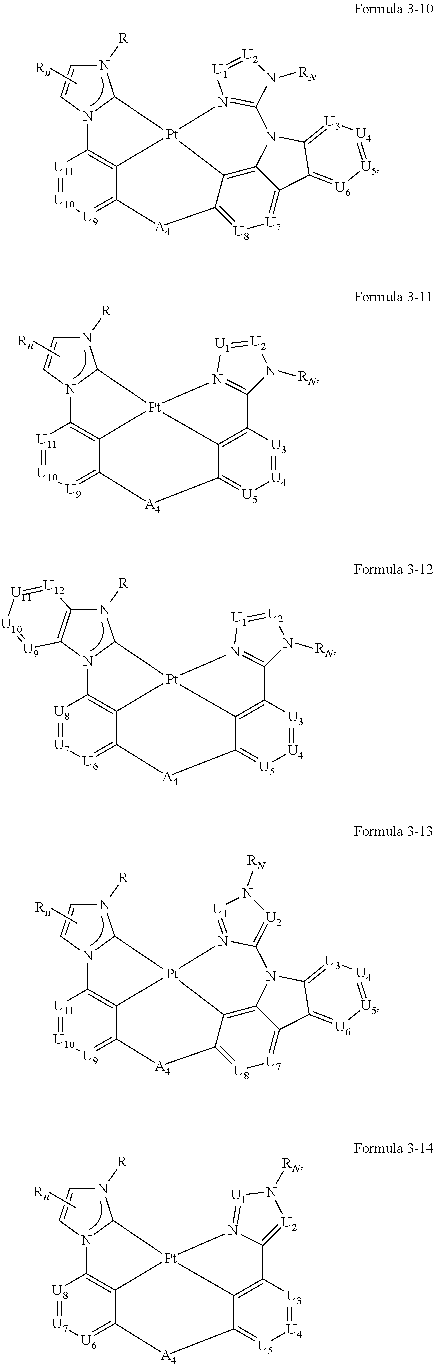

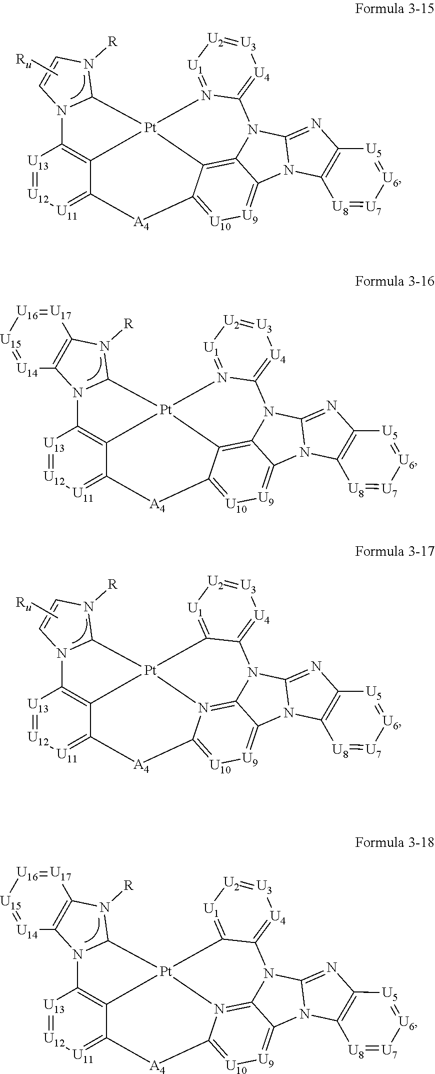

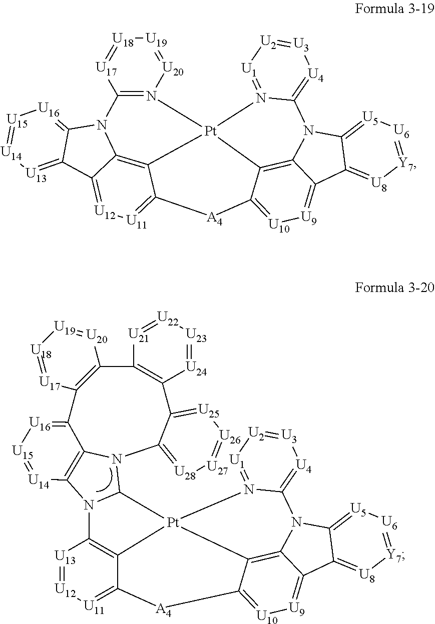

wherein
A₄ is, at each occurrence identically or differently, selected from a single bond, O, S, Se, (SiR_{q}R_{q})_{y}, PR_{q}, NR_{q}, substituted or unsubstituted arylene having 6 to 30 carbon atoms, substituted or unsubstituted heteroarylene having 3 to 30 carbon atoms, or a combination thereof, wherein y is, at each occurrence identically or differently, selected from 1, 2, or 3;
U₁ to U₂₉ are, at each occurrence identically or differently, selected from CRₙ or N;
Rᵤ represents, at each occurrence identically or differently, mono-substitution, multiple substitutions, or non-substitution;
R, R_{N}, R_{q}, Rᵤ, and Rₙ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof, and
adjacent substituents R, R_{N}, R_{q}, Rᵤ, and Rₙ can be optionally joined to form a ring.

In this embodiment, the expression that “adjacent substituents R, R_{N}, R_{q}, Rᵤ, and Rₙ can be optionally joined to form a ring” is intended to mean that any one or more of groups of adjacent substituents, such as two substituents R_{q}, two substituents Rᵤ, two substituents Rₙ, substituents R and Rᵤ, substituents R and Rₙ, substituents R_{N} and Rₙ, and substituents R_{q} and Rₙ, can be joined to form a ring. Obviously, it is also possible that none of these groups of adjacent substituents are joined to form a ring.

According to an embodiment of the present disclosure, the metal complex has a structure represented by Formula 3-1 or Formula 3-2.

According to an embodiment of the present disclosure, A₂ is selected from a single bond, O, or S.

According to an embodiment of the present disclosure, A₂ is selected from O.

According to an embodiment of the present disclosure, U₁ to U₂₉ are, at each occurrence identically or differently, selected from CRₙ, and Rₙ is, at each occurrence identically or differently, selected from the group consisting of: hydrogen, deuterium, halogen, cyano, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, and combinations thereof.

According to an embodiment of the present disclosure, Rₙ is, at each occurrence identically or differently, selected from the group consisting of: hydrogen, deuterium, fluorine, methyl, deuterated methyl, ethyl, n-propyl, isopropyl, cyclopropyl, n-butyl, isobutyl, t-butyl, cyclopentyl, cyclohexyl, phenyl, trimethylsilyl, carbazolyl, indolyl, benzofuryl, dibenzofuryl, benzosilolyl, dibenzosilolyl, benzothienyl, dibenzothienyl, dibenzoselenophenyl, and combinations thereof.

According to an embodiment of the present disclosure, the substituent R has a structure represented by Formula 4:

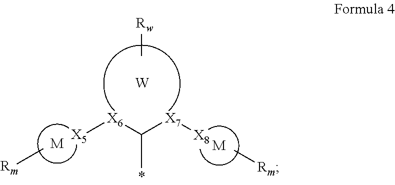

wherein in Formula 4,
the ring M and the ring W are, at each occurrence identically or differently, selected from an unsaturated carbocyclic ring having 5 to 30 carbon atoms, an unsaturated heterocyclic ring having 3 to 30 carbon atoms, or a combination thereof,
X₅ to X₈ are, at each occurrence identically or differently, selected from C or N;
“*” represents a position where Formula 4 is joined;
Rₘ and R_{w} represent, at each occurrence identically or differently, mono-substitution, multiple substitutions, or non-substitution;
Rₘ and R_{w} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof, and
adjacent substituents Rₘ, R_{w} can be optionally joined to form a ring.

In the present disclosure, the expression that “adjacent substituents Rₘ, R_{w} can be optionally joined to form a ring” is intended to mean that any one or more of groups of adjacent substituents, such as two substituents Rₘ, two substituents R_{w}, and substituents Rₘ and R_{w}, can be joined to form a ring. Obviously, it is also possible that none of these groups of adjacent substituents are joined to form a ring.

According to an embodiment of the present disclosure, the substituent R has a structure represented by Formula 4-1:

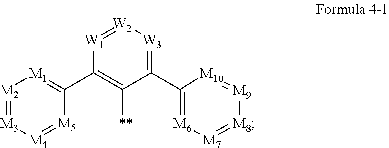

wherein in Formula 4-1,
M₁ to M₁₀ are each independently selected from CRₘ or N;
W₁ to W₃ are each independently selected from CR_{w} or N;
“**” represents a position where Formula 4-1 is joined;
Rₘ and R_{w} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof, and
adjacent substituents Rₘ, R_{w} can be optionally joined to form a ring.

According to an embodiment of the present disclosure, the substituent R is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

According to an embodiment of the present disclosure, in Formula 4 or Formula 4-1, at least one R_{w} is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

According to an embodiment of the present disclosure, M₁ to M₁₀ are each independently selected from CRₘ.

According to an embodiment of the present disclosure, W₁ to W₃ are each independently selected from CR_{w}.

According to an embodiment of the present disclosure, Rₘ and R_{w} are, at each occurrence identically or differently, selected from the group consisting of: hydrogen, deuterium, halogen, cyano, hydroxyl, sulfanyl, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, and combinations thereof.

According to an embodiment of the present disclosure, M₁ to M₁₀ are each selected from CH or CD.

According to an embodiment of the present disclosure, W₂ is selected from CR_{w}, and the R_{w} is selected from the group consisting of: deuterium, halogen, cyano, hydroxyl, sulfanyl, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, and combinations thereof.

According to an embodiment of the present disclosure, the metal complex has a structure represented by a general formula of Pt(Lₐ)(L_{b}), wherein Lₐ and L_{b} are a first ligand and a second ligand coordinated to the metal Pt, respectively. For example, for

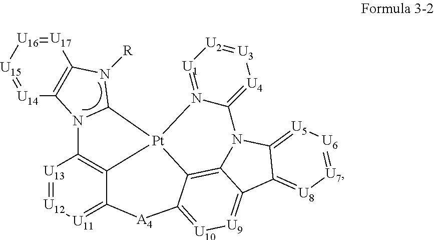

Lₐ has a structure represented by Formula A:

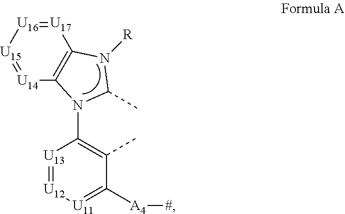

wherein “#” in Formula A represents a position where L_{b} is joined; and L_{b} has a structure represented by Formula B:

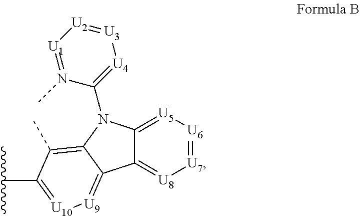

wherein “ [symbol] ” in Formula B represents a position where Lₐ is joined.

According to an embodiment of the present disclosure, the metal complex is selected from the group consisting of Compound BD1 to Compound BD18, wherein specific structures of Compound BD1 to Compound BD18 are shown in claim 18.

According to an embodiment of the present disclosure, the metal complex has a structure represented by Pt(Lₐ)(L_{b}), wherein Lₐ and L_{b} are a first ligand and a second ligand coordinated to the metal Pt, respectively, Lₐ is selected from the group consisting of Lₐ1-1 to Lₐ1-25 and Lₐ2-1 to Lₐ2-6, and L_{b} is selected from the group consisting of L_{b}1-1 to L_{b}1-8 and L_{b}2-1 to L_{b}2-22, wherein specific structures of Lₐ1-1 to Lₐ1-25, Lₐ2-1 to Lₐ2-6, L_{b}1-1 to L_{b}1-8, and L_{b}2-1 to L_{b}2-22 are shown in claim 18.

According to an embodiment of the present disclosure, the metal complex is selected from the group consisting of Compound Pt1 to Compound Pt81, Compound Pt1 to Compound Pt81 each have a structure represented by Pt(Lₐ)(L_{b}), and specific structures of Compound Pt1 to Compound Pt81 are shown in claim 18.

According to an embodiment of the present disclosure, a maximum emission wavelength λ_{max-PL-2} of a photoluminescence spectrum of the metal complex is 440 nm to 500 nm.

According to an embodiment of the present disclosure, the maximum emission wavelength λ_{max-PL-2} of the photoluminescence spectrum of the metal complex is 440 nm to 470 nm.

According to an embodiment of the present disclosure, the maximum emission wavelength λ_{max-PL-2} of the photoluminescence spectrum of the metal complex is 455 nm to 465 nm.

According to an embodiment of the present disclosure, a full width at half maximum FWHM-_{PL-2} of the photoluminescence spectrum of the metal complex is less than or equal to 45 nm.

According to an embodiment of the present disclosure, the full width at half maximum FWHM-_{PL-2} of the photoluminescence spectrum of the metal complex is less than or equal to 35 nm.

According to an embodiment of the present disclosure, the full width at half maximum FWHM-_{PL-2} of the photoluminescence spectrum of the metal complex is less than or equal to 30 nm.

According to an embodiment of the present disclosure, the full width at half maximum FWHM-_{PL-2} of the photoluminescence spectrum of the metal complex is less than or equal to 25 nm.

According to an embodiment of the present disclosure, the full width at half maximum FWHM-_{PL-2} of the photoluminescence spectrum of the metal complex is less than or equal to 20 nm.

According to an embodiment of the present disclosure, the organic layer is an emissive layer and the metal complex is a phosphorescent sensitizer.

According to an embodiment of the present disclosure, the emissive layer further comprises a first host compound and a second host compound.

According to an embodiment of the present disclosure, the first host compound and the second host compound are each independently selected from a compound comprising at least one chemical group selected from the group consisting of: benzene, pyridine, pyrimidine, triazine, carbazole, azacarbazole, indolocarbazole, dibenzothiophene, aza-dibenzothiophene, dibenzofuran, azadibenzofuran, dibenzoselenophene, triphenylene, azatriphenylene, fluorene, silafluorene, naphthalene, quinoline, isoquinoline, quinazoline, quinoxaline, phenanthrene, azaphenanthrene, and combinations thereof.

According to an embodiment of the present disclosure, the first host compound has a structure represented by one of Formula 5 to Formula 7:

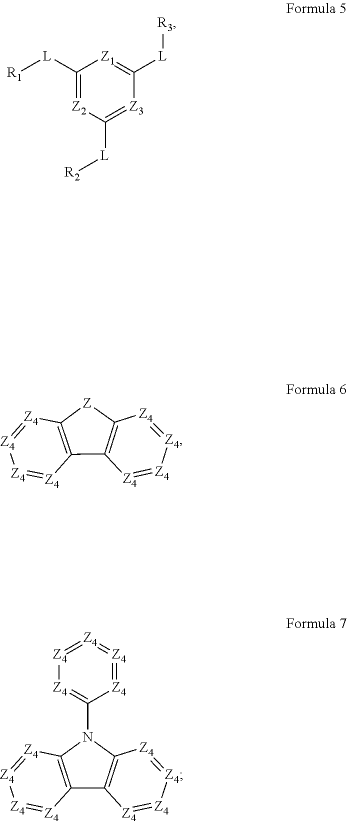

wherein in Formula 5, Z₁ to Z₃ are, at each occurrence identically or differently, selected from CR₄ or N, and at least one of Z₁ to Z₃ is N;
L is, at each occurrence identically or differently, selected from the group consisting of: a single bond, substituted or unsubstituted arylene having 6 to 30 carbon atoms, substituted or unsubstituted heteroarylene having 3 to 30 carbon atoms, and combinations thereof,
in Formula 6 and Formula 7, Z₄ is, at each occurrence identically or differently, selected from CR₄ or N, and at least one Z₄ is N;
Z is, at each occurrence identically or differently, selected from O or S;
R₁ to R₄ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
adjacent substituents R₄ can be optionally joined to form a ring.

In the present disclosure, the expression that “adjacent substituents R₄ can be optionally joined to form a ring” is intended to mean that two adjacent substituents R₄ can be joined to form a ring. Obviously, it is also possible that two adjacent substituents R₄ are not joined to form a ring.

According to an embodiment of the present disclosure, the first host compound has a structure represented by Formula 5-1 or Formula 6-1:

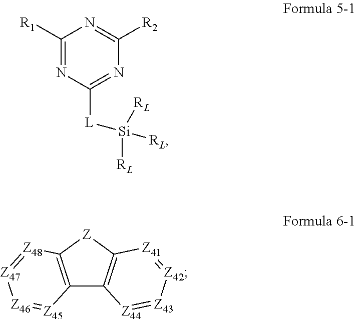

wherein in Formula 5-1,
R₁ and R₂ are each independently selected from substituted or unsubstituted heteroaryl having 3 to 30 carbon atoms;
L is selected from a single bond, substituted or unsubstituted arylene having 6 to 30 carbon atoms, substituted or unsubstituted heteroarylene having 3 to 30 carbon atoms, or a combination thereof,
in Formula 6-1,
Z is selected from O or S;
Z₄₁ to Z₄₈ are, at each occurrence identically or differently, selected from CR₄, CR₄′, or N, at least one of Z₄₁ to Z₄₈ is selected from N, and at least one of Z₄₁ to Z₄₈ is selected from CR₄′;
R₄′ is, at each occurrence identically or differently, selected from substituted or unsubstituted aryl having 6 to 30 carbon atoms, substituted or unsubstituted heteroaryl having 3 to 30 carbon atoms, or a combination thereof,
R_{L} and R₄ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof, and
adjacent substituents R₄ can be optionally joined to form a ring.

According to an embodiment of the present disclosure, L is, at each occurrence identically or differently, selected from the group consisting of: a single bond, substituted or unsubstituted arylene having 6 to 18 carbon atoms, substituted or unsubstituted heteroarylene having 3 to 18 carbon atoms, and combinations thereof.

According to an embodiment of the present disclosure, L is, at each occurrence identically or differently, selected from the group consisting of: a single bond, phenylene, biphenylylene, fluorenylene, triphenylenylene, furylene, thienylene, dibenzofurylene, dibenzothienylene, and combinations thereof.

According to an embodiment of the present disclosure, R_{L} is, at each occurrence identically or differently, selected from the group consisting of: substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, and combinations thereof.

According to an embodiment of the present disclosure, R_{L} is, at each occurrence identically or differently, selected from substituted or unsubstituted aryl having 6 to 30 carbon atoms.

According to an embodiment of the present disclosure, R_{L} is, at each occurrence identically or differently, selected from the group consisting of: phenyl, biphenyl, triphenylenyl, indenyl, fluorenyl, indolyl, carbazolyl, benzofuryl, dibenzofuryl, benzosilolyl, dibenzosilolyl, benzothienyl, dibenzothienyl, dibenzoselenophenyl, and combinations thereof.

According to an embodiment of the present disclosure, R₁ to R₄ are, at each occurrence identically or differently, selected from the group consisting of: hydrogen, deuterium, halogen, cyano, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, and combinations thereof.

According to an embodiment of the present disclosure, R₁ to R₄ are, at each occurrence identically or differently, selected from the group consisting of: hydrogen, deuterium, halogen, cyano, substituted or unsubstituted aryl having 6 to 18 carbon atoms, substituted or unsubstituted heteroaryl having 3 to 18 carbon atoms, and combinations thereof.

According to an embodiment of the present disclosure, R₁ to R₄ are, at each occurrence identically or differently, selected from the group consisting of: hydrogen, deuterium, fluorine, cyano, phenyl, biphenyl, triphenylenyl, indenyl, fluorenyl, indolyl, carbazolyl, benzofuryl, dibenzofuryl, benzosilolyl, dibenzosilolyl, benzothienyl, dibenzothienyl, dibenzoselenophenyl, triazinyl, and combinations thereof.

According to an embodiment of the present disclosure, in Formula 6-1, at least one of Z₄₁ to Z₄₈ is selected from N, and at least two of Z₄₁ to Z₄₈ are selected from CR₄′.

According to an embodiment of the present disclosure, in Formula 6-1, only one of Z₄₁ to Z₄₈ is selected from N, and only two of Z₄₁ to Z₄₈ are selected from CR₄′.

According to an embodiment of the present disclosure, in Formula 6-1, Z₄₂ is selected from N, and Z₄₁ and Z₄₆ are selected from CR₄′.

According to an embodiment of the present disclosure, the first host compound is selected from the group consisting of Compound N-1-1 to Compound N-1-60, Compound N-2-1 to Compound N-2-35, and Compound N-3-1 to Compound N-3-9:

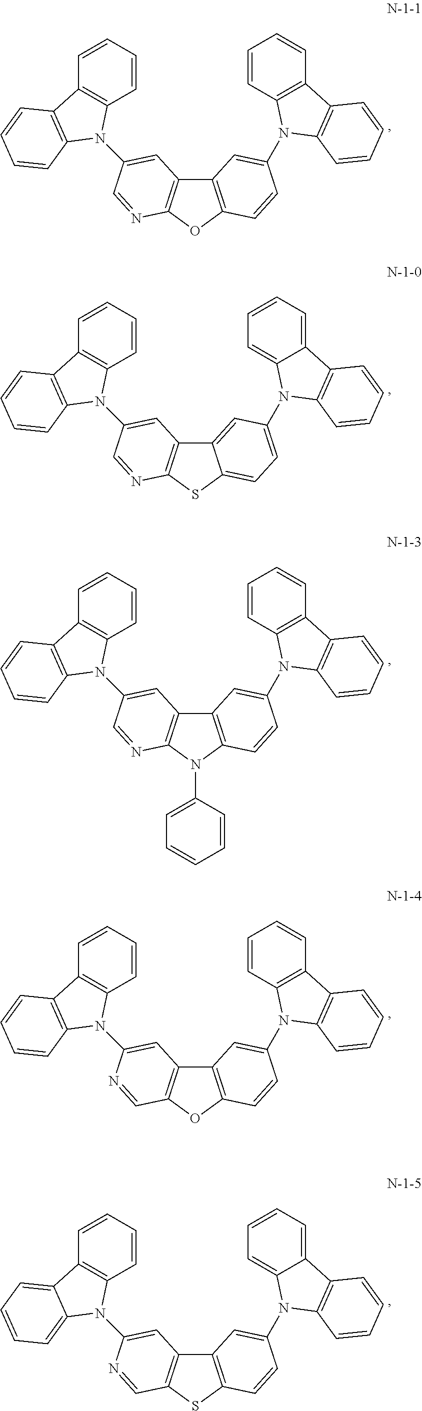 [SMILES: c1ccc2c(c1)c1ccccc1n2-c1ccc2oc3ncc(-n4c5ccccc5c5ccccc54)cc3c2c1 ; c1ccc2c(c1)c1ccccc1n2-c1ccc2sc3ncc(-n4c5ccccc5c5ccccc54)cc3c2c1 ; c1ccc(-n2c3ccc(-n4c5ccccc5c5ccccc54)cc3c3cc(-n4c5ccccc5c5ccccc54)cnc32)cc1 ; c1ccc2c(c1)c1ccccc1n2-c1ccc2oc3cnc(-n4c5ccccc5c5ccccc54)cc3c2c1 ; c1ccc2c(c1)c1ccccc1n2-c1ccc2sc3cnc(-n4c5ccccc5c5ccccc54)cc3c2c1]

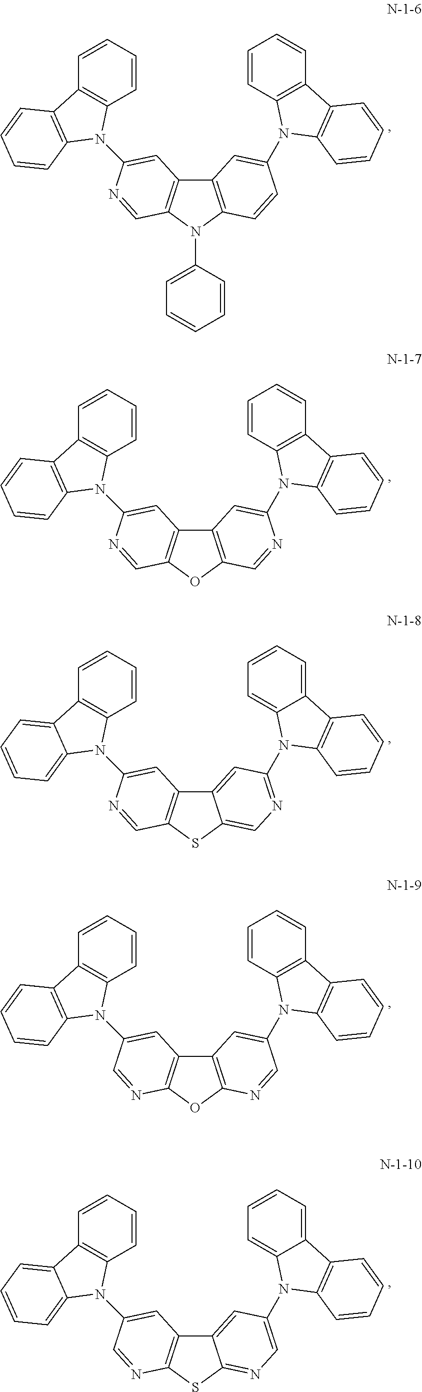 [SMILES: c1ccc(-n2c3ccc(-n4c5ccccc5c5ccccc54)cc3c3cc(-n4c5ccccc5c5ccccc54)ncc32)cc1 ; c1ccc2c(c1)c1ccccc1n2-c1cc2c(cn1)oc1cnc(-n3c4ccccc4c4ccccc43)cc12 ; c1ccc2c(c1)c1ccccc1n2-c1cc2c(cn1)sc1cnc(-n3c4ccccc4c4ccccc43)cc12 ; c1ccc2c(c1)c1ccccc1n2-c1cnc2oc3ncc(-n4c5ccccc5c5ccccc54)cc3c2c1 ; c1ccc2c(c1)c1ccccc1n2-c1cnc2sc3ncc(-n4c5ccccc5c5ccccc54)cc3c2c1]

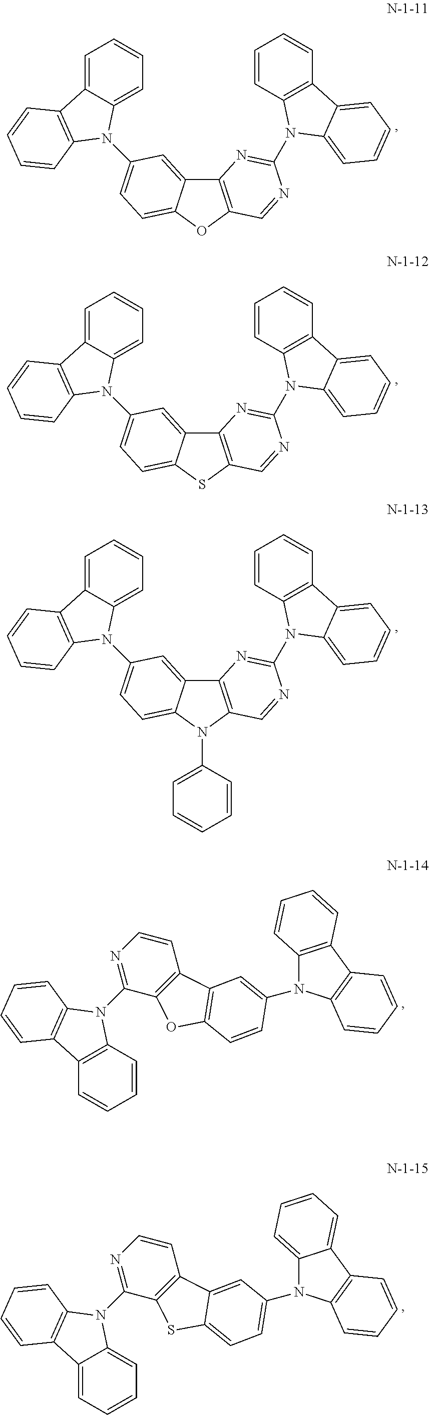 [SMILES: c1ccc2c(c1)c1ccccc1n2-c1ccc2oc3cnc(-n4c5ccccc5c5ccccc54)nc3c2c1 ; c1ccc2c(c1)c1ccccc1n2-c1ccc2sc3cnc(-n4c5ccccc5c5ccccc54)nc3c2c1 ; c1ccc(-n2c3ccc(-n4c5ccccc5c5ccccc54)cc3c3nc(-n4c5ccccc5c5ccccc54)ncc32)cc1 ; c1ccc2c(c1)c1ccccc1n2-c1ccc2oc3c(-n4c5ccccc5c5ccccc54)nccc3c2c1 ; c1ccc2c(c1)c1ccccc1n2-c1ccc2sc3c(-n4c5ccccc5c5ccccc54)nccc3c2c1]

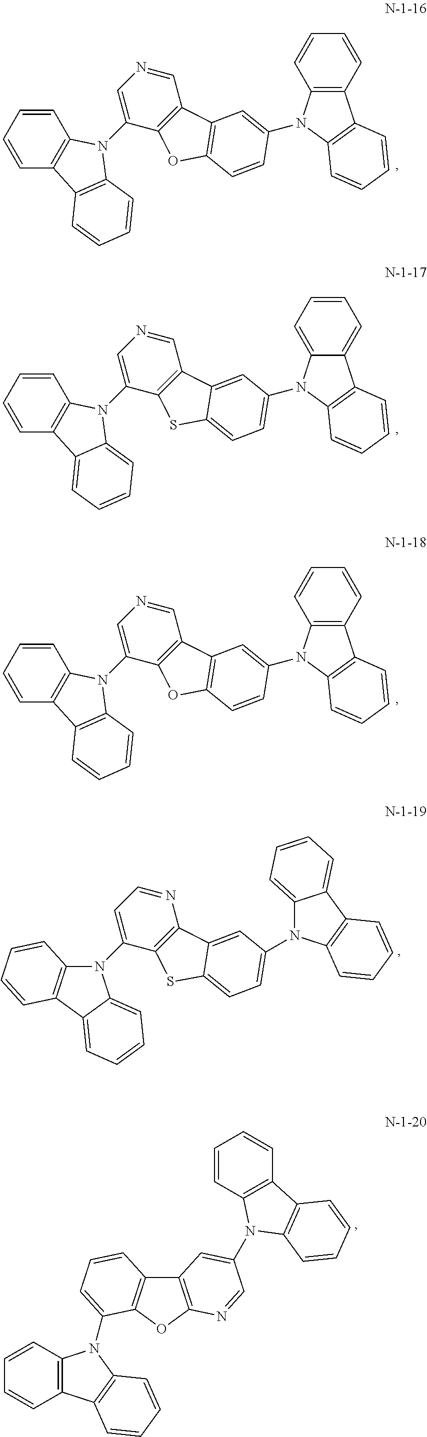 [SMILES: c1ccc2c(c1)c1ccccc1n2-c1ccc2oc3c(-n4c5ccccc5c5ccccc54)cncc3c2c1 ; c1ccc2c(c1)c1ccccc1n2-c1ccc2sc3c(-n4c5ccccc5c5ccccc54)cncc3c2c1 ; c1ccc2c(c1)c1ccccc1n2-c1ccc2oc3c(-n4c5ccccc5c5ccccc54)cncc3c2c1 ; c1ccc2c(c1)c1ccccc1n2-c1ccc2sc3c(-n4c5ccccc5c5ccccc54)ccnc3c2c1 ; c1cc(-n2c3ccccc3c3ccccc32)c2oc3ncc(-n4c5ccccc5c5ccccc54)cc3c2c1]

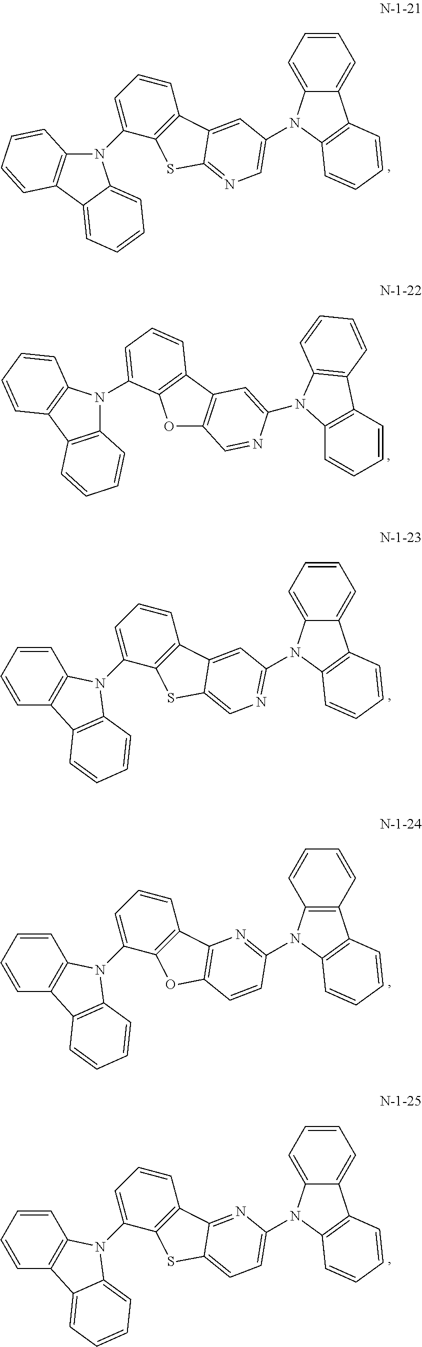 [SMILES: c1cc(-n2c3ccccc3c3ccccc32)c2sc3ncc(-n4c5ccccc5c5ccccc54)cc3c2c1 ; c1cc(-n2c3ccccc3c3ccccc32)c2oc3cnc(-n4c5ccccc5c5ccccc54)cc3c2c1 ; c1cc(-n2c3ccccc3c3ccccc32)c2sc3cnc(-n4c5ccccc5c5ccccc54)cc3c2c1 ; c1cc(-n2c3ccccc3c3ccccc32)c2oc3ccc(-n4c5ccccc5c5ccccc54)nc3c2c1 ; c1cc(-n2c3ccccc3c3ccccc32)c2sc3ccc(-n4c5ccccc5c5ccccc54)nc3c2c1]

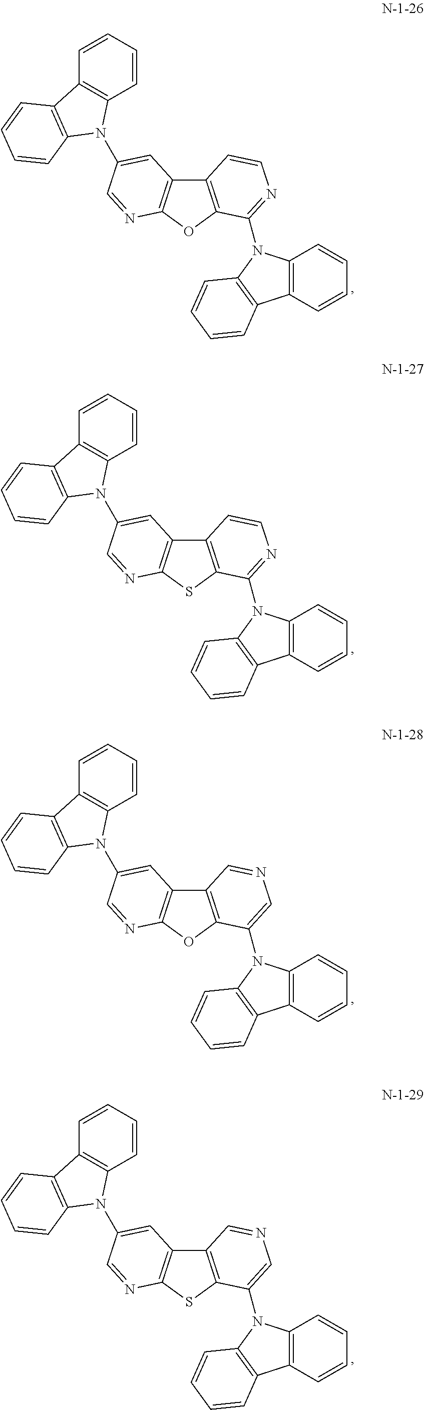 [SMILES: c1ccc2c(c1)c1ccccc1n2-c1cnc2oc3c(-n4c5ccccc5c5ccccc54)nccc3c2c1 ; c1ccc2c(c1)c1ccccc1n2-c1cnc2sc3c(-n4c5ccccc5c5ccccc54)nccc3c2c1 ; c1ccc2c(c1)c1ccccc1n2-c1cnc2oc3c(-n4c5ccccc5c5ccccc54)cncc3c2c1 ; c1ccc2c(c1)c1ccccc1n2-c1cnc2sc3c(-n4c5ccccc5c5ccccc54)cncc3c2c1]

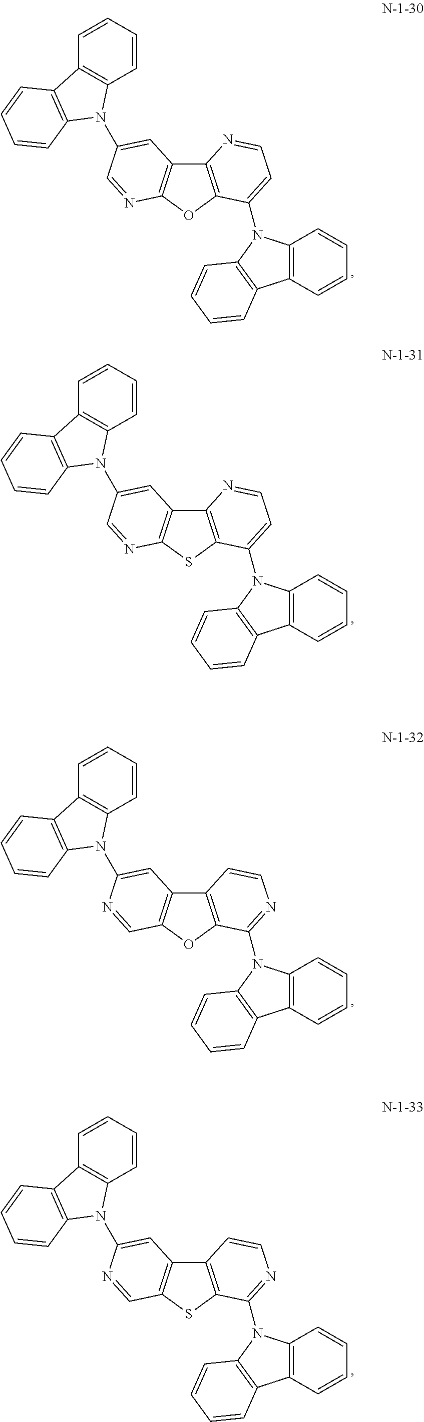 [SMILES: c1ccc2c(c1)c1ccccc1n2-c1cnc2oc3c(-n4c5ccccc5c5ccccc54)ccnc3c2c1 ; c1ccc2c(c1)c1ccccc1n2-c1cnc2sc3c(-n4c5ccccc5c5ccccc54)ccnc3c2c1 ; c1ccc2c(c1)c1ccccc1n2-c1cc2c(cn1)oc1c(-n3c4ccccc4c4ccccc43)nccc12 ; c1ccc2c(c1)c1ccccc1n2-c1cc2c(cn1)sc1c(-n3c4ccccc4c4ccccc43)nccc12]

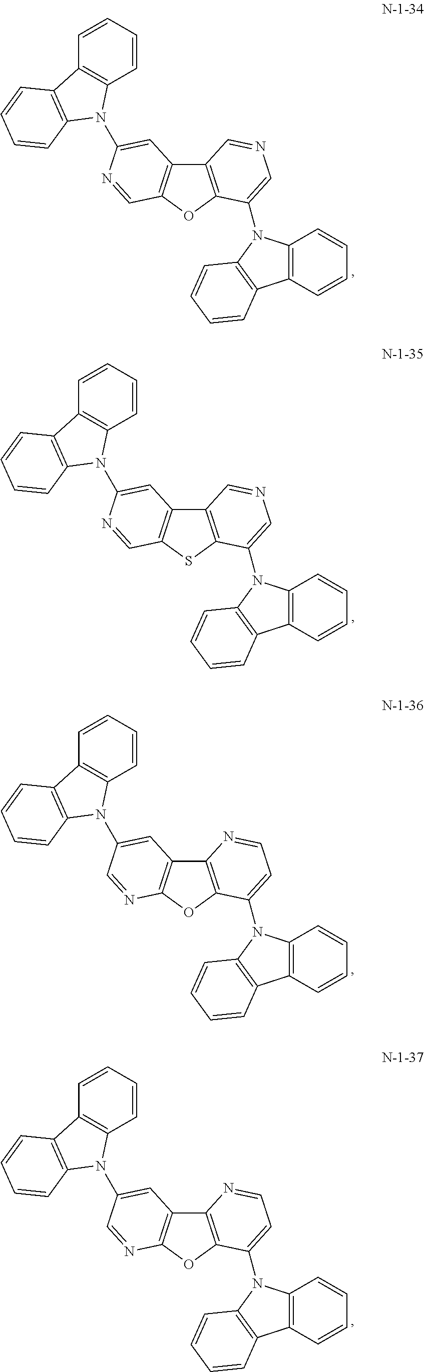 [SMILES: c1ccc2c(c1)c1ccccc1n2-c1cc2c(cn1)oc1c(-n3c4ccccc4c4ccccc43)cncc12 ; c1ccc2c(c1)c1ccccc1n2-c1cc2c(cn1)sc1c(-n3c4ccccc4c4ccccc43)cncc12 ; c1ccc2c(c1)c1ccccc1n2-c1cnc2oc3c(-n4c5ccccc5c5ccccc54)ccnc3c2c1 ; c1ccc2c(c1)c1ccccc1n2-c1cnc2oc3c(-n4c5ccccc5c5ccccc54)ccnc3c2c1]

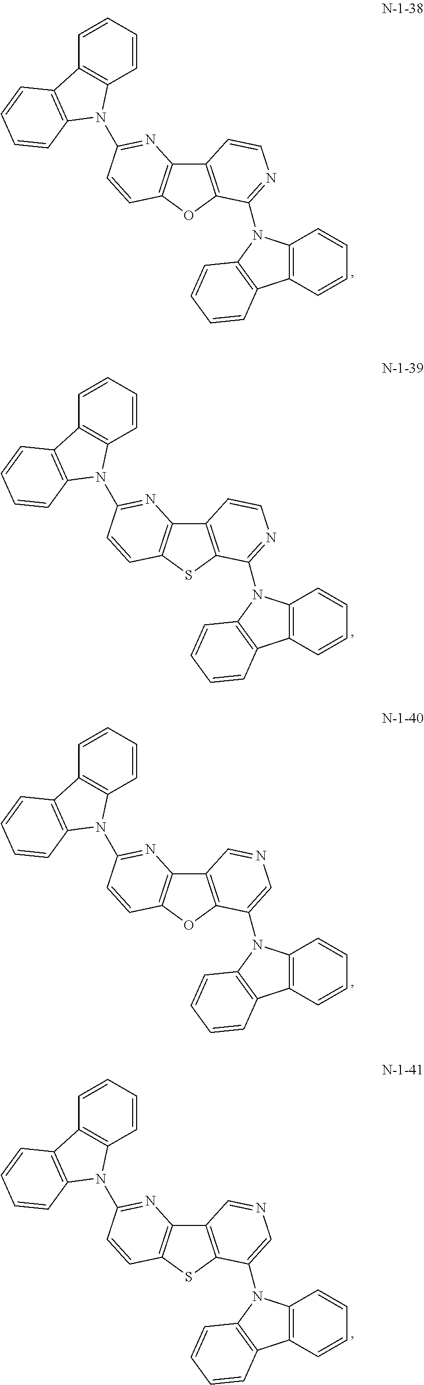 [SMILES: c1ccc2c(c1)c1ccccc1n2-c1ccc2oc3c(-n4c5ccccc5c5ccccc54)nccc3c2n1 ; c1ccc2c(c1)c1ccccc1n2-c1ccc2sc3c(-n4c5ccccc5c5ccccc54)nccc3c2n1 ; c1ccc2c(c1)c1ccccc1n2-c1ccc2oc3c(-n4c5ccccc5c5ccccc54)cncc3c2n1 ; c1ccc2c(c1)c1ccccc1n2-c1ccc2sc3c(-n4c5ccccc5c5ccccc54)cncc3c2n1]

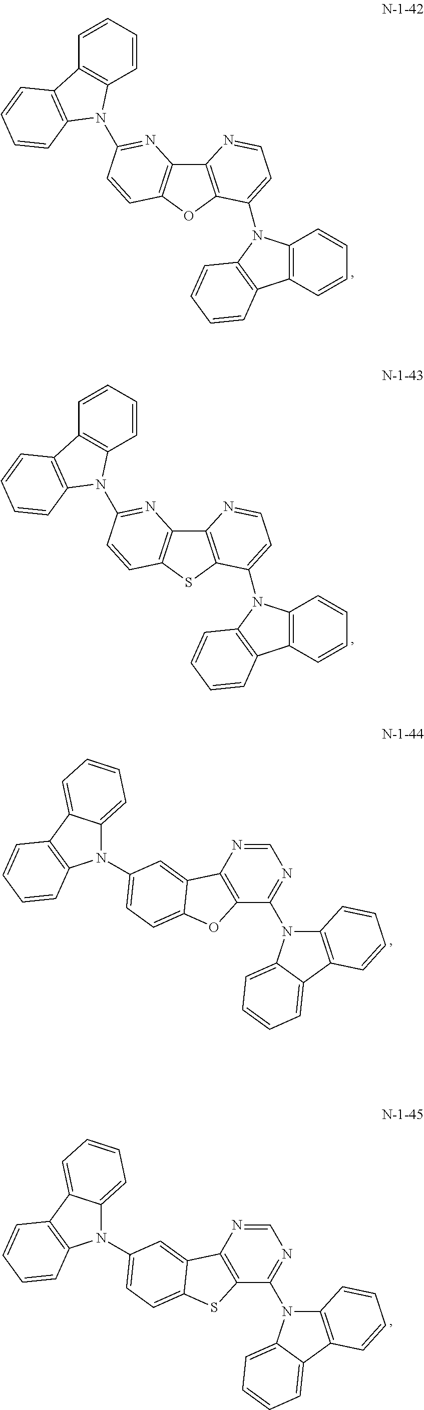 [SMILES: c1ccc2c(c1)c1ccccc1n2-c1ccc2oc3c(-n4c5ccccc5c5ccccc54)ccnc3c2n1 ; c1ccc2c(c1)c1ccccc1n2-c1ccc2sc3c(-n4c5ccccc5c5ccccc54)ccnc3c2n1 ; c1ccc2c(c1)c1ccccc1n2-c1ccc2oc3c(-n4c5ccccc5c5ccccc54)ncnc3c2c1 ; c1ccc2c(c1)c1ccccc1n2-c1ccc2sc3c(-n4c5ccccc5c5ccccc54)ncnc3c2c1]

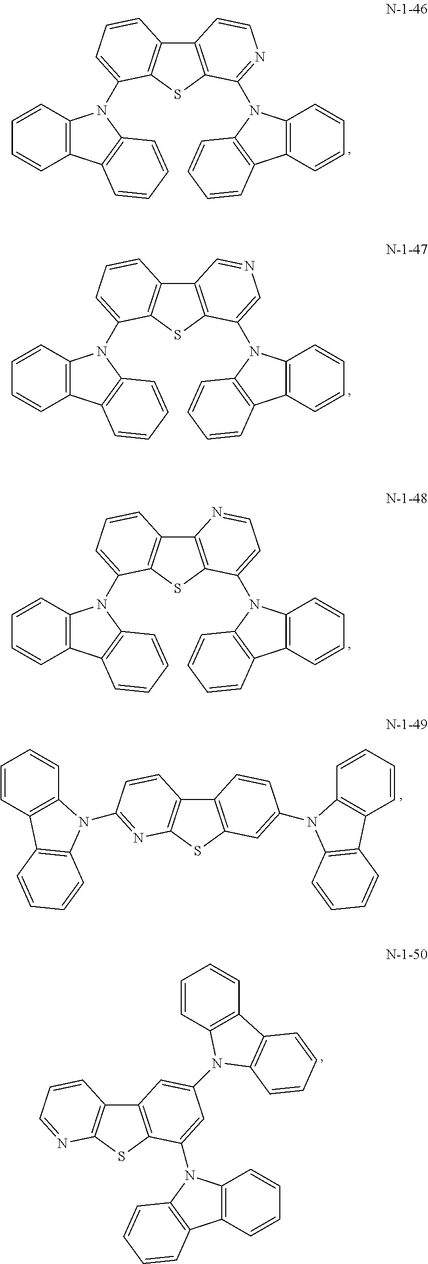 [SMILES: c1cc(-n2c3ccccc3c3ccccc32)c2sc3c(-n4c5ccccc5c5ccccc54)nccc3c2c1 ; c1cc(-n2c3ccccc3c3ccccc32)c2sc3c(-n4c5ccccc5c5ccccc54)cncc3c2c1 ; c1cc(-n2c3ccccc3c3ccccc32)c2sc3c(-n4c5ccccc5c5ccccc54)ccnc3c2c1 ; c1ccc2c(c1)c1ccccc1n2-c1ccc2c(c1)sc1nc(-n3c4ccccc4c4ccccc43)ccc12 ; c1cnc2sc3c(-n4c5ccccc5c5ccccc54)cc(-n4c5ccccc5c5ccccc54)cc3c2c1]

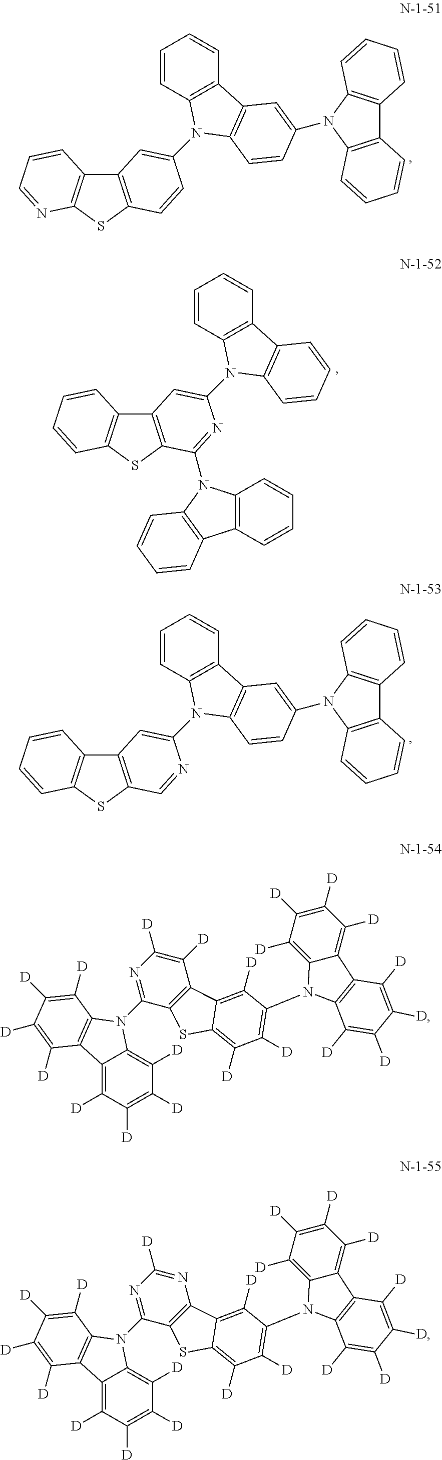

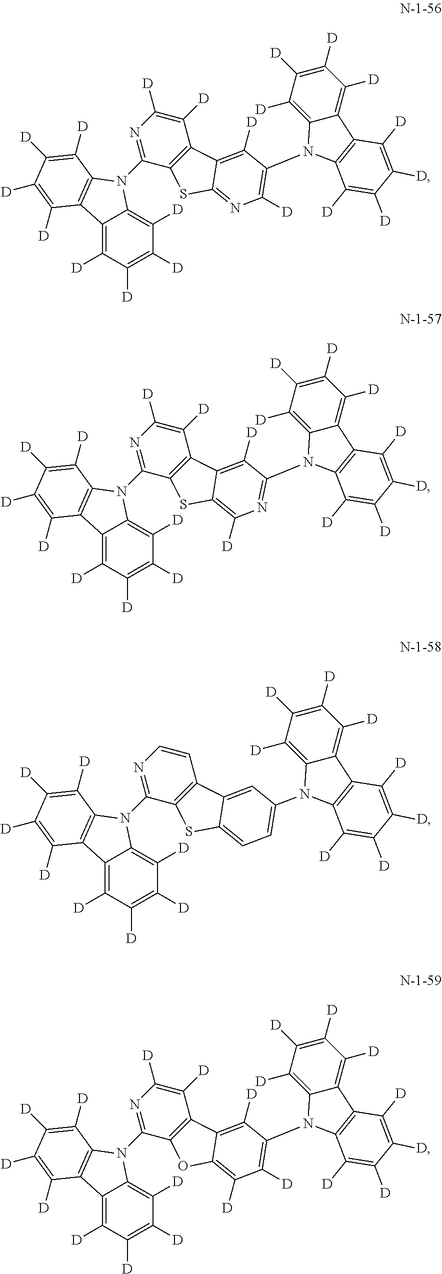

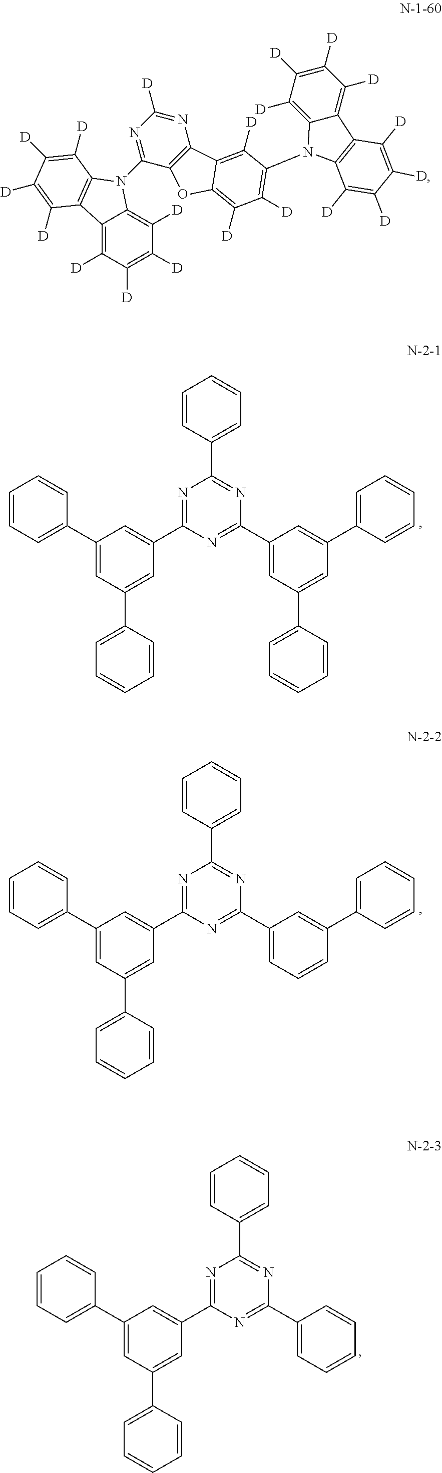

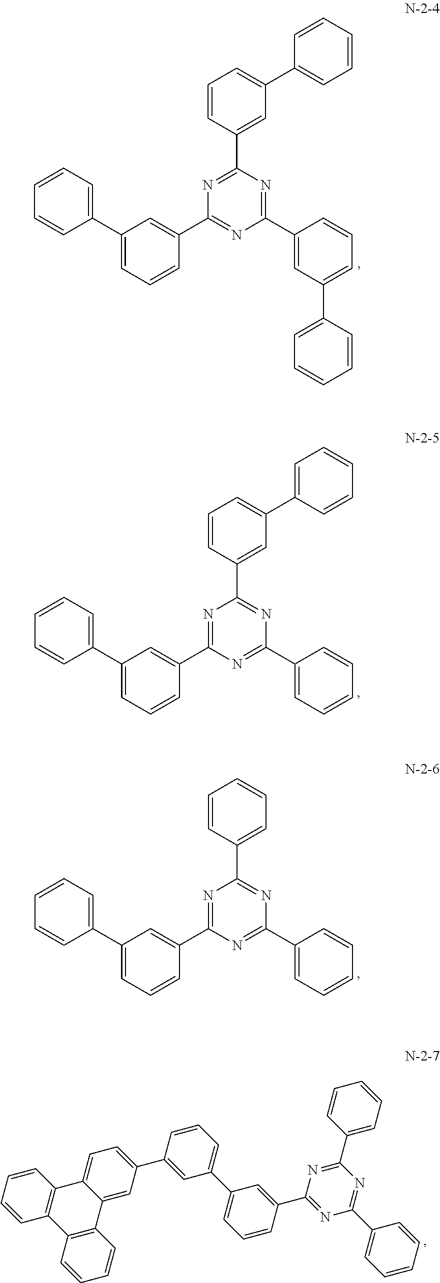 [SMILES: c1ccc(-c2cccc(-c3nc(-c4cccc(-c5ccccc5)c4)nc(-c4cccc(-c5ccccc5)c4)n3)c2)cc1 ; c1ccc(-c2cccc(-c3nc(-c4ccccc4)nc(-c4cccc(-c5ccccc5)c4)n3)c2)cc1 ; c1ccc(-c2cccc(-c3nc(-c4ccccc4)nc(-c4ccccc4)n3)c2)cc1 ; c1ccc(-c2nc(-c3ccccc3)nc(-c3cccc(-c4cccc(-c5ccc6c7ccccc7c7ccccc7c6c5)c4)c3)n2)cc1]

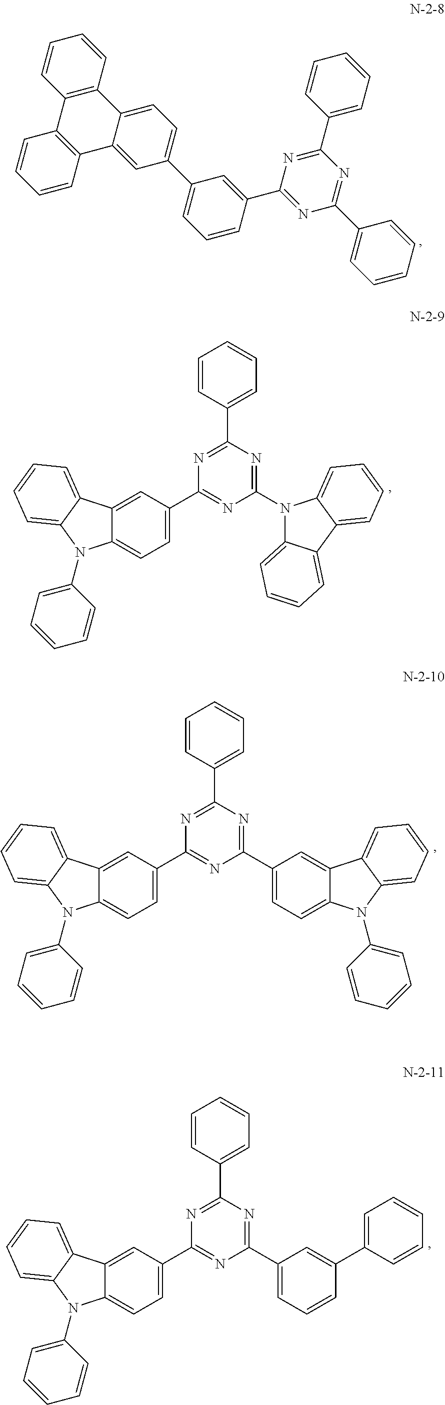 [SMILES: c1ccc(-c2nc(-c3ccccc3)nc(-c3cccc(-c4ccc5c6ccccc6c6ccccc6c5c4)c3)n2)cc1 ; c1ccc(-c2nc(-c3ccc4c(c3)c3ccccc3n4-c3ccccc3)nc(-n3c4ccccc4c4ccccc43)n2)cc1 ; c1ccc(-c2nc(-c3ccc4c(c3)c3ccccc3n4-c3ccccc3)nc(-c3ccc4c(c3)c3ccccc3n4-c3ccccc3)n2)cc1 ; c1ccc(-c2cccc(-c3nc(-c4ccccc4)nc(-c4ccc5c(c4)c4ccccc4n5-c4ccccc4)n3)c2)cc1]

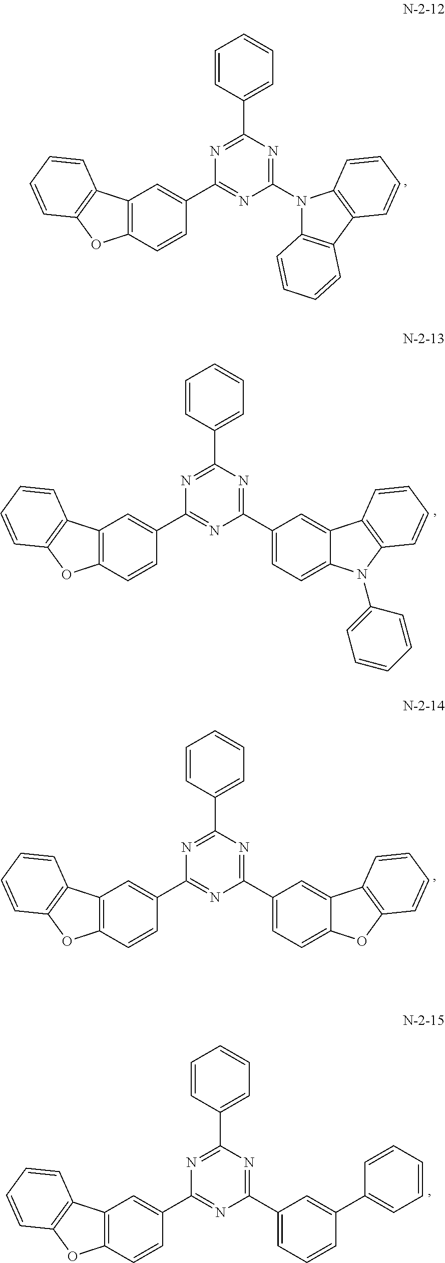 [SMILES: c1ccc(-c2nc(-c3ccc4oc5ccccc5c4c3)nc(-n3c4ccccc4c4ccccc43)n2)cc1 ; c1ccc(-c2nc(-c3ccc4oc5ccccc5c4c3)nc(-c3ccc4c(c3)c3ccccc3n4-c3ccccc3)n2)cc1 ; c1ccc(-c2nc(-c3ccc4oc5ccccc5c4c3)nc(-c3ccc4oc5ccccc5c4c3)n2)cc1 ; c1ccc(-c2cccc(-c3nc(-c4ccccc4)nc(-c4ccc5oc6ccccc6c5c4)n3)c2)cc1]

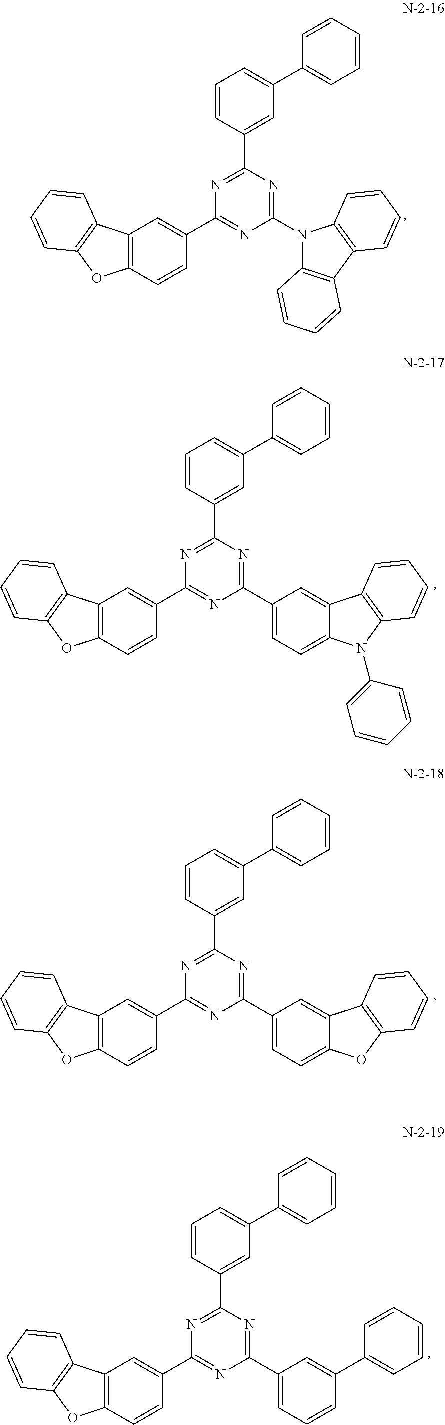 [SMILES: c1ccc(-c2cccc(-c3nc(-c4ccc5oc6ccccc6c5c4)nc(-n4c5ccccc5c5ccccc54)n3)c2)cc1 ; c1ccc(-c2cccc(-c3nc(-c4ccc5oc6ccccc6c5c4)nc(-c4ccc5c(c4)c4ccccc4n5-c4ccccc4)n3)c2)cc1 ; c1ccc(-c2cccc(-c3nc(-c4ccc5oc6ccccc6c5c4)nc(-c4ccc5oc6ccccc6c5c4)n3)c2)cc1 ; c1ccc(-c2cccc(-c3nc(-c4cccc(-c5ccccc5)c4)nc(-c4ccc5oc6ccccc6c5c4)n3)c2)cc1]

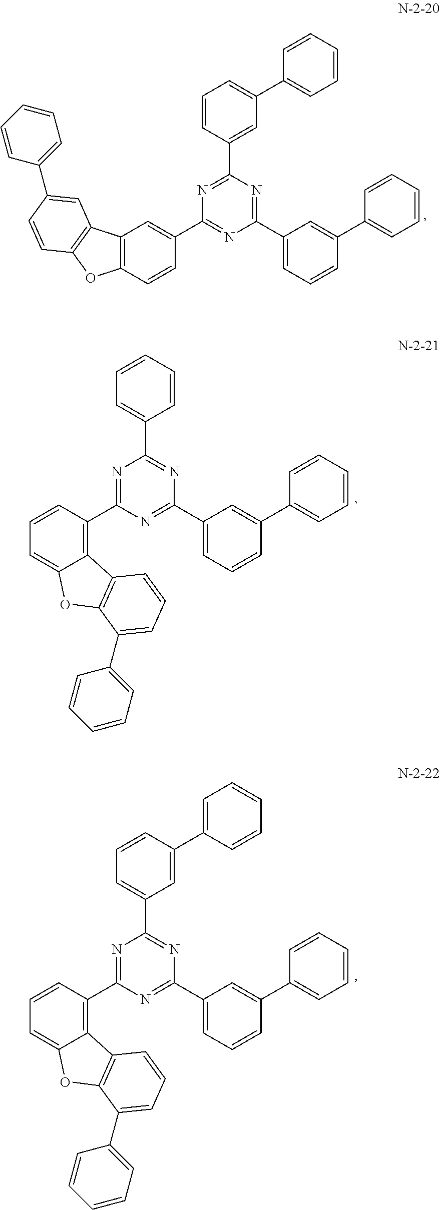 [SMILES: c1ccc(-c2cccc(-c3nc(-c4cccc(-c5ccccc5)c4)nc(-c4ccc5oc6ccc(-c7ccccc7)cc6c5c4)n3)c2)cc1 ; c1ccc(-c2cccc(-c3nc(-c4ccccc4)nc(-c4cccc5oc6c(-c7ccccc7)cccc6c45)n3)c2)cc1 ; c1ccc(-c2cccc(-c3nc(-c4cccc(-c5ccccc5)c4)nc(-c4cccc5oc6c(-c7ccccc7)cccc6c45)n3)c2)cc1]

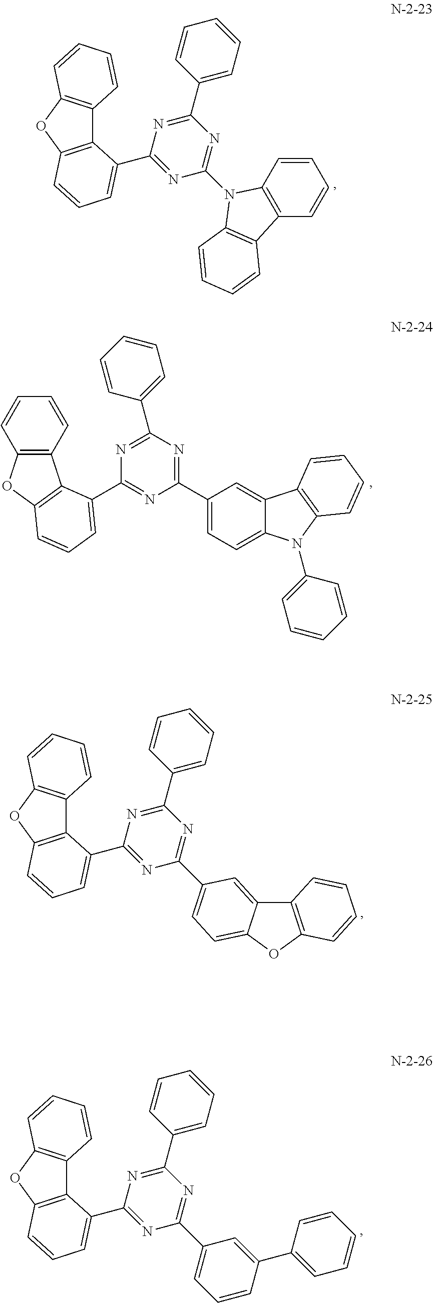 [SMILES: c1ccc(-c2nc(-c3cccc4oc5ccccc5c34)nc(-n3c4ccccc4c4ccccc43)n2)cc1 ; c1ccc(-c2nc(-c3ccc4c(c3)c3ccccc3n4-c3ccccc3)nc(-c3cccc4oc5ccccc5c34)n2)cc1 ; c1ccc(-c2nc(-c3ccc4oc5ccccc5c4c3)nc(-c3cccc4oc5ccccc5c34)n2)cc1 ; c1ccc(-c2cccc(-c3nc(-c4ccccc4)nc(-c4cccc5oc6ccccc6c45)n3)c2)cc1]

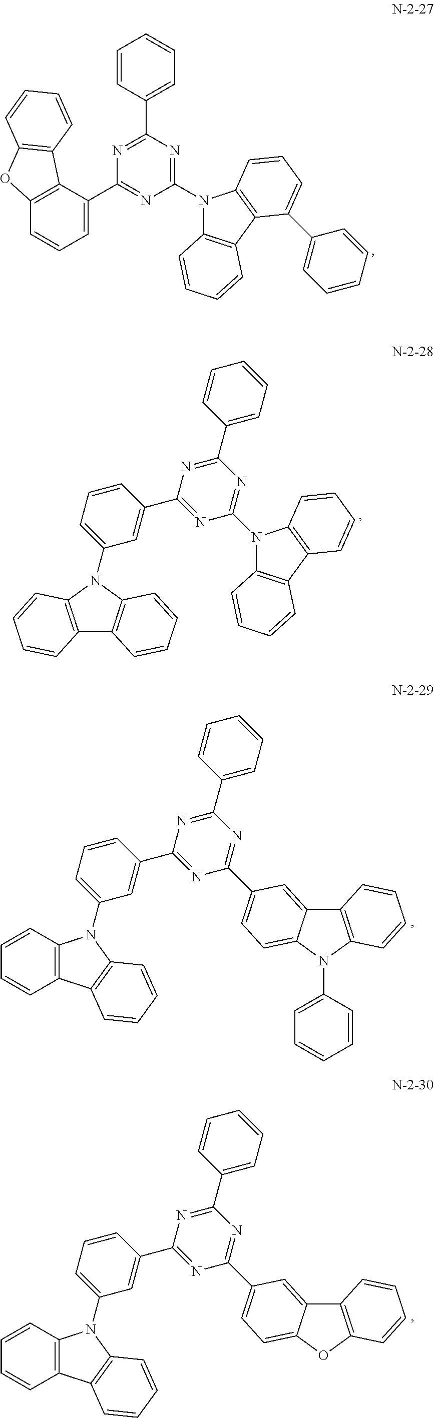 [SMILES: c1ccc(-c2nc(-c3cccc4oc5ccccc5c34)nc(-n3c4ccccc4c4c(-c5ccccc5)cccc43)n2)cc1 ; c1ccc(-c2nc(-c3cccc(-n4c5ccccc5c5ccccc54)c3)nc(-n3c4ccccc4c4ccccc43)n2)cc1 ; c1ccc(-c2nc(-c3cccc(-n4c5ccccc5c5ccccc54)c3)nc(-c3ccc4c(c3)c3ccccc3n4-c3ccccc3)n2)cc1 ; c1ccc(-c2nc(-c3cccc(-n4c5ccccc5c5ccccc54)c3)nc(-c3ccc4oc5ccccc5c4c3)n2)cc1]

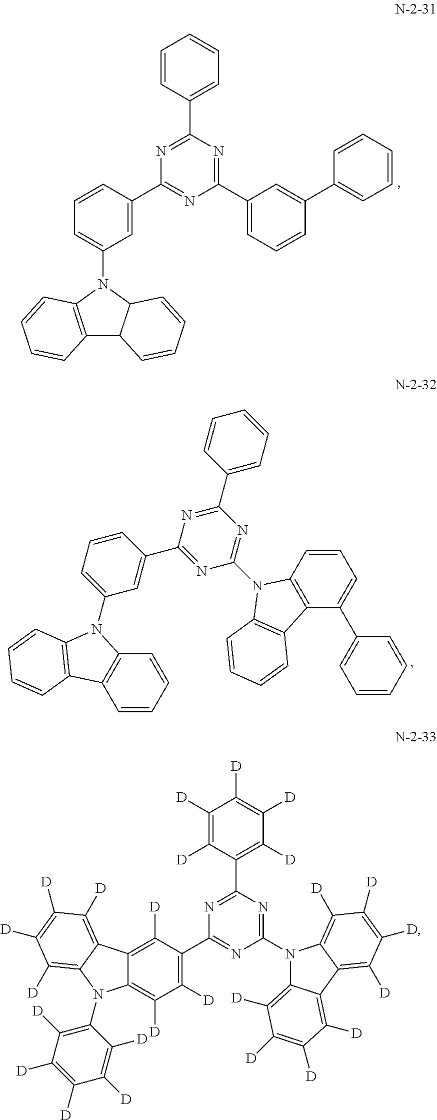

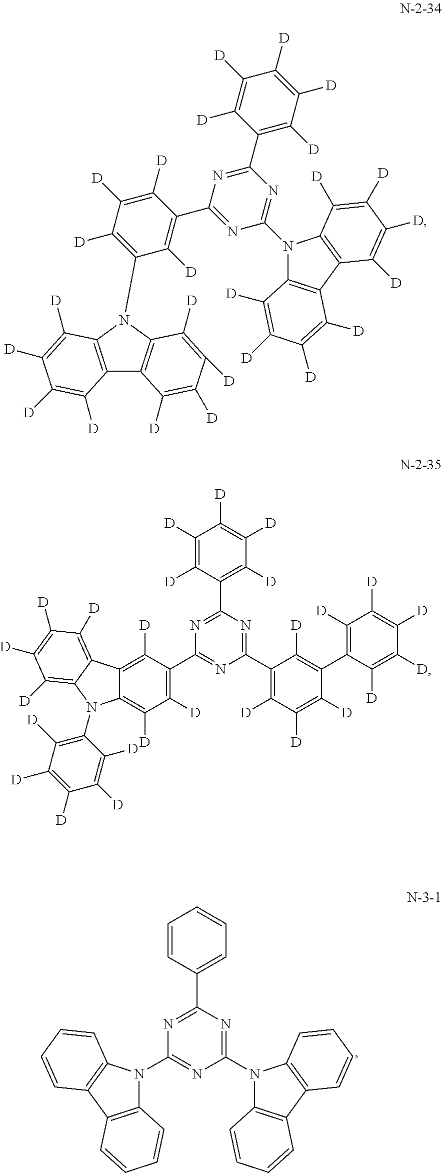

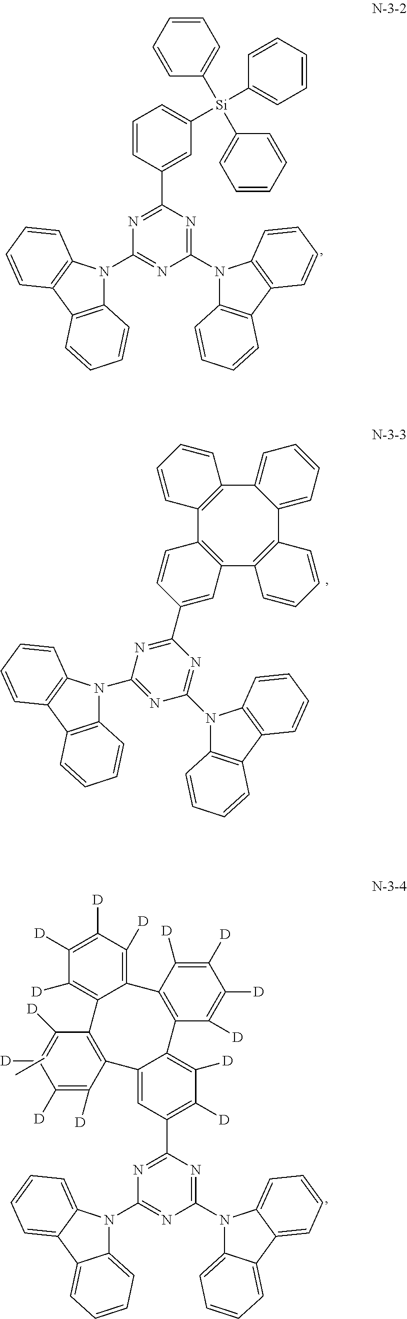

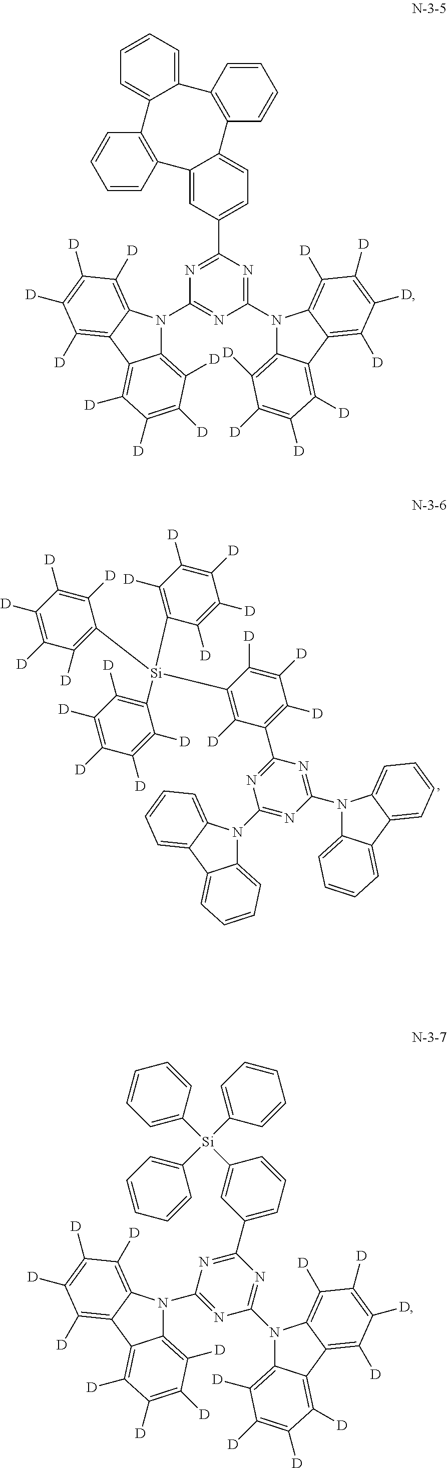

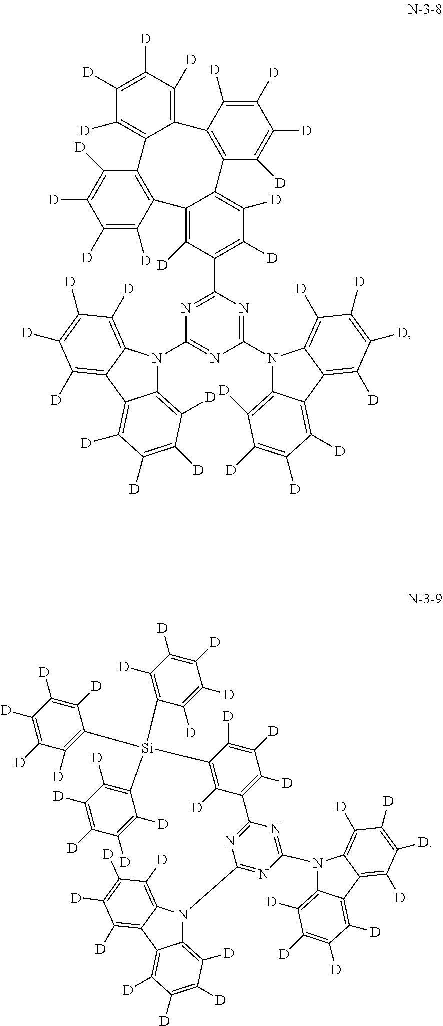

According to an embodiment of the present disclosure, hydrogens in the structures of Compound N-1-1 to Compound N-1-53, Compound N-1-58, Compound N-2-1 to Compound N-2-32, and Compound N-3-1 to Compound N-3-7 can be partially or fully substituted with deuterium.

According to an embodiment of the present disclosure, the second host compound has a structure represented by Formula 8:

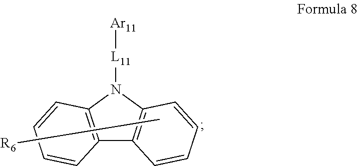

wherein in Formula 8,
L₁₁ is selected from a single bond, substituted or unsubstituted arylene having 6 to 30 carbon atoms, substituted or unsubstituted heteroarylene having 3 to 30 carbon atoms, or a combination thereof,
Ar₁₁ is selected from substituted or unsubstituted aryl having 6 to 30 carbon atoms, substituted or unsubstituted heteroaryl having 3 to 30 carbon atoms, substituted or unsubstituted amino having 0 to 30 carbon atoms, or a combination thereof,
R₆ represents, at each occurrence identically or differently, mono-substitution, multiple substitutions, or non-substitution;
R₆ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof, and
adjacent substituents R₆ can be optionally joined to form a ring.

In the present disclosure, the expression that “adjacent substituents R₆ can be optionally joined to form a ring” is intended to mean that two adjacent substituents R₆ can be joined to form a ring. Obviously, it is also possible that two adjacent substituents R₆ are not joined to form a ring.

According to an embodiment of the present disclosure, the second host compound has a structure represented by Formula 8-1 or Formula 8-2:

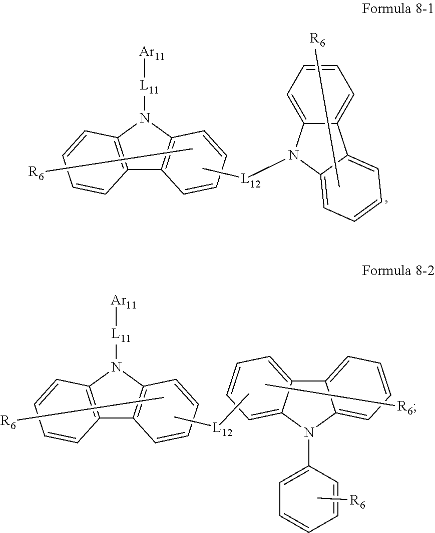

wherein L₁₁ and L₁₂ are each selected from a single bond, substituted or unsubstituted arylene having 6 to 30 carbon atoms, substituted or unsubstituted heteroarylene having 3 to 30 carbon atoms, or a combination thereof,
Ar₁₁ is selected from substituted or unsubstituted aryl having 6 to 30 carbon atoms, substituted or unsubstituted heteroaryl having 3 to 30 carbon atoms, substituted or unsubstituted amino having 0 to 30 carbon atoms, or a combination thereof,
R₆ represents, at each occurrence identically or differently, mono-substitution, multiple substitutions, or non-substitution;
R₆ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
adjacent substituents R₆ can be optionally joined to form a ring.

According to an embodiment of the present disclosure, the second host compound has a structure represented by Formula 8-3 or Formula 8-4:

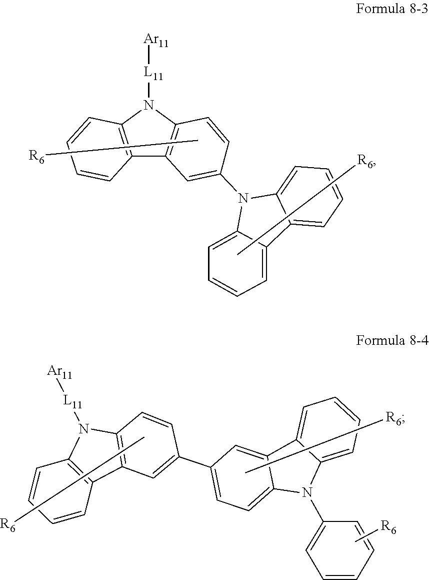

wherein Ar₁₁ is selected from substituted or unsubstituted aryl having 6 to 30 carbon atoms, substituted or unsubstituted heteroaryl having 3 to 30 carbon atoms, substituted or unsubstituted amino having 0 to 30 carbon atoms, or a combination thereof,
L₁₁ is selected from a single bond, substituted or unsubstituted arylene having 6 to 30 carbon atoms, substituted or unsubstituted heteroarylene having 3 to 30 carbon atoms, or a combination thereof;
R₆ represents, at each occurrence identically or differently, mono-substitution, multiple substitutions, or non-substitution;
R₆ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof, and
adjacent substituents R₆ can be optionally joined to form a ring.

According to an embodiment of the present disclosure, R₆ is, at each occurrence identically or differently, selected from the group consisting of: hydrogen, deuterium, halogen, cyano, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, and combinations thereof.

According to an embodiment of the present disclosure, R₆ is, at each occurrence identically or differently, selected from the group consisting of: hydrogen, deuterium, halogen, cyano, substituted or unsubstituted aryl having 6 to 18 carbon atoms, substituted or unsubstituted heteroaryl having 3 to 18 carbon atoms, and combinations thereof.

According to an embodiment of the present disclosure, R₆ is, at each occurrence identically or differently, selected from the group consisting of: hydrogen, deuterium, fluorine, cyano, phenyl, biphenyl, triphenylenyl, indenyl, fluorenyl, indolyl, carbazolyl, benzofuryl, dibenzofuryl, benzosilolyl, dibenzosilolyl, benzothienyl, dibenzothienyl, dibenzoselenophenyl, and combinations thereof.

According to an embodiment of the present disclosure, the second host compound is selected from the group consisting of Compound P-1 to Compound P-38:

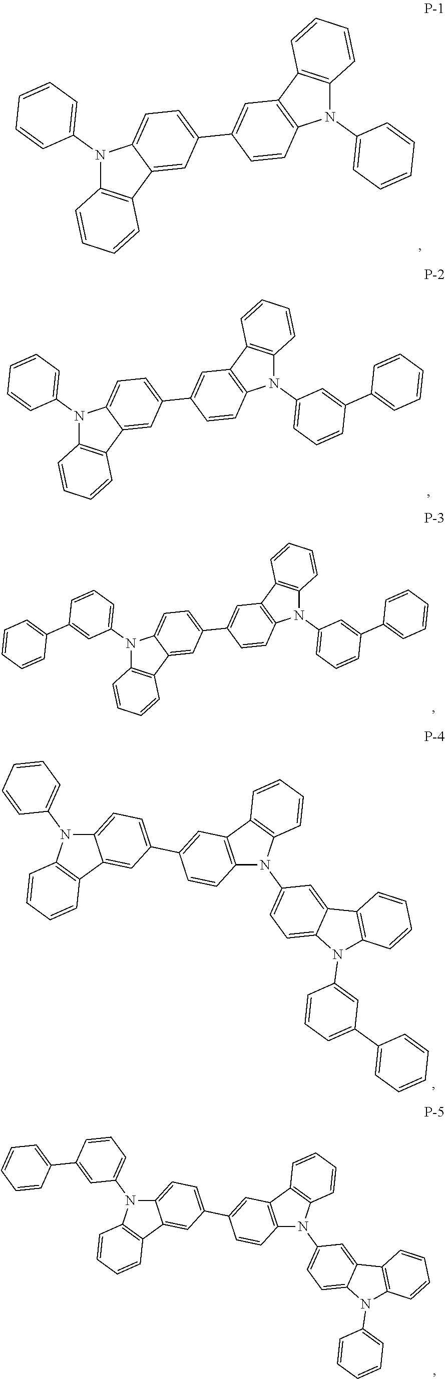 [SMILES: c1ccc(-n2c3ccccc3c3cc(-c4ccc5c(c4)c4ccccc4n5-c4ccccc4)ccc32)cc1 ; c1ccc(-c2cccc(-n3c4ccccc4c4cc(-c5ccc6c(c5)c5ccccc5n6-c5ccccc5)ccc43)c2)cc1 ; c1ccc(-c2cccc(-n3c4ccccc4c4cc(-c5ccc6c(c5)c5ccccc5n6-c5cccc(-c6ccccc6)c5)ccc43)c2)cc1 ; c1ccc(-c2cccc(-n3c4ccccc4c4cc(-n5c6ccccc6c6cc(-c7ccc8c(c7)c7ccccc7n8-c7ccccc7)ccc65)ccc43)c2)cc1 ; c1ccc(-c2cccc(-n3c4ccccc4c4cc(-c5ccc6c(c5)c5ccccc5n6-c5ccc6c(c5)c5ccccc5n6-c5ccccc5)ccc43)c2)cc1]

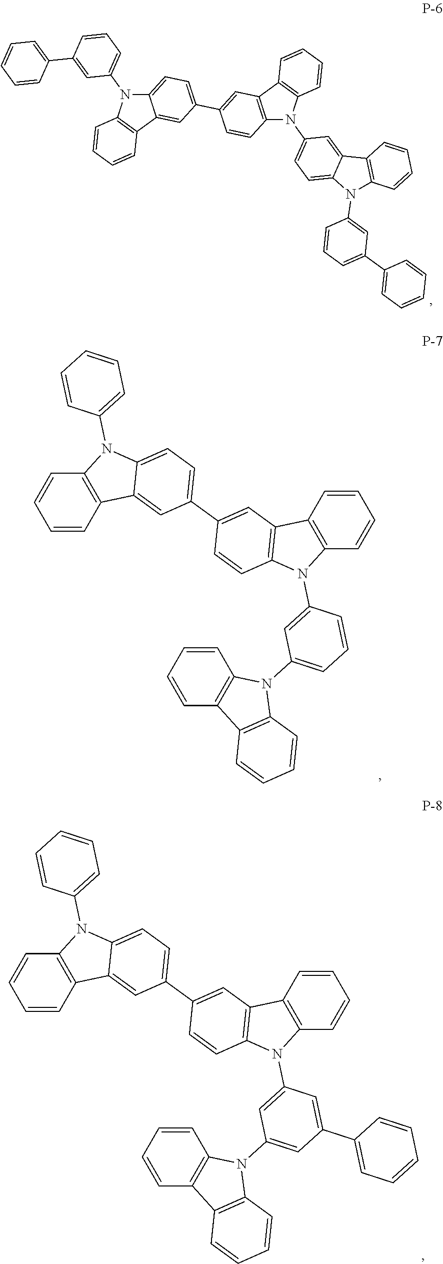 [SMILES: c1ccc(-c2cccc(-n3c4ccccc4c4cc(-c5ccc6c(c5)c5ccccc5n6-c5ccc6c(c5)c5ccccc5n6-c5cccc(-c6ccccc6)c5)ccc43)c2)cc1 ; c1ccc(-n2c3ccccc3c3cc(-c4ccc5c(c4)c4ccccc4n5-c4cccc(-n5c6ccccc6c6ccccc65)c4)ccc32)cc1 ; c1ccc(-c2cc(-n3c4ccccc4c4ccccc43)cc(-n3c4ccccc4c4cc(-c5ccc6c(c5)c5ccccc5n6-c5ccccc5)ccc43)c2)cc1]

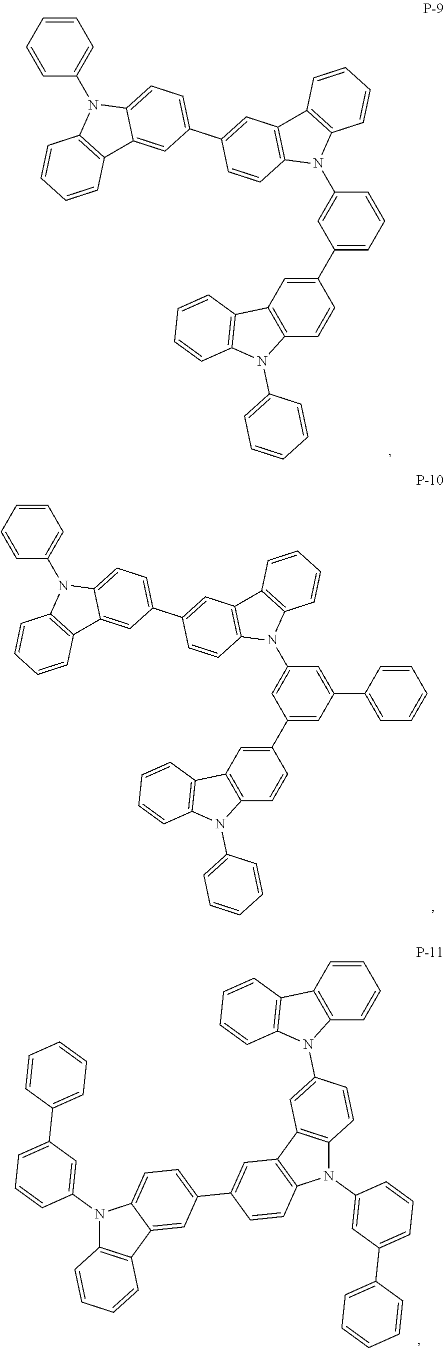 [SMILES: c1ccc(-n2c3ccccc3c3cc(-c4cccc(-n5c6ccccc6c6cc(-c7ccc8c(c7)c7ccccc7n8-c7ccccc7)ccc65)c4)ccc32)cc1 ; c1ccc(-c2cc(-c3ccc4c(c3)c3ccccc3n4-c3ccccc3)cc(-n3c4ccccc4c4cc(-c5ccc6c(c5)c5ccccc5n6-c5ccccc5)ccc43)c2)cc1 ; c1ccc(-c2cccc(-n3c4ccccc4c4cc(-c5ccc6c(c5)c5cc(-n7c8ccccc8c8ccccc87)ccc5n6-c5cccc(-c6ccccc6)c5)ccc43)c2)cc1]

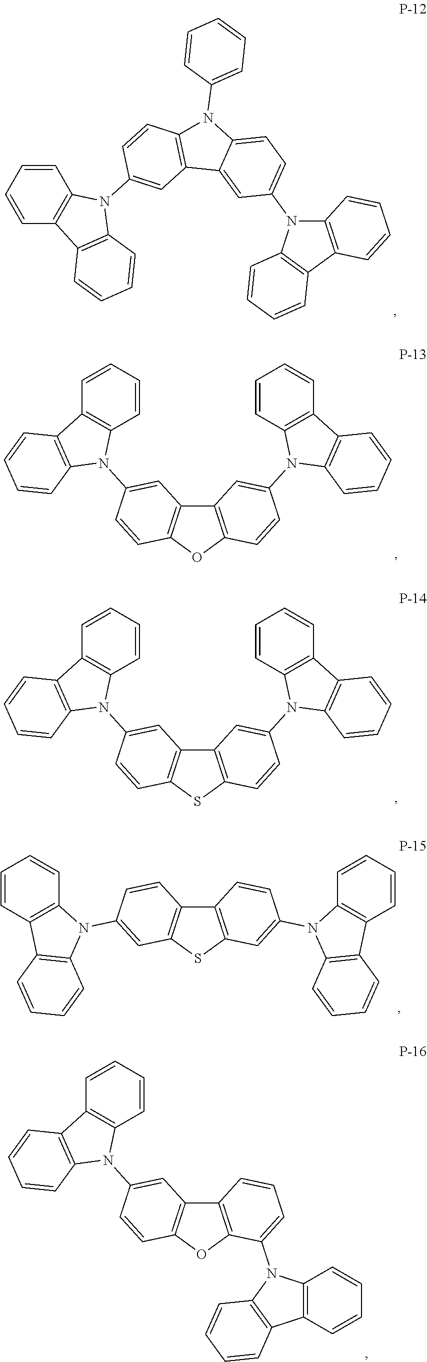

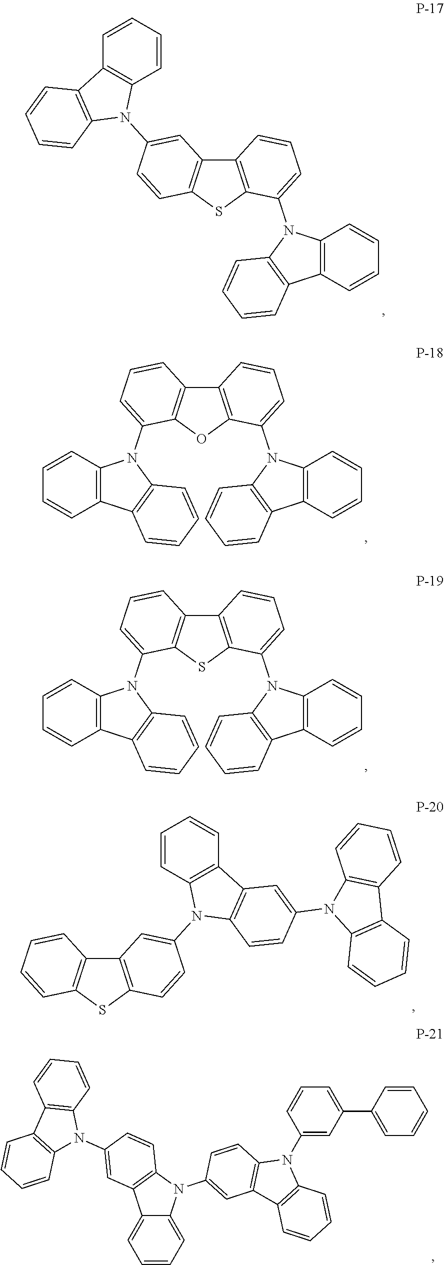

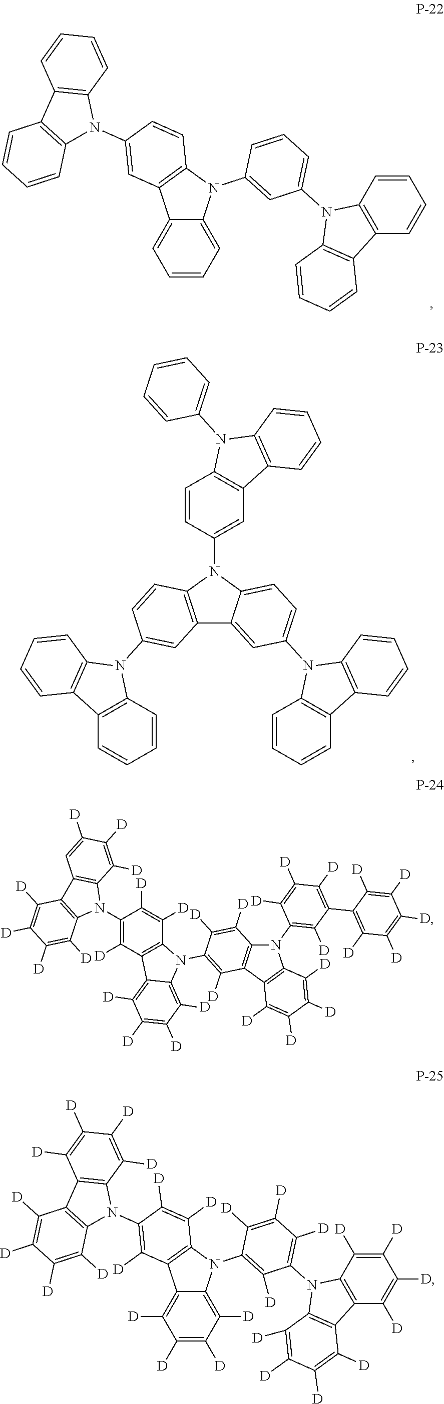

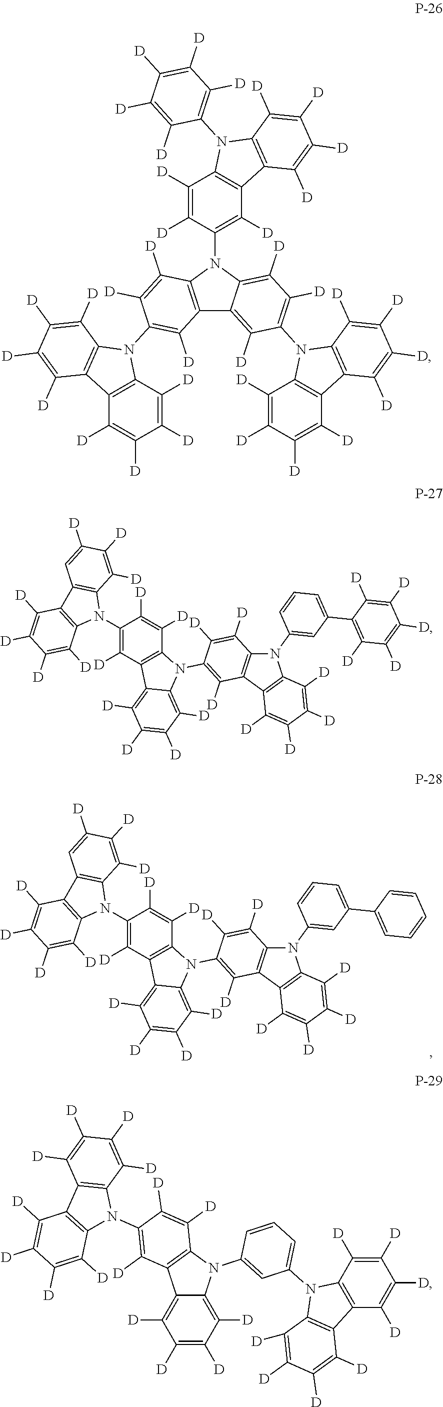

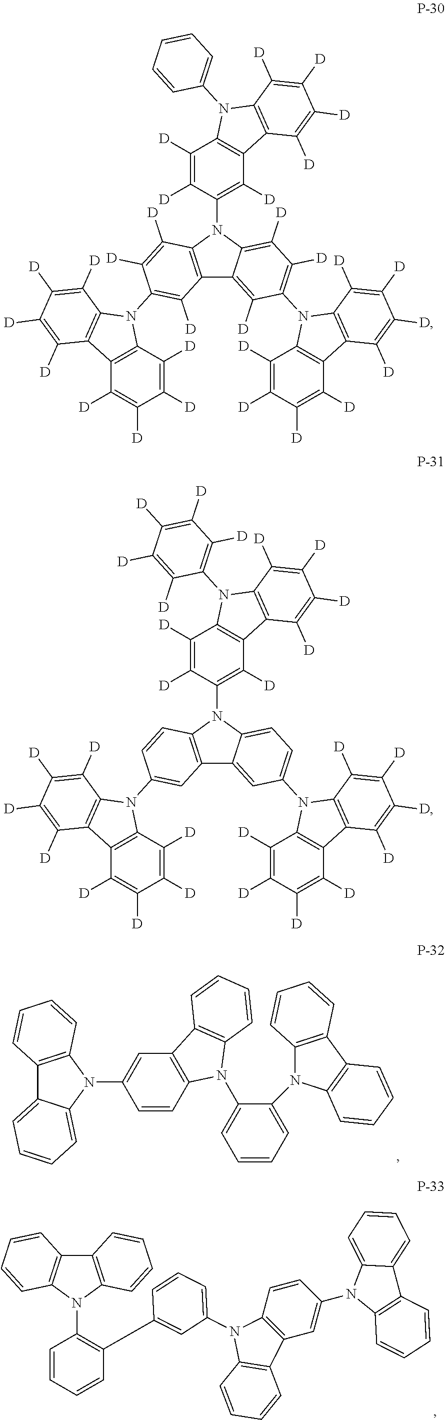

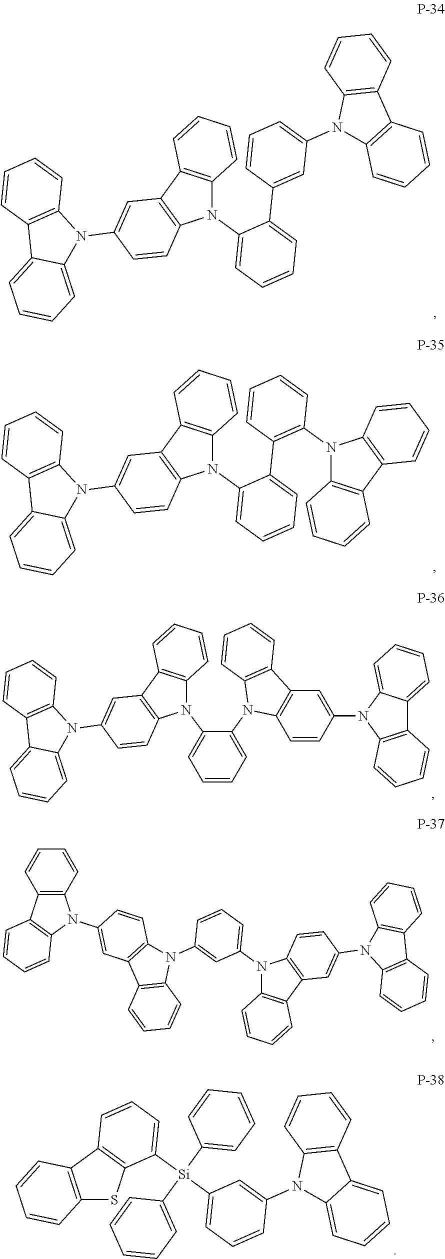 [SMILES: c1cc(-c2ccccc2-n2c3ccccc3c3cc(-n4c5ccccc5c5ccccc54)ccc32)cc(-n2c3ccccc3c3ccccc32)c1 ; c1ccc(-n2c3ccccc3c3ccccc32)c(-c2ccccc2-n2c3ccccc3c3cc(-n4c5ccccc5c5ccccc54)ccc32)c1 ; c1ccc(-n2c3ccccc3c3cc(-n4c5ccccc5c5ccccc54)ccc32)c(-n2c3ccccc3c3cc(-n4c5ccccc5c5ccccc54)ccc32)c1 ; c1cc(-n2c3ccccc3c3cc(-n4c5ccccc5c5ccccc54)ccc32)cc(-n2c3ccccc3c3cc(-n4c5ccccc5c5ccccc54)ccc32)c1 ; c1ccc([Si](c2ccccc2)(c2cccc(-n3c4ccccc4c4ccccc43)c2)c2cccc3c2sc2ccccc23)cc1]

According to an embodiment of the present disclosure, hydrogens in the structures of Compound P-1 to Compound P-23 and Compound P-27 to Compound P-38 can be partially or fully substituted with deuterium.

According to an embodiment of the present disclosure, the weight of the first host compound and the second host compound accounts for 65% to 98.9% of a total weight of materials of the emissive layer, the weight of the metal complex accounts for 1% to 30% of the total weight of materials of the emissive layer, and the weight of the fluorescent material accounts for 0.1% to 5% of the total weight of materials of the emissive layer.

According to an embodiment of the present disclosure, the weight of the first host compound and the second host compound accounts for 82% to 94.5% of the total weight of materials of the emissive layer, the weight of the metal complex accounts for 5% to 15% of the total weight of materials of the emissive layer, and the weight of the fluorescent material accounts for 0.5% to 3% of the total weight of materials of the emissive layer.

According to an embodiment of the present disclosure, the weight of the first host compound and the second host compound accounts for 86.5% to 91.5% of the total weight of materials of the emissive layer, the weight of the metal complex accounts for 8% to 12% of the total weight of materials of the emissive layer, and the weight of the fluorescent material accounts for 0.5% to 1.5% of the total weight of materials of the emissive layer.

According to an embodiment of the present disclosure, the device emits blue light.

According to an embodiment of the present disclosure, the device emits deep blue light.

According to an embodiment of the present disclosure, the device emits white light.

According to an embodiment of the present disclosure, the maximum emission wavelength of the device is 460 nm to 470 nm.

According to an embodiment of the present disclosure, the organic electroluminescent device emits fluorescence.

According to an embodiment of the present disclosure, the organic electroluminescent device emits delayed fluorescence.

According to an embodiment of the present disclosure, the fluorescent material is an emitter.

According to an embodiment of the present disclosure, disclosed is a display apparatus comprising the organic electroluminescent device according to any one of the preceding embodiments.

Combination with Other Materials

The materials described in the present disclosure for a particular layer in an organic light emitting device can be used in combination with various other materials present in the device. The combinations of these materials are described in more detail in U.S. Pat. App. No. 20160359122 at paragraphs 0132-0161, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

The materials described herein as useful for a particular layer in an organic light emitting device may be used in combination with a variety of other materials present in the device. For example, compounds disclosed herein may be used in combination with a wide variety of light-emitting dopants, hosts, transporting layers, blocking layers, injection layers, electrodes, and other layers that may be present. The combination of these materials is described in detail in paragraphs 0080-0101 of U.S. Pat. App. No. 20150349273, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

A method for preparing an organic electroluminescent device is not limited. The preparation methods in the following device examples are merely examples and are not to be construed as limitations. Those skilled in the art can make reasonable improvements on the preparation methods in the following device examples based on the related art. For example, the proportions of various materials in an emissive layer are not particularly limited. Those skilled in the art can reasonably select the proportions within certain ranges based on the related art. For example, taking the total weight of materials of the emissive layer for reference, a host material may account for 75% to 98%, a metal complex may account for 1% to 20%, and a thermally activated delayed fluorescence material may account for 1% to 5%; or the host material may account for 85% to 98%, the metal complex may account for 1% to 13%, and the thermally activated delayed fluorescence material may account for 1% to 2%. Further, the host material comprises two materials, where the ratio of the two host materials may range from 99:1 to 1:99, the ratio may range from 80:20 to 20:80, or the ratio may range from 70:30 to 30:70. In the examples of the device, the characteristics of the device are tested using conventional equipment in the art (including, but not limited to, evaporator produced by ANGSTROM ENGINEERING, optical testing system produced by SUZHOU FSTAR, life testing system produced by SUZHOU FSTAR, and ellipsometer produced by BEIJING ELLITOP, etc.) by methods well-known to the persons skilled in the art. As the persons skilled in the art are aware of the above-mentioned equipment use, test methods, and other related contents, the inherent data of samples can be obtained with certainty and without influence, so the above related contents are not further described in this patent.

In the present disclosure, a maximum emission wavelength λ_{max-PL} and a full width at half maximum FWHM-_{PL} of a photoluminescence spectrum were tested by the method below.

The photoluminescence (PL) spectrum data of a compound to be tested were measured using a fluorescence spectrophotometer F98 produced by SHANGHAI LENGGUANG TECHNOLOGY CO., LTD. The compound to be tested was dissolved in a toluene solvent to prepare a solution with a concentration of 1×10⁻⁶ mol/L, nitrogen was introduced into the prepared solution to be tested to remove oxygen for 5 min, the solution to be tested was placed in a quartz sample tube and excited at room temperature (298 K) by light with a maximum absorption wavelength of the compound to be tested, and an emission spectrum of the solution to be tested was measured. The emission spectrum had the maximum emission wavelength λ_{max-PL} and the full width at half maximum FWHM-_{PL} (that is, a peak width at a position of half the height of a peak, which is the distance between two points where a straight line passing through a midpoint of the height of the peak and being parallel to the peak bottom intersects two sides of the peak).

As an example, the maximum emission wavelength λ_{max-PL} of the photoluminescence spectrum the full width at half maximum FWHM-_{PL} of the photoluminescence spectrum of the following compound were measured by the above method. The specific results are shown in Table 1.

TABLE 1
PL spectrum data of the compound

| Fluorescent | | |
|---|---|---|
| Material | λ_{max-PL-1} (nm) | FWHM-_{PL-1} (nm) |
| BD-1-30 | 459 | 27.51 |

### Device Example

Hereinafter, the present disclosure is described in more detail with reference to the examples below. Apparently, the examples below are used only for the purpose of illustration and are not intended to limit the scope of the present disclosure. Based on the examples below, those skilled in the art can obtain other examples of the present disclosure by conducting improvements on these examples.

### Device Example 1

Firstly, a glass substrate having an indium tin oxide (ITO) anode with a thickness of 80 nm was cleaned and then treated with oxygen plasma and UV ozone. After the treatment, the substrate was dried in a glovebox to remove moisture. Then, the substrate was mounted on a substrate holder and placed in a vacuum chamber. The organic layers specified below were sequentially deposited through vacuum thermal evaporation on the ITO anode at a rate of 0.2 to 2 Angstroms per second and a vacuum degree of about 10⁻⁷ Torr. Compound HT and Compound HI were co-deposited (at a weight ratio of 97:3) for use as a hole injection layer (HIL) with a thickness of 100 Å. Compound HT was used as a hole transporting layer (HTL) with a thickness of 250 Å. Compound P-21 was used as an electron blocking layer (EBL) with a thickness of 50 Å. A first host compound N-3-2, a second host compound P-25, a metal complex Pt27, and a fluorescent material BD-1-30 were co-deposited (at a weight ratio of 34.9:52.1:12:1) for use as an emissive layer (EML) with a thickness of 350 Å. Compound N-3-2 was used as a hole blocking layer (HBL) with a thickness of 50 Å. On the HBL, Compound ET and 8-hydroxyquinolinolato-lithium (Liq) were co-deposited (at a weight ratio of 40:60) for use as an electron transporting layer (ETL) with a thickness of 310 Å. Finally, LiF was deposited for use as an electron injection layer with a thickness of 15 Å and Al was deposited for use as a cathode with a thickness of 1200 Å. The device was transferred back to the glovebox and encapsulated with a glass lid and a moisture getter to complete the device.

### Device Comparative Example 1

Device Comparative Example 1 was prepared in the same manner as Device Example 1 except that the first host compound N-3-2, the second host compound P-25, and the fluorescent material BD-1-30 were co-deposited (at a weight ratio of 39.6:59.4:1) for use as an emissive layer (EML) (350 Å).

Detailed structures and thicknesses of layers of the devices are shown in the following table. A layer using more than one material is obtained by doping different compounds at their weight ratio as recorded.

TABLE 2
Part of the device structures of Device Example 1 and Device Comparative Example 1

| Device ID | HIL | HTL | EBL | EML | HBL | ETL |
|---|---|---|---|---|---|---|
| Example 1 | Compound | Compound | Compound | Compound | Compound | Compound |
| | HT:Compound | HT (250 | P-21 (50 | N-3-2:Compound | N-3-2 (50 | ET:Liq |
| | HI (97:3) (100 | Å) | Å) | P-25:Compound | Å) | (40:60) |
| | Å) | | | Pt27:Compound | | (310 Å) |
| | | | | BD-1-30 | | |
| | | | | (34.9:52.1:12:1) | | |
| | | | | (350 Å) | | |
| Comparative | Compound | Compound | Compound | Compound | Compound | Compound |
| Example 1 | HT:Compound | HT (250 | P-21 (50 | N-3-2:Compound | N-3-2 (50 | ET:Liq |
| | HI (97:3) (100 | Å) | Å) | P-25:Compound | Å) | (40:60) |
| | Å) | | | BD-1-30 | | (310 Å) |
| | | | | (39.6:59.4:1) | | |
| | | | | (350 Å) | | |

The materials used in the devices have the following structures:

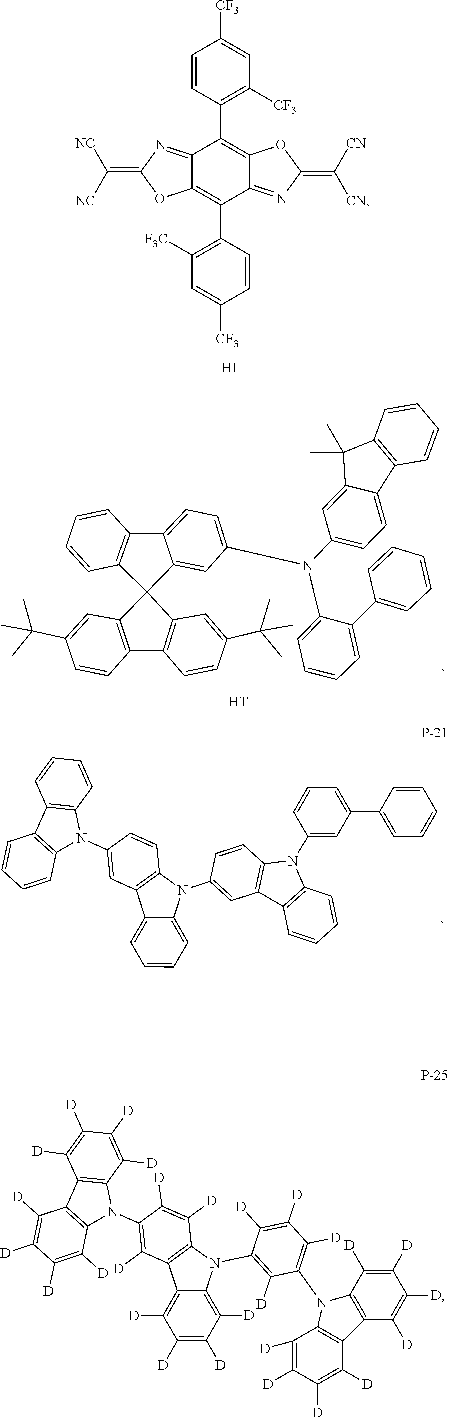

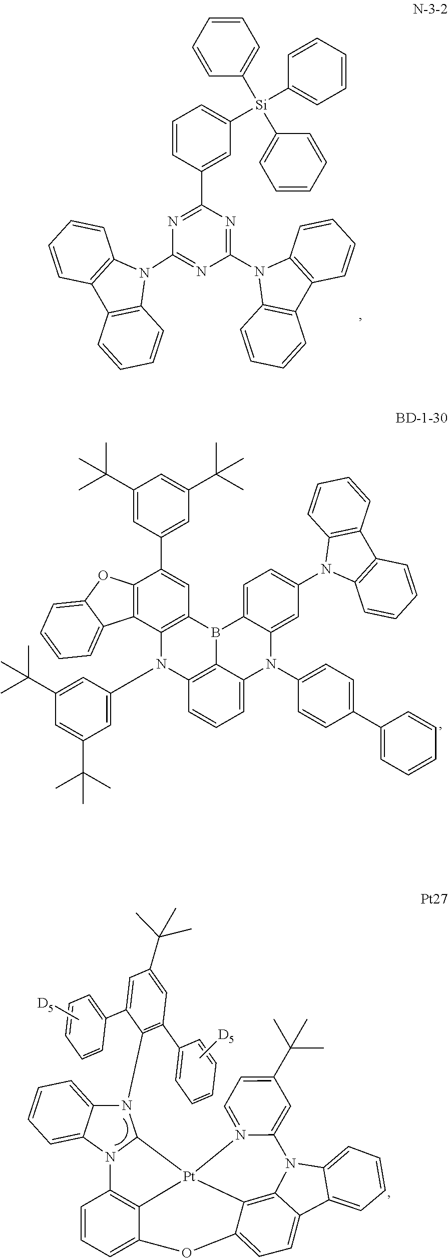

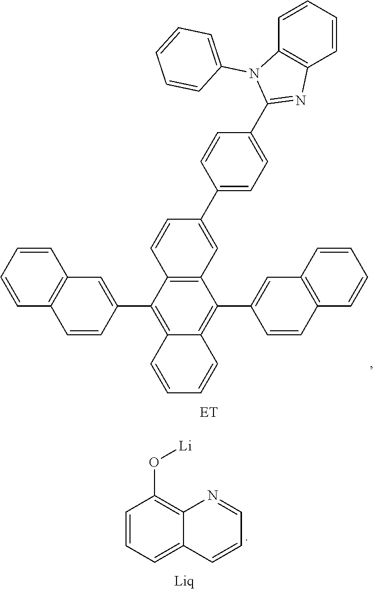

The CIE values, maximum emission wavelengths (λₘₐₓ), full widths at half maximum (FWHM), and external quantum efficiency (EQE) of Example 1 and Comparative Example 1 were measured at 10 mA/cm². To more intuitively show comparisons of data, the external quantum efficiency of Comparative Example 1 was set to 1.00, and the external quantum efficiency of Example 1 was converted relative to the corresponding datum of Comparative Example 1. The relevant data are shown in Table 3.

TABLE 3
Device data of Example 1 and Comparative Example 1

| | | λₘₐₓ | FWHM | |
|---|---|---|---|---|
| Device ID | CIE (x, y) | [nm] | [nm] | EQE |
| Example 1 | 0.133, 0.111 | 462 | 26.0 | 1.75 |
| Comparative | 0.133, 0.092 | 460 | 28.2 | 1.00 |
| Example 1 | | | | |

### Discussion

Example 1 differed from Comparative Example 1 in that the emissive layer of Example 1 used the metal complex selected in the present disclosure as a phosphorescent sensitizer to sensitize the fluorescent material, while Comparative Example 1 did not use a metal complex as the phosphorescent sensitizer. As can be seen from the data in Table 3, Example 1 and Comparative Example 1 had substantially consistent maximum emission wavelengths, indicating that light emitted by the device of Example 1 was from the fluorescent material. However, compared with the ordinary fluorescent device of Comparative Example 1, the device of Example 1 of the present disclosure had a further narrowed full width at half maximum, and more importantly, the external quantum efficiency was increased by up to 75%. These data indicate that a combination of the fluorescent material of the present disclosure having a structure of Formula 1 and the metal complex of the present disclosure comprising a ligand with a structure represented by Formula 2 can further narrow the full width at half maximum of the device and, particularly, can greatly improve the device efficiency.

To conclude, the device of the present disclosure, which uses the combination of the fluorescent material of the present disclosure having a particular structure of Formula 1 and the metal complex of the present disclosure comprising a ligand with a structure represented by Formula 2 (the phosphorescent sensitizer) in the emissive layer, can achieve very good device performance, such as a narrower full width at half maximum and higher external quantum efficiency, and has a broad application prospect.

It should be understood that various embodiments described herein are merely embodiments and not intended to limit the scope of the present disclosure. Therefore, it is apparent to those skilled in the art that the present disclosure as claimed may include variations of specific embodiments and preferred embodiments described herein. Many of the materials and structures described herein may be replaced with other materials and structures without departing from the spirit of the present disclosure. It should be understood that various theories as to why the present disclosure works are not intended to be limitative.

What is claimed is:

1. An organic electroluminescent device, comprising:
an anode,
a cathode, and
an organic layer disposed between the anode and the cathode, wherein the organic layer comprises at least a fluorescent material and a metal complex;
wherein the fluorescent material has a structure represented by Formula 1: 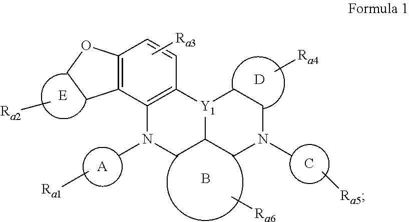
wherein in Formula 1, the ring A, the ring B, the ring C, the ring D, and the ring E are each independently selected from an unsaturated carbocyclic ring having 5 to 30 carbon atoms or an unsaturated heterocyclic ring having 3 to 30 carbon atoms;
Y₁ is selected from B, P═O, P═S, As, As=O, As=S, SiR′, or GeR′;
Rₐ₁, Rₐ₂, Rₐ₃, Rₐ₄, Rₐ₅, and Rₐ₆ represent, at each occurrence identically or differently, mono-substitution, multiple substitutions, or non-substitution;
R′, Rₐ₁, Rₐ₂, Rₐ₃, Rₐ₄, Rₐ₅, and Rₐ₆ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof, and
adjacent substituents Rₐ₁, Rₐ₂, Rₐ₃, Rₐ₄, Rₐ₅, Rₐ₆ can be optionally joined to form a ring;
wherein the metal complex comprises a metal M and a ligand Lₐ coordinated to the metal M, the metal M is selected from a metal with a relative atomic mass greater than 40, and the ligand Lₐ has a structure represented by Formula 2: 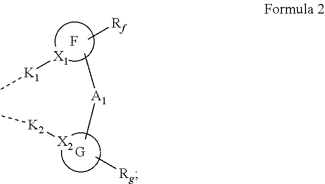
wherein in Formula 2, the ring F and the ring G are each independently selected from an unsaturated carbocyclic ring having 5 to 30 carbon atoms, an unsaturated heterocyclic ring having 1 to 30 carbon atoms, or a combination thereof;
X₁ and X₂ are identically or differently selected from C or N;
K₁ and K₂ are each independently selected from a single bond, O, or S;
A₁ is selected from a single bond, O, S, Se, (SiR_{q}R_{q})_{y}, PR_{q}, NR_{q}, (CR_{q}R_{q})_{y}, substituted or unsubstituted arylene having 6 to 30 carbon atoms, substituted or unsubstituted heteroarylene having 3 to 30 carbon atoms, or a combination thereof, wherein y is, at each occurrence identically or differently, selected from 1, 2, 3, 4, or 5;
R_{f} and R_{g} represent, at each occurrence identically or differently, mono-substitution, multiple substitutions, or non-substitution;
R_{f} and R_{g} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof, and
adjacent substituents R_{f} and R_{g} can be optionally joined to form a ring.

2. The organic electroluminescent device according to claim 1, wherein the ring A, the ring B, the ring C, the ring D, and the ring E are each independently selected from a five-membered unsaturated carbocyclic ring, an aromatic ring having 6 to 30 carbon atoms, or a heteroaromatic ring having 3 to 30 carbon atoms;
preferably, the ring A, the ring B, the ring C, the ring D, and the ring E are, at each occurrence identically or differently, selected from a five-membered unsaturated carbocyclic ring, an aromatic ring having 6 to 18 carbon atoms, or a heteroaromatic ring having 3 to 18 carbon atoms;
more preferably, the ring A, the ring B, the ring C, the ring D, and the ring E are, at each occurrence identically or differently, selected from a benzene ring, a pyridine ring, a naphthalene ring, a phenanthrene ring, an anthracene ring, an indene ring, a fluorene ring, an indole ring, a carbazole ring, a benzofuran ring, a dibenzofuran ring, a benzosilole ring, a dibenzosilole ring, a benzothiophene ring, a dibenzothiophene ring, a dibenzoselenophene ring, a cyclopentadienyl ring, a furan ring, a thiophene ring, a silole ring, or a combination thereof.

3. The organic electroluminescent device according to claim 1, wherein the fluorescent material has a structure represented by Formula 1-1: 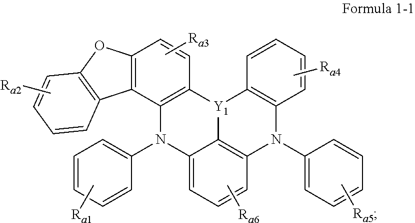
wherein
Y₁ is selected from B, P═O, P═S, As, As=O, As=S, SiR′, or GeR′;
Rₐ₁, Rₐ₂, Rₐ₃, Rₐ₄, Rₐ₅, and Rₐ₆ represent, at each occurrence identically or differently, mono-substitution, multiple substitutions, or non-substitution;
R′, Rₐ₁, Rₐ₂, Rₐ₃, Rₐ₄, Rₐ₅, and Rₐ₆ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
adjacent substituents Rₐ₁, Rₐ₂, Rₐ₃, Rₐ₄, Rₐ₅, Rₐ₆ can be optionally joined to form a ring;
preferably, Y₁ is selected from B, P═O, or P═S;
more preferably, Y₁ is selected from B.

4. The organic electroluminescent device according to claim 3, wherein Rₐ₁, Rₐ₂, Rₐ₃, Rₐ₄, Rₐ₅, and Rₐ₆ are, at each occurrence identically or differently, selected from the group consisting of: hydrogen, deuterium, halogen, cyano, hydroxyl, sulfanyl, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, and combinations thereof;
preferably, Rₐ₁, Rₐ₂, Rₐ₃, Rₐ₄, Rₐ₅, and Rₐ₆ are, at each occurrence identically or differently, selected from the group consisting of: hydrogen, deuterium, halogen, cyano, hydroxyl, sulfanyl, substituted or unsubstituted alkyl having 1 to 6 carbon atoms, substituted or unsubstituted cycloalkyl having 3 to 6 ring carbon atoms, substituted or unsubstituted heteroalkyl having 1 to 6 carbon atoms, substituted or unsubstituted heterocyclic group having 3 to 6 ring atoms, substituted or unsubstituted aryl having 6 to 24 carbon atoms, substituted or unsubstituted heteroaryl having 3 to 12 carbon atoms, substituted or unsubstituted alkylsilyl having 3 to 6 carbon atoms, substituted or unsubstituted arylsilyl having 6 to 12 carbon atoms, substituted or unsubstituted alkylgermanyl having 3 to 6 carbon atoms, substituted or unsubstituted arylgermanyl having 6 to 12 carbon atoms, substituted or unsubstituted amino having 0 to 12 carbon atoms, and combinations thereof;
more preferably, Rₐ₁, Rₐ₂, Rₐ₃, Rₐ₄, Rₐ₅, and Rₐ₆ are, at each occurrence identically or differently, selected from the group consisting of: hydrogen, deuterium, fluorine, cyano, hydroxyl, sulfanyl, methyl, ethyl, n-propyl, isopropyl, cyclopropyl, n-butyl, isobutyl, t-butyl, cyclopentyl, neopentyl, cyclohexyl, trimethylsilyl, trimethylgermanyl, phenyl, biphenyl, terphenyl, tetraphenyl, triphenylenyl, tetraphenylenyl, naphthyl, phenanthryl, anthryl, indenyl, fluorenyl, indolyl, carbazolyl, benzofuryl, dibenzofuryl, benzosilolyl, dibenzosilolyl, benzothienyl, dibenzothienyl, dibenzoselenophenyl, diphenylamino, dibenzofurylphenylamino, and combinations thereof.

5. The organic electroluminescent device according to claim 3, wherein at least one of Rₐ₁, Rₐ₂, Rₐ₃, Rₐ₄, Rₐ₅, and Rₐ₆ is, at each occurrence identically or differently, selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
preferably, at least one of Rₐ₁, Rₐ₂, Rₐ₃, Rₐ₄, Rₐ₅, and Rₐ₆ is, at each occurrence identically or differently, selected from the group consisting of: deuterium, halogen, cyano, hydroxyl, sulfanyl, substituted or unsubstituted alkyl having 1 to 6 carbon atoms, substituted or unsubstituted cycloalkyl having 3 to 6 ring carbon atoms, substituted or unsubstituted heteroalkyl having 1 to 6 carbon atoms, substituted or unsubstituted aryl having 6 to 24 carbon atoms, substituted or unsubstituted heteroaryl having 3 to 12 carbon atoms, substituted or unsubstituted alkylsilyl having 3 to 6 carbon atoms, substituted or unsubstituted arylsilyl having 6 to 12 carbon atoms, substituted or unsubstituted alkylgermanyl having 3 to 6 carbon atoms, substituted or unsubstituted arylgermanyl having 6 to 12 carbon atoms, substituted or unsubstituted amino having 0 to 12 carbon atoms, and combinations thereof,
more preferably, at least one of Rₐ₁, Rₐ₂, Rₐ₃, Rₐ₄, Rₐ₅, and Rₐ₆ is, at each occurrence identically or differently, selected from the group consisting of: deuterium, fluorine, cyano, hydroxyl, sulfanyl, methyl, ethyl, n-propyl, isopropyl, cyclopropyl, n-butyl, isobutyl, t-butyl, cyclopentyl, neopentyl, cyclohexyl, trimethylsilyl, trimethylgermanyl, phenyl, biphenyl, terphenyl, tetraphenyl, triphenylenyl, tetraphenylenyl, naphthyl, phenanthryl, anthryl, indenyl, fluorenyl, indolyl, carbazolyl, benzofuryl, dibenzofuryl, benzosilolyl, dibenzosilolyl, benzothienyl, dibenzothienyl, dibenzoselenophenyl, diphenylamino, dibenzofurylphenylamino, and combinations thereof.

6. The organic electroluminescent device according to claim 3, wherein Rₐ₃ is selected from the group consisting of: substituted or unsubstituted aryl having 6 to 30 carbon atoms, substituted or unsubstituted heteroaryl having 3 to 30 carbon atoms, and combinations thereof,
preferably, Rₐ₃ is selected from the group consisting of: substituted or unsubstituted aryl having 6 to 24 carbon atoms, substituted or unsubstituted heteroaryl having 3 to 12 carbon atoms, and combinations thereof,
more preferably, Rₐ₃ is selected from the group consisting of: phenyl, biphenyl, terphenyl, tetraphenyl, triphenylenyl, tetraphenylenyl, naphthyl, phenanthryl, anthryl, indenyl, fluorenyl, indolyl, carbazolyl, benzofuryl, dibenzofuryl, benzosilolyl, dibenzosilolyl, benzothienyl, dibenzothienyl, dibenzoselenophenyl, and combinations thereof.

7. The organic electroluminescent device according to claim 3, wherein Rₐ₄ is selected from the group consisting of: substituted or unsubstituted aryl having 6 to 30 carbon atoms, substituted or unsubstituted heteroaryl having 3 to 30 carbon atoms, and combinations thereof,
preferably, Rₐ₄ is selected from the group consisting of: substituted or unsubstituted aryl having 6 to 24 carbon atoms, substituted or unsubstituted heteroaryl having 3 to 12 carbon atoms, and combinations thereof,
more preferably, Rₐ₄ is selected from the group consisting of: phenyl, biphenyl, terphenyl, tetraphenyl, triphenylenyl, tetraphenylenyl, naphthyl, phenanthryl, anthryl, indenyl, fluorenyl, indolyl, carbazolyl, benzofuryl, dibenzofuryl, benzosilolyl, dibenzosilolyl, benzothienyl, dibenzothienyl, dibenzoselenophenyl, and combinations thereof.

8. The organic electroluminescent device according to claim 1, wherein the fluorescent material is selected from the group consisting of Compound BD-1-1 to Compound BD-1-33, Compound BD-2-1 to Compound BD-2-19, Compound BD-3-1 to Compound BD-3-15, Compound BD-4-1 to Compound BD-4-36, and Compound BD-5-1 to Compound BD-5-14: 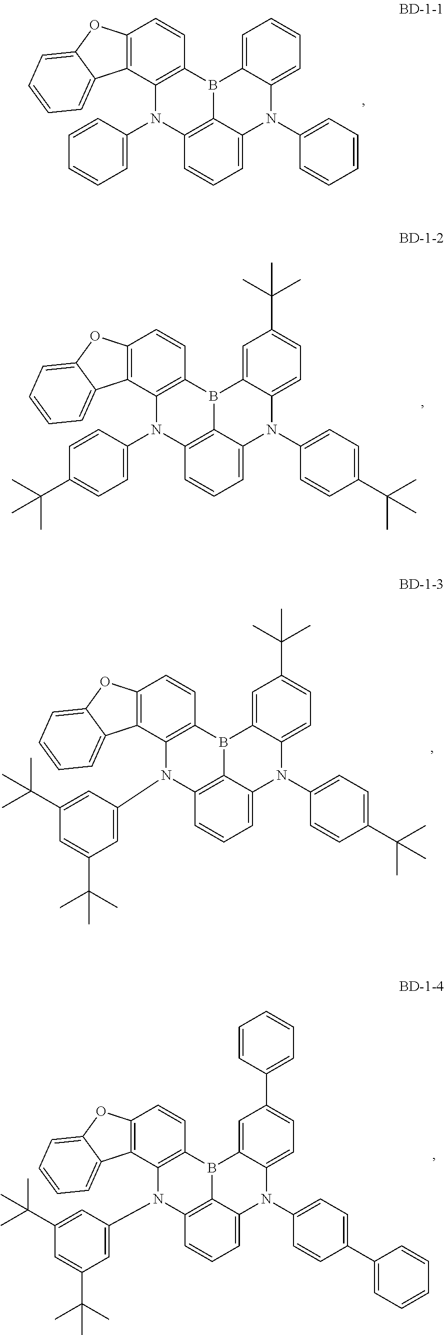 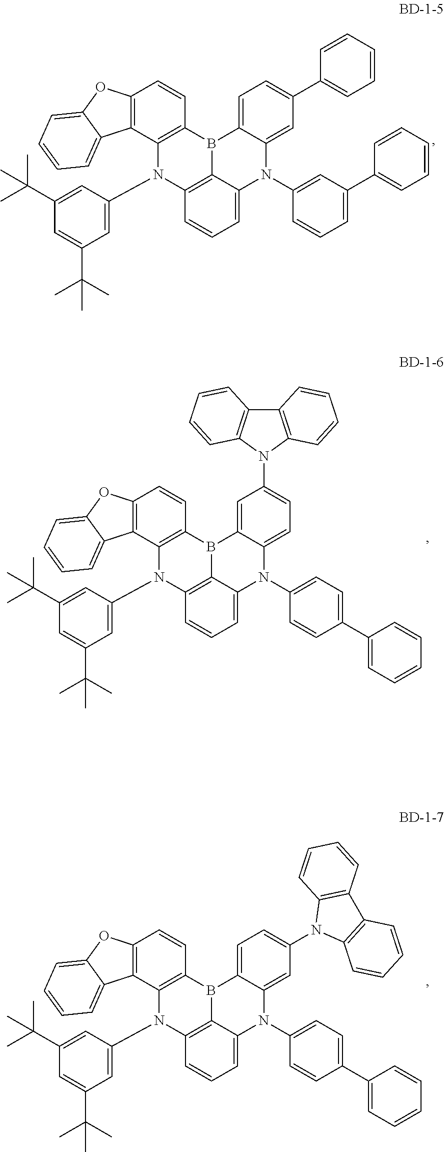 [SMILES: CC(C)(C)c1cc(N2c3cccc4c3B(c3ccc(-c5ccccc5)cc3N4c3cccc(-c4ccccc4)c3)c3ccc4oc5ccccc5c4c32)cc(C(C)(C)C)c1 ; CC(C)(C)c1cc(N2c3cccc4c3B(c3cc(-n5c6ccccc6c6ccccc65)ccc3N4c3ccc(-c4ccccc4)cc3)c3ccc4oc5ccccc5c4c32)cc(C(C)(C)C)c1 ; CC(C)(C)c1cc(N2c3cccc4c3B(c3ccc(-n5c6ccccc6c6ccccc65)cc3N4c3ccc(-c4ccccc4)cc3)c3ccc4oc5ccccc5c4c32)cc(C(C)(C)C)c1] 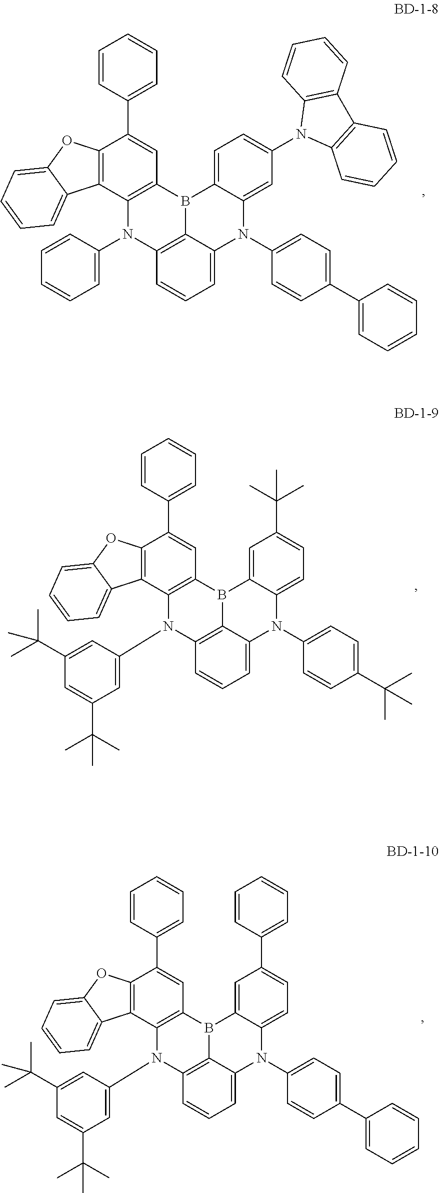 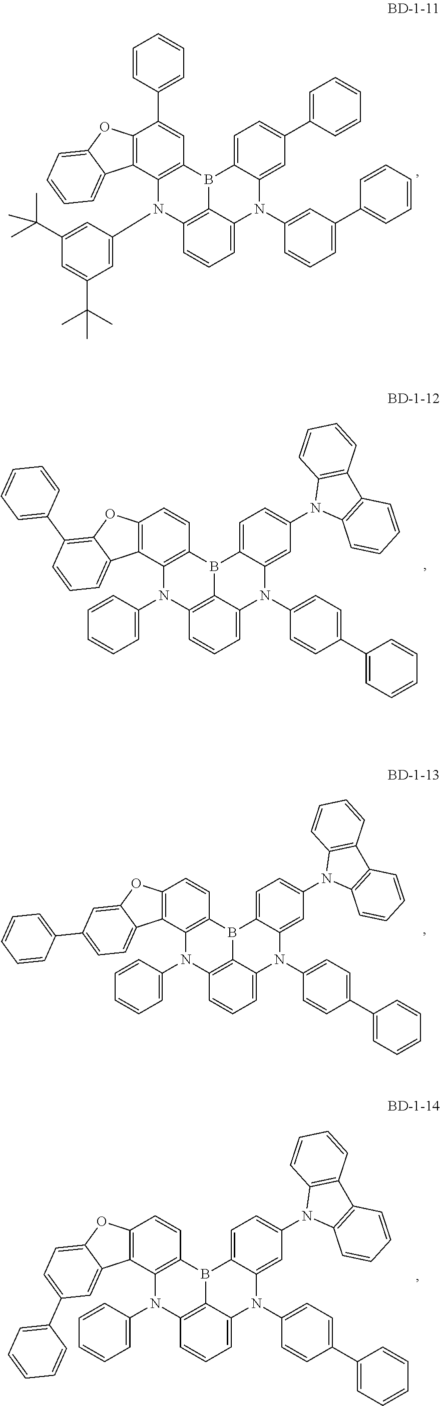 [SMILES: CC(C)(C)c1cc(N2c3cccc4c3B(c3ccc(-c5ccccc5)cc3N4c3cccc(-c4ccccc4)c3)c3cc(-c4ccccc4)c4oc5ccccc5c4c32)cc(C(C)(C)C)c1 ; c1ccc(-c2ccc(N3c4cc(-n5c6ccccc6c6ccccc65)ccc4B4c5ccc6oc7c(-c8ccccc8)cccc7c6c5N(c5ccccc5)c5cccc3c54)cc2)cc1 ; c1ccc(-c2ccc(N3c4cc(-n5c6ccccc6c6ccccc65)ccc4B4c5ccc6oc7cc(-c8ccccc8)ccc7c6c5N(c5ccccc5)c5cccc3c54)cc2)cc1 ; c1ccc(-c2ccc(N3c4cc(-n5c6ccccc6c6ccccc65)ccc4B4c5ccc6oc7ccc(-c8ccccc8)cc7c6c5N(c5ccccc5)c5cccc3c54)cc2)cc1] 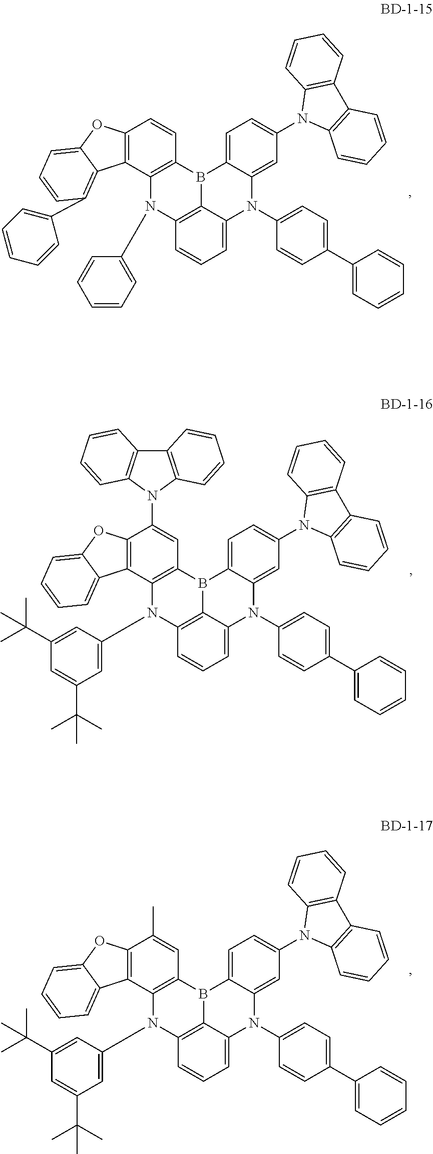 [SMILES: c1ccc(-c2ccc(N3c4cc(-n5c6ccccc6c6ccccc65)ccc4B4c5ccc6oc7cccc(-c8ccccc8)c7c6c5N(c5ccccc5)c5cccc3c54)cc2)cc1 ; CC(C)(C)c1cc(N2c3cccc4c3B(c3ccc(-n5c6ccccc6c6ccccc65)cc3N4c3ccc(-c4ccccc4)cc3)c3cc(-n4c5ccccc5c5ccccc54)c4oc5ccccc5c4c32)cc(C(C)(C)C)c1 ; Cc1cc2c(c3c1oc1ccccc13)N(c1cc(C(C)(C)C)cc(C(C)(C)C)c1)c1cccc3c1B2c1ccc(-n2c4ccccc4c4ccccc42)cc1N3c1ccc(-c2ccccc2)cc1] 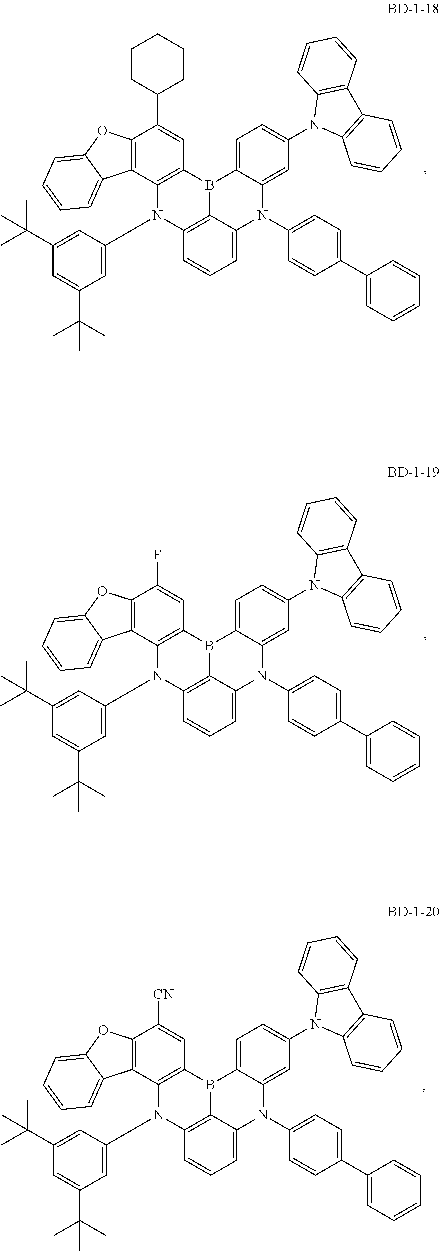 [SMILES: CC(C)(C)c1cc(N2c3cccc4c3B(c3ccc(-n5c6ccccc6c6ccccc65)cc3N4c3ccc(-c4ccccc4)cc3)c3cc(C4CCCCC4)c4oc5ccccc5c4c32)cc(C(C)(C)C)c1 ; CC(C)(C)c1cc(N2c3cccc4c3B(c3ccc(-n5c6ccccc6c6ccccc65)cc3N4c3ccc(-c4ccccc4)cc3)c3cc(F)c4oc5ccccc5c4c32)cc(C(C)(C)C)c1 ; CC(C)(C)c1cc(N2c3cccc4c3B(c3ccc(-n5c6ccccc6c6ccccc65)cc3N4c3ccc(-c4ccccc4)cc3)c3cc(C#N)c4oc5ccccc5c4c32)cc(C(C)(C)C)c1] 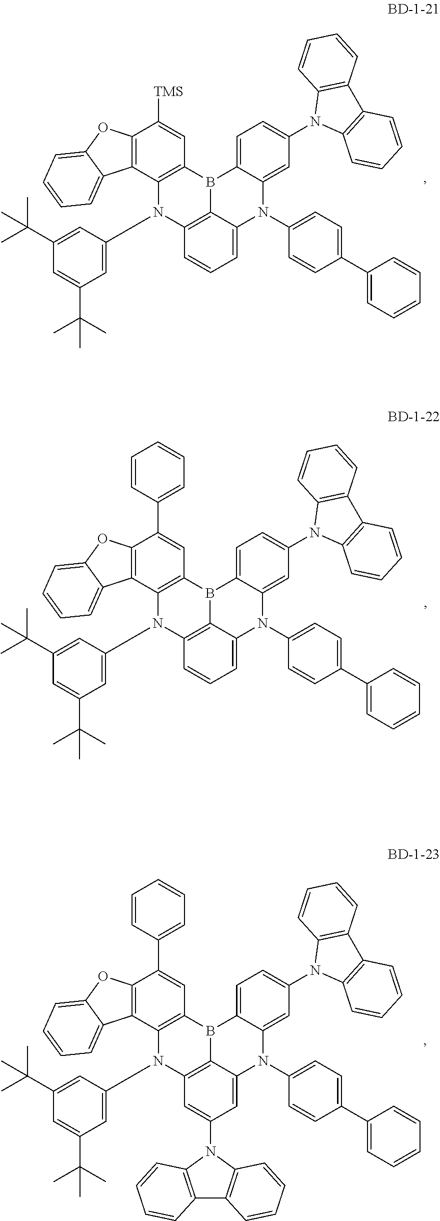 [SMILES: CC(C)(C)c1cc(N2c3cccc4c3B(c3ccc(-n5c6ccccc6c6ccccc65)cc3N4c3ccc(-c4ccccc4)cc3)c3cc([Si](C)(C)C)c4oc5ccccc5c4c32)cc(C(C)(C)C)c1 ; CC(C)(C)c1cc(N2c3cccc4c3B(c3ccc(-n5c6ccccc6c6ccccc65)cc3N4c3ccc(-c4ccccc4)cc3)c3cc(-c4ccccc4)c4oc5ccccc5c4c32)cc(C(C)(C)C)c1 ; CC(C)(C)c1cc(N2c3cc(-n4c5ccccc5c5ccccc54)cc4c3B(c3ccc(-n5c6ccccc6c6ccccc65)cc3N4c3ccc(-c4ccccc4)cc3)c3cc(-c4ccccc4)c4oc5ccccc5c4c32)cc(C(C)(C)C)c1] 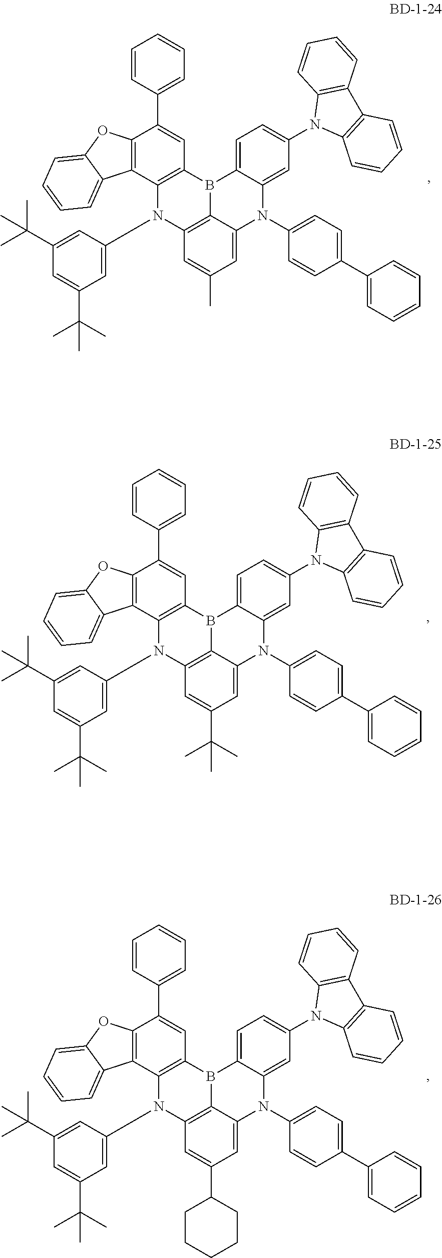 [SMILES: Cc1cc2c3c(c1)N(c1cc(C(C)(C)C)cc(C(C)(C)C)c1)c1c(cc(-c4ccccc4)c4oc5ccccc5c14)B3c1ccc(-n3c4ccccc4c4ccccc43)cc1N2c1ccc(-c2ccccc2)cc1 ; CC(C)(C)c1cc(N2c3cc(C(C)(C)C)cc4c3B(c3ccc(-n5c6ccccc6c6ccccc65)cc3N4c3ccc(-c4ccccc4)cc3)c3cc(-c4ccccc4)c4oc5ccccc5c4c32)cc(C(C)(C)C)c1 ; CC(C)(C)c1cc(N2c3cc(C4CCCCC4)cc4c3B(c3ccc(-n5c6ccccc6c6ccccc65)cc3N4c3ccc(-c4ccccc4)cc3)c3cc(-c4ccccc4)c4oc5ccccc5c4c32)cc(C(C)(C)C)c1] 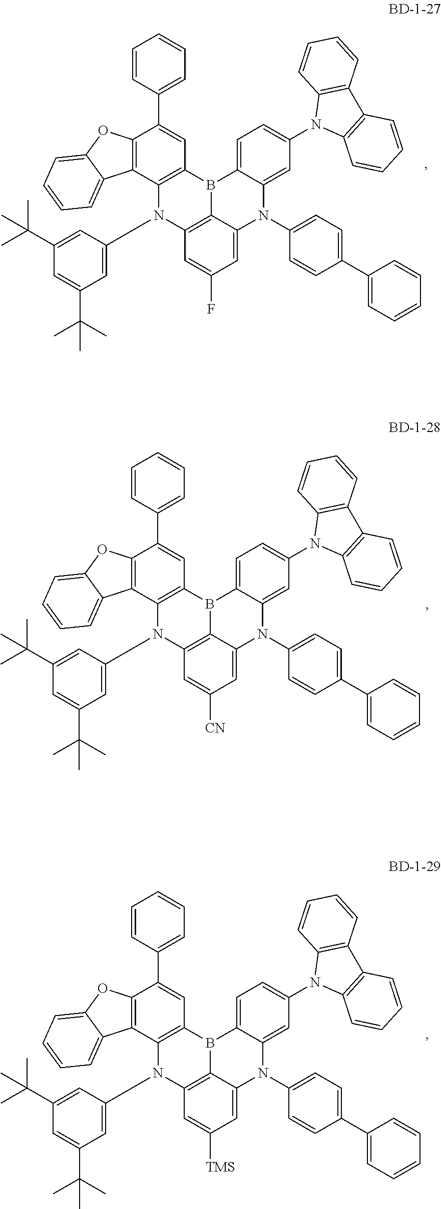 [SMILES: CC(C)(C)c1cc(N2c3cc(F)cc4c3B(c3ccc(-n5c6ccccc6c6ccccc65)cc3N4c3ccc(-c4ccccc4)cc3)c3cc(-c4ccccc4)c4oc5ccccc5c4c32)cc(C(C)(C)C)c1 ; CC(C)(C)c1cc(N2c3cc(C#N)cc4c3B(c3ccc(-n5c6ccccc6c6ccccc65)cc3N4c3ccc(-c4ccccc4)cc3)c3cc(-c4ccccc4)c4oc5ccccc5c4c32)cc(C(C)(C)C)c1 ; CC(C)(C)c1cc(N2c3cc([Si](C)(C)C)cc4c3B(c3ccc(-n5c6ccccc6c6ccccc65)cc3N4c3ccc(-c4ccccc4)cc3)c3cc(-c4ccccc4)c4oc5ccccc5c4c32)cc(C(C)(C)C)c1] 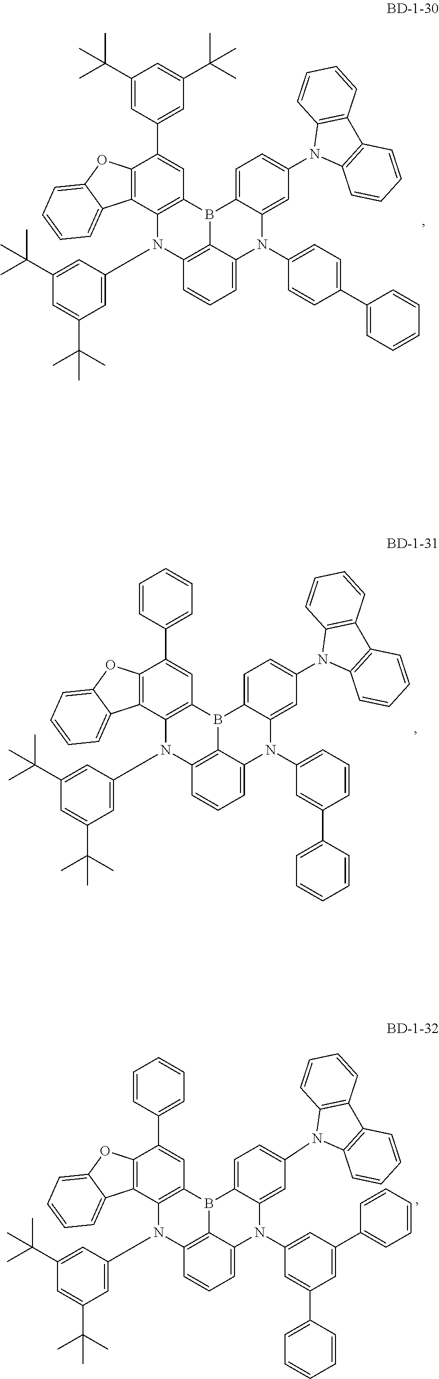 [SMILES: CC(C)(C)c1cc(-c2cc3c(c4c2oc2ccccc24)N(c2cc(C(C)(C)C)cc(C(C)(C)C)c2)c2cccc4c2B3c2ccc(-n3c5ccccc5c5ccccc53)cc2N4c2ccc(-c3ccccc3)cc2)cc(C(C)(C)C)c1 ; CC(C)(C)c1cc(N2c3cccc4c3B(c3ccc(-n5c6ccccc6c6ccccc65)cc3N4c3cccc(-c4ccccc4)c3)c3cc(-c4ccccc4)c4oc5ccccc5c4c32)cc(C(C)(C)C)c1 ; CC(C)(C)c1cc(N2c3cccc4c3B(c3ccc(-n5c6ccccc6c6ccccc65)cc3N4c3cc(-c4ccccc4)cc(-c4ccccc4)c3)c3cc(-c4ccccc4)c4oc5ccccc5c4c32)cc(C(C)(C)C)c1] 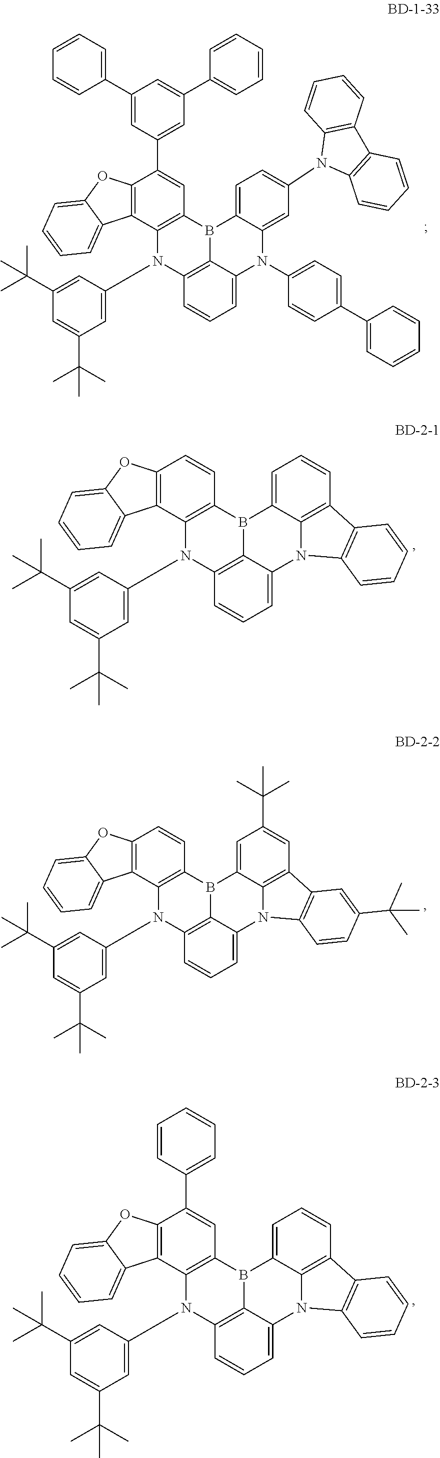 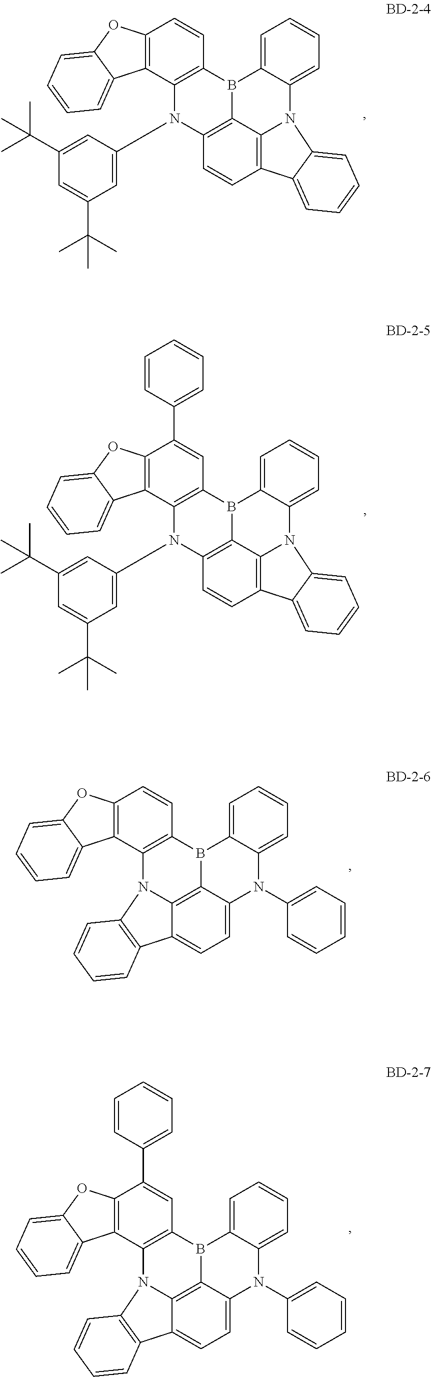 [SMILES: CC(C)(C)c1cc(N2c3ccc4c5ccccc5n5c4c3B(c3ccccc3-5)c3ccc4oc5ccccc5c4c32)cc(C(C)(C)C)c1 ; CC(C)(C)c1cc(N2c3ccc4c5ccccc5n5c4c3B(c3ccccc3-5)c3cc(-c4ccccc4)c4oc5ccccc5c4c32)cc(C(C)(C)C)c1 ; c1ccc(N2c3ccccc3B3c4ccc5oc6ccccc6c5c4-n4c5ccccc5c5ccc2c3c54)cc1 ; c1ccc(-c2cc3c(c4c2oc2ccccc24)-n2c4ccccc4c4ccc5c(c42)B3c2ccccc2N5c2ccccc2)cc1] 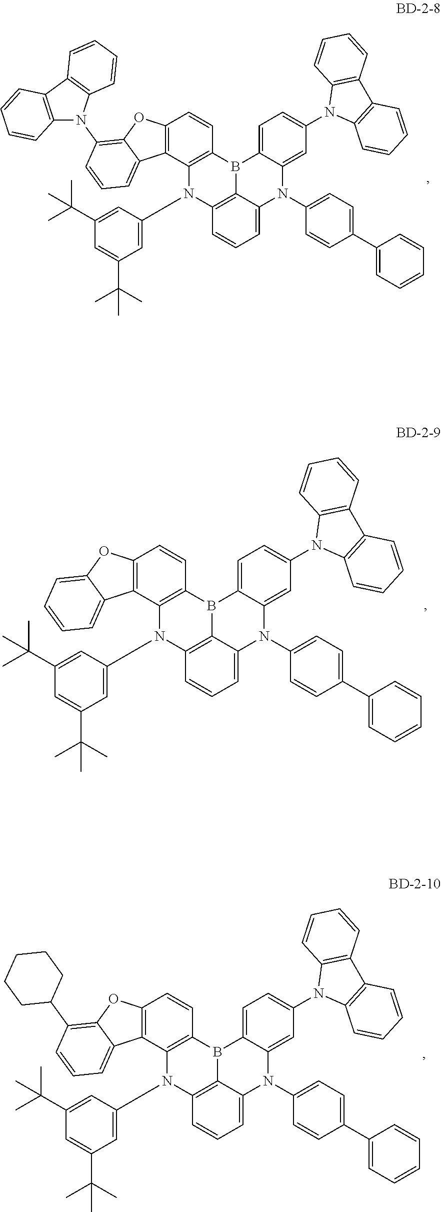 [SMILES: CC(C)(C)c1cc(N2c3cccc4c3B(c3ccc(-n5c6ccccc6c6ccccc65)cc3N4c3ccc(-c4ccccc4)cc3)c3ccc4oc5c(-n6c7ccccc7c7ccccc76)cccc5c4c32)cc(C(C)(C)C)c1 ; CC(C)(C)c1cc(N2c3cccc4c3B(c3ccc(-n5c6ccccc6c6ccccc65)cc3N4c3ccc(-c4ccccc4)cc3)c3ccc4oc5ccccc5c4c32)cc(C(C)(C)C)c1 ; CC(C)(C)c1cc(N2c3cccc4c3B(c3ccc(-n5c6ccccc6c6ccccc65)cc3N4c3ccc(-c4ccccc4)cc3)c3ccc4oc5c(C6CCCCC6)cccc5c4c32)cc(C(C)(C)C)c1] 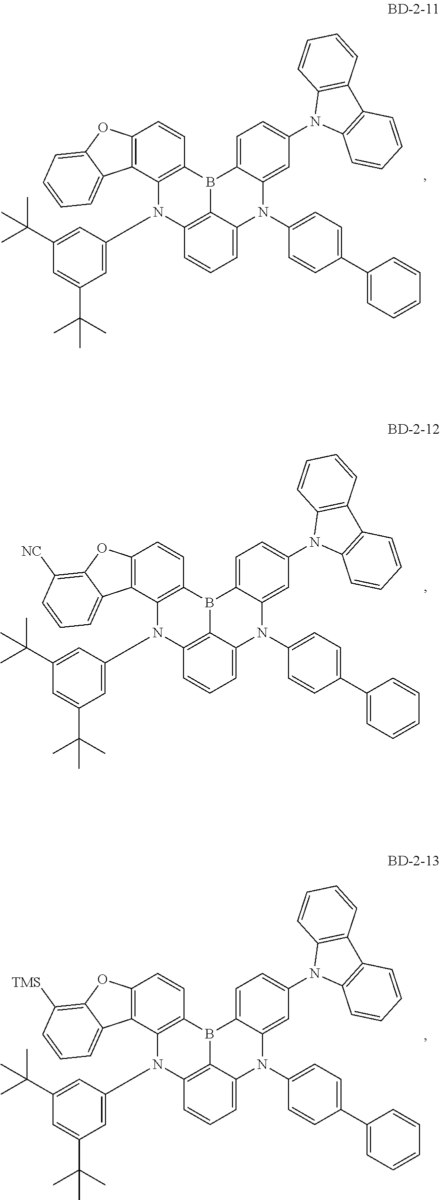 [SMILES: CC(C)(C)c1cc(N2c3cccc4c3B(c3ccc(-n5c6ccccc6c6ccccc65)cc3N4c3ccc(-c4ccccc4)cc3)c3ccc4oc5ccccc5c4c32)cc(C(C)(C)C)c1 ; CC(C)(C)c1cc(N2c3cccc4c3B(c3ccc(-n5c6ccccc6c6ccccc65)cc3N4c3ccc(-c4ccccc4)cc3)c3ccc4oc5c(C#N)cccc5c4c32)cc(C(C)(C)C)c1 ; CC(C)(C)c1cc(N2c3cccc4c3B(c3ccc(-n5c6ccccc6c6ccccc65)cc3N4c3ccc(-c4ccccc4)cc3)c3ccc4oc5c([Si](C)(C)C)cccc5c4c32)cc(C(C)(C)C)c1] 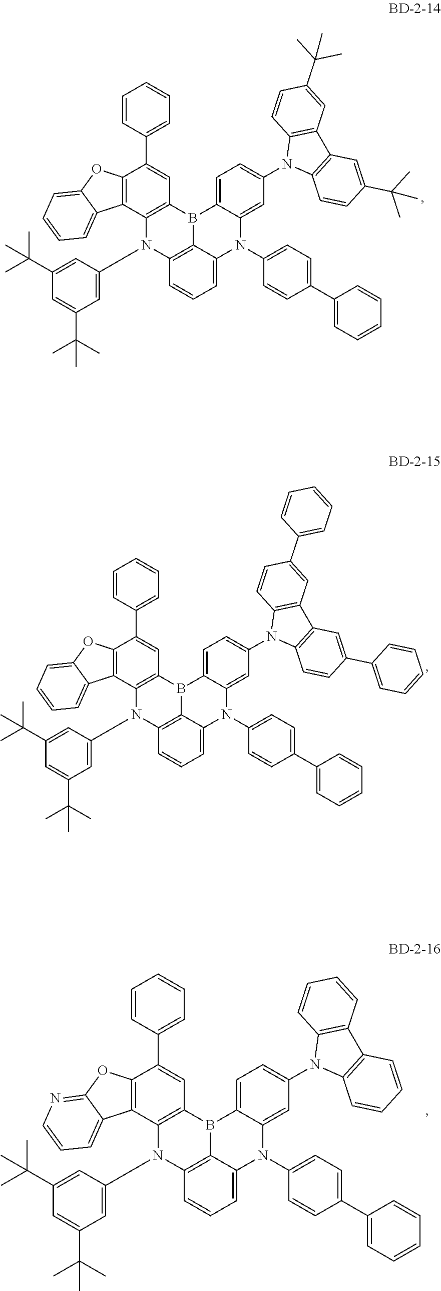 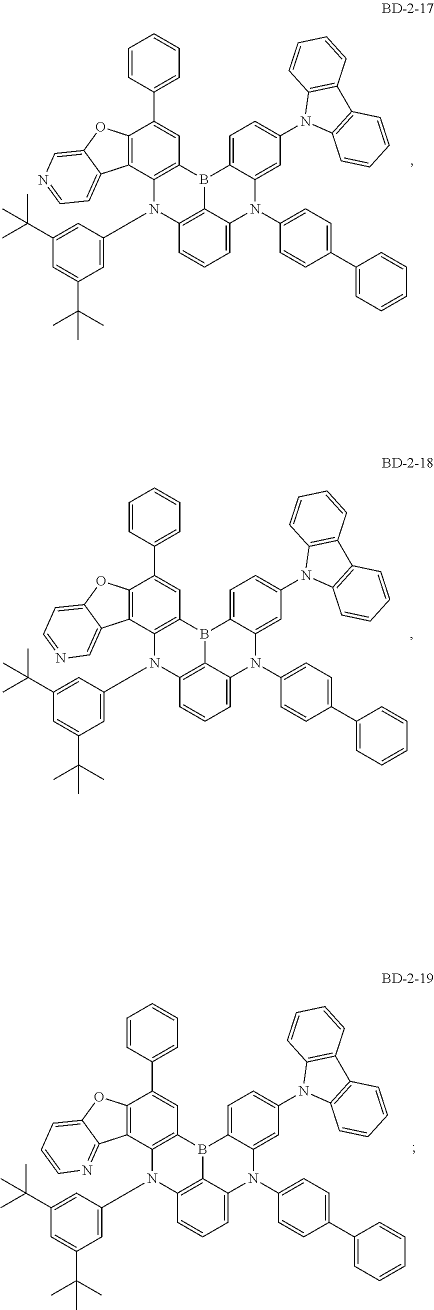 [SMILES: CC(C)(C)c1cc(N2c3cccc4c3B(c3ccc(-n5c6ccccc6c6ccccc65)cc3N4c3ccc(-c4ccccc4)cc3)c3cc(-c4ccccc4)c4oc5cnccc5c4c32)cc(C(C)(C)C)c1 ; CC(C)(C)c1cc(N2c3cccc4c3B(c3ccc(-n5c6ccccc6c6ccccc65)cc3N4c3ccc(-c4ccccc4)cc3)c3cc(-c4ccccc4)c4oc5ccncc5c4c32)cc(C(C)(C)C)c1 ; CC(C)(C)c1cc(N2c3cccc4c3B(c3ccc(-n5c6ccccc6c6ccccc65)cc3N4c3ccc(-c4ccccc4)cc3)c3cc(-c4ccccc4)c4oc5cccnc5c4c32)cc(C(C)(C)C)c1] 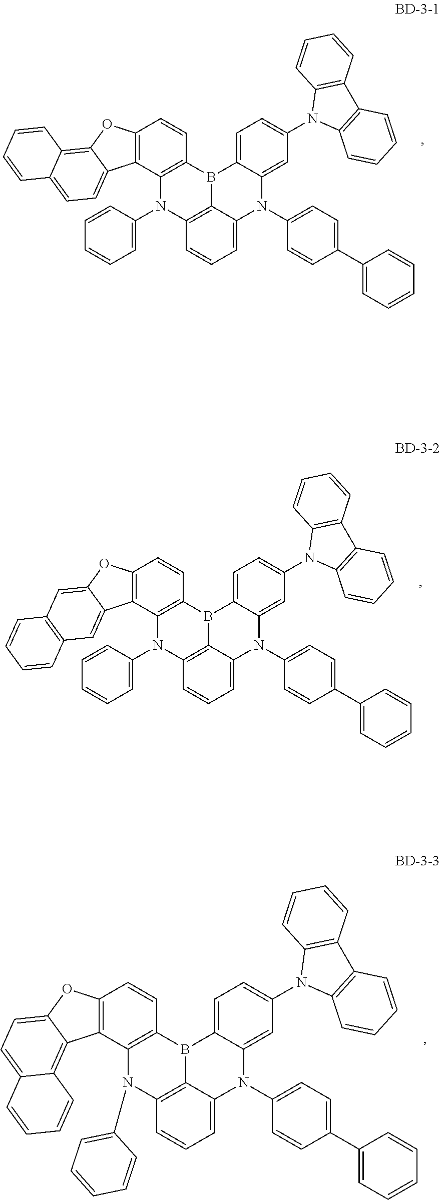 [SMILES: c1ccc(-c2ccc(N3c4cc(-n5c6ccccc6c6ccccc65)ccc4B4c5ccc6oc7c8ccccc8ccc7c6c5N(c5ccccc5)c5cccc3c54)cc2)cc1 ; c1ccc(-c2ccc(N3c4cc(-n5c6ccccc6c6ccccc65)ccc4B4c5ccc6oc7cc8ccccc8cc7c6c5N(c5ccccc5)c5cccc3c54)cc2)cc1 ; c1ccc(-c2ccc(N3c4cc(-n5c6ccccc6c6ccccc65)ccc4B4c5ccc6oc7ccc8ccccc8c7c6c5N(c5ccccc5)c5cccc3c54)cc2)cc1] 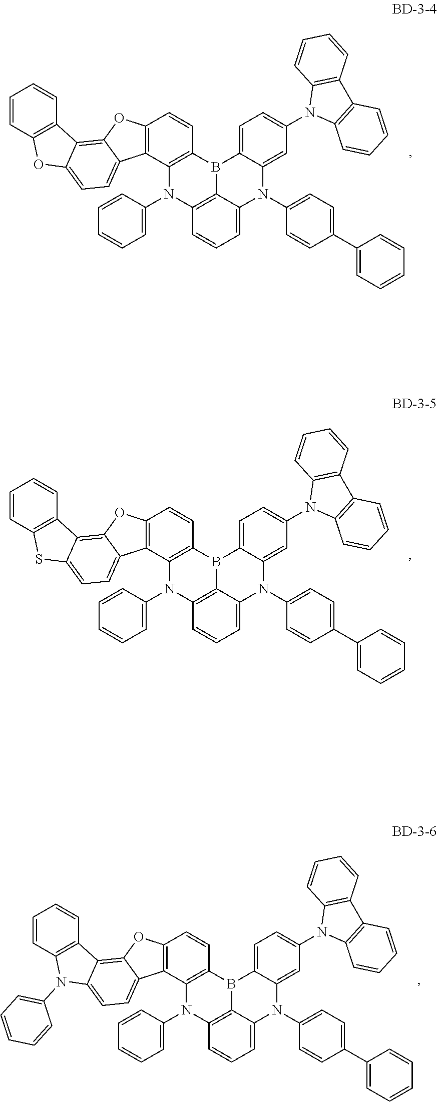 [SMILES: c1ccc(-c2ccc(N3c4cc(-n5c6ccccc6c6ccccc65)ccc4B4c5ccc6oc7c(ccc8oc9ccccc9c87)c6c5N(c5ccccc5)c5cccc3c54)cc2)cc1 ; c1ccc(-c2ccc(N3c4cc(-n5c6ccccc6c6ccccc65)ccc4B4c5ccc6oc7c(ccc8sc9ccccc9c87)c6c5N(c5ccccc5)c5cccc3c54)cc2)cc1 ; c1ccc(-c2ccc(N3c4cc(-n5c6ccccc6c6ccccc65)ccc4B4c5ccc6oc7c(ccc8c7c7ccccc7n8-c7ccccc7)c6c5N(c5ccccc5)c5cccc3c54)cc2)cc1] 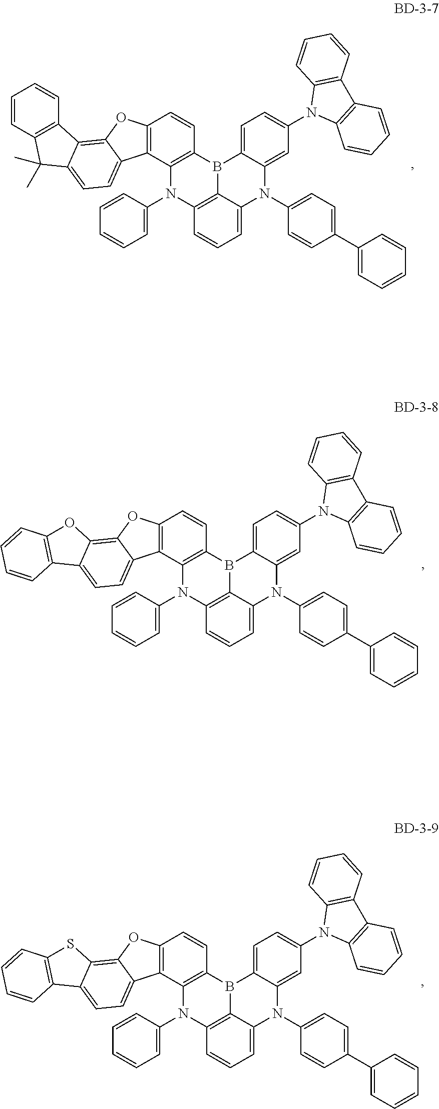 [SMILES: CC1(C)c2ccccc2-c2c1ccc1c2oc2ccc3c(c21)N(c1ccccc1)c1cccc2c1B3c1ccc(-n3c4ccccc4c4ccccc43)cc1N2c1ccc(-c2ccccc2)cc1 ; c1ccc(-c2ccc(N3c4cc(-n5c6ccccc6c6ccccc65)ccc4B4c5ccc6oc7c(ccc8c9ccccc9oc87)c6c5N(c5ccccc5)c5cccc3c54)cc2)cc1 ; c1ccc(-c2ccc(N3c4cc(-n5c6ccccc6c6ccccc65)ccc4B4c5ccc6oc7c(ccc8c9ccccc9sc87)c6c5N(c5ccccc5)c5cccc3c54)cc2)cc1] 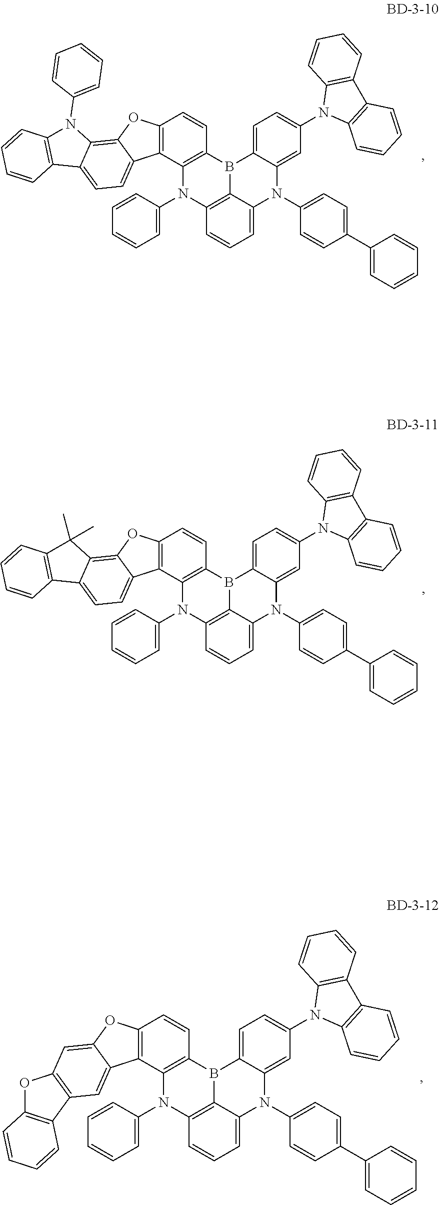 [SMILES: c1ccc(-c2ccc(N3c4cc(-n5c6ccccc6c6ccccc65)ccc4B4c5ccc6oc7c(ccc8c9ccccc9n(-c9ccccc9)c87)c6c5N(c5ccccc5)c5cccc3c54)cc2)cc1 ; CC1(C)c2ccccc2-c2ccc3c(oc4ccc5c(c43)N(c3ccccc3)c3cccc4c3B5c3ccc(-n5c6ccccc6c6ccccc65)cc3N4c3ccc(-c4ccccc4)cc3)c21 ; c1ccc(-c2ccc(N3c4cc(-n5c6ccccc6c6ccccc65)ccc4B4c5ccc6oc7cc8oc9ccccc9c8cc7c6c5N(c5ccccc5)c5cccc3c54)cc2)cc1] 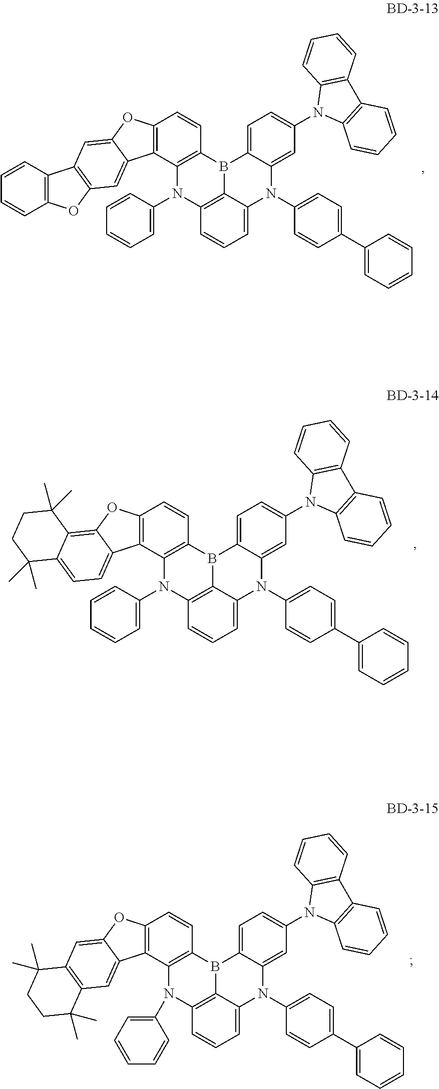 [SMILES: c1ccc(-c2ccc(N3c4cc(-n5c6ccccc6c6ccccc65)ccc4B4c5ccc6oc7cc8c(cc7c6c5N(c5ccccc5)c5cccc3c54)oc3ccccc38)cc2)cc1 ; CC1(C)CCC(C)(C)c2c1ccc1c2oc2ccc3c(c21)N(c1ccccc1)c1cccc2c1B3c1ccc(-n3c4ccccc4c4ccccc43)cc1N2c1ccc(-c2ccccc2)cc1 ; CC1(C)CCC(C)(C)c2cc3c(cc21)oc1ccc2c(c13)N(c1ccccc1)c1cccc3c1B2c1ccc(-n2c4ccccc4c4ccccc42)cc1N3c1ccc(-c2ccccc2)cc1] 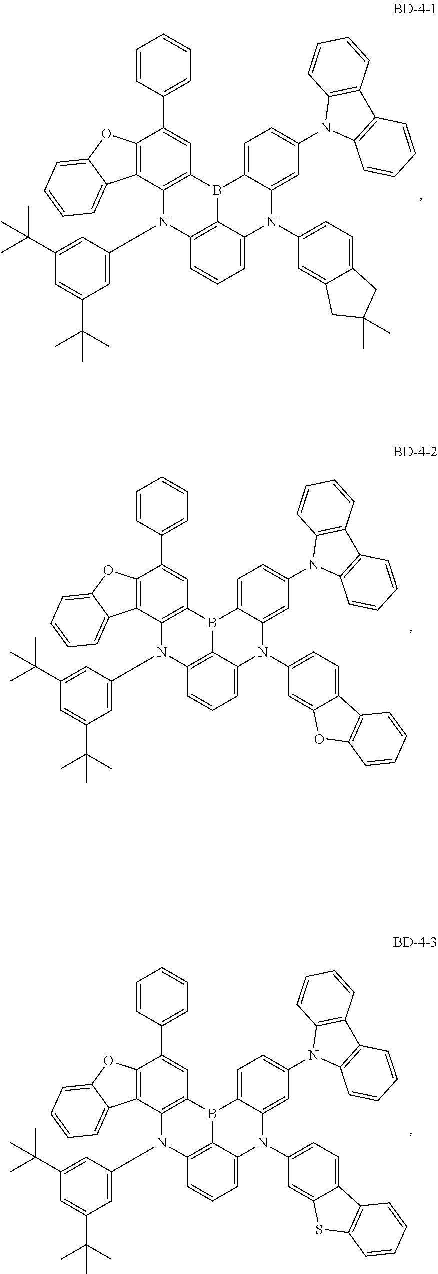 [SMILES: CC1(C)Cc2ccc(N3c4cc(-n5c6ccccc6c6ccccc65)ccc4B4c5cc(-c6ccccc6)c6oc7ccccc7c6c5N(c5cc(C(C)(C)C)cc(C(C)(C)C)c5)c5cccc3c54)cc2C1 ; CC(C)(C)c1cc(N2c3cccc4c3B(c3ccc(-n5c6ccccc6c6ccccc65)cc3N4c3ccc4c(c3)oc3ccccc34)c3cc(-c4ccccc4)c4oc5ccccc5c4c32)cc(C(C)(C)C)c1 ; CC(C)(C)c1cc(N2c3cccc4c3B(c3ccc(-n5c6ccccc6c6ccccc65)cc3N4c3ccc4c(c3)sc3ccccc34)c3cc(-c4ccccc4)c4oc5ccccc5c4c32)cc(C(C)(C)C)c1] 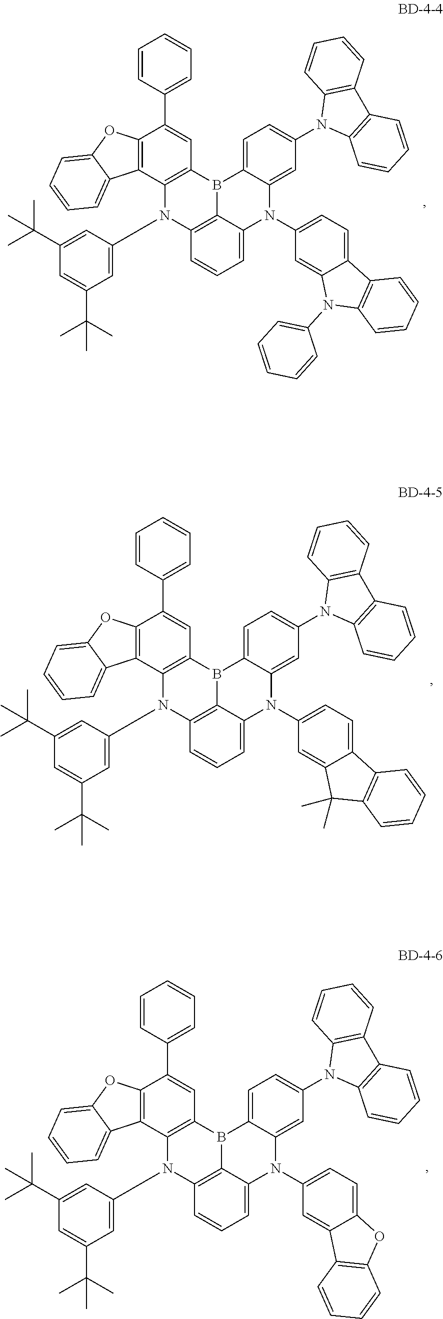 [SMILES: CC(C)(C)c1cc(N2c3cccc4c3B(c3ccc(-n5c6ccccc6c6ccccc65)cc3N4c3ccc4c5ccccc5n(-c5ccccc5)c4c3)c3cc(-c4ccccc4)c4oc5ccccc5c4c32)cc(C(C)(C)C)c1 ; CC(C)(C)c1cc(N2c3cccc4c3B(c3ccc(-n5c6ccccc6c6ccccc65)cc3N4c3ccc4c(c3)C(C)(C)c3ccccc3-4)c3cc(-c4ccccc4)c4oc5ccccc5c4c32)cc(C(C)(C)C)c1 ; CC(C)(C)c1cc(N2c3cccc4c3B(c3ccc(-n5c6ccccc6c6ccccc65)cc3N4c3ccc4oc5ccccc5c4c3)c3cc(-c4ccccc4)c4oc5ccccc5c4c32)cc(C(C)(C)C)c1] 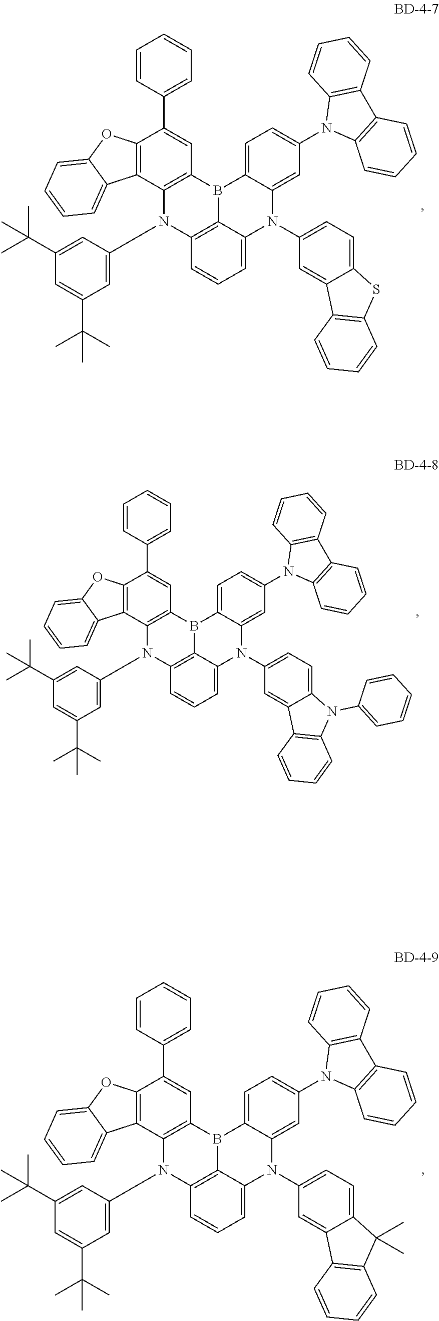 [SMILES: CC(C)(C)c1cc(N2c3cccc4c3B(c3ccc(-n5c6ccccc6c6ccccc65)cc3N4c3ccc4sc5ccccc5c4c3)c3cc(-c4ccccc4)c4oc5ccccc5c4c32)cc(C(C)(C)C)c1 ; CC(C)(C)c1cc(N2c3cccc4c3B(c3ccc(-n5c6ccccc6c6ccccc65)cc3N4c3ccc4c(c3)c3ccccc3n4-c3ccccc3)c3cc(-c4ccccc4)c4oc5ccccc5c4c32)cc(C(C)(C)C)c1 ; CC(C)(C)c1cc(N2c3cccc4c3B(c3ccc(-n5c6ccccc6c6ccccc65)cc3N4c3ccc4c(c3)-c3ccccc3C4(C)C)c3cc(-c4ccccc4)c4oc5ccccc5c4c32)cc(C(C)(C)C)c1] 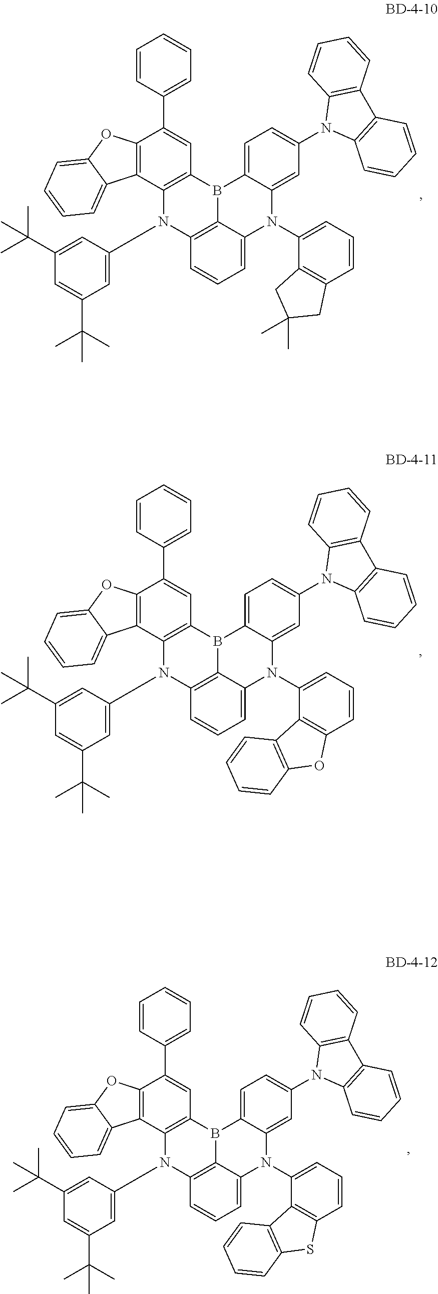 [SMILES: CC1(C)Cc2cccc(N3c4cc(-n5c6ccccc6c6ccccc65)ccc4B4c5cc(-c6ccccc6)c6oc7ccccc7c6c5N(c5cc(C(C)(C)C)cc(C(C)(C)C)c5)c5cccc3c54)c2C1 ; CC(C)(C)c1cc(N2c3cccc4c3B(c3ccc(-n5c6ccccc6c6ccccc65)cc3N4c3cccc4oc5ccccc5c34)c3cc(-c4ccccc4)c4oc5ccccc5c4c32)cc(C(C)(C)C)c1 ; CC(C)(C)c1cc(N2c3cccc4c3B(c3ccc(-n5c6ccccc6c6ccccc65)cc3N4c3cccc4sc5ccccc5c34)c3cc(-c4ccccc4)c4oc5ccccc5c4c32)cc(C(C)(C)C)c1] 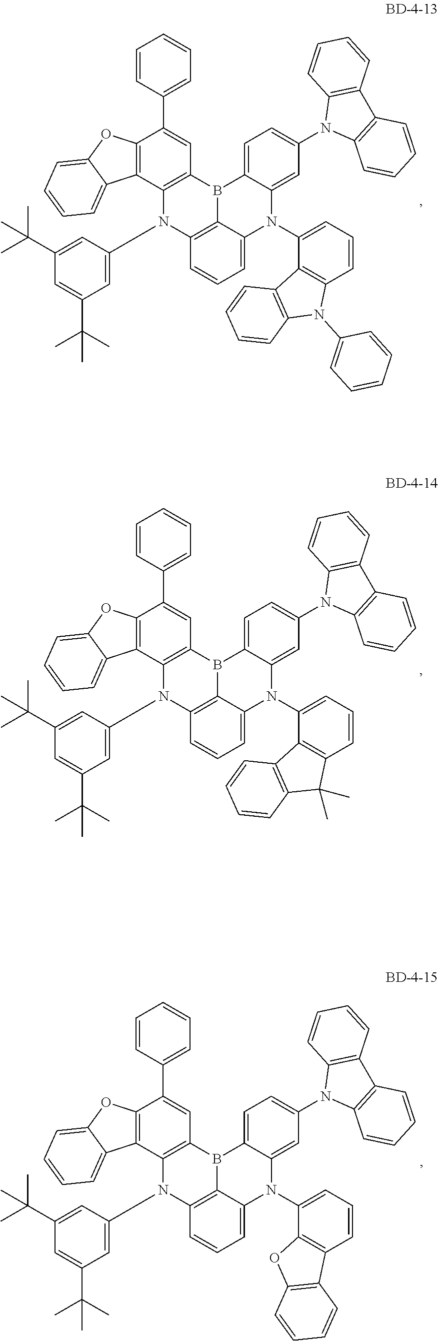 [SMILES: CC(C)(C)c1cc(N2c3cccc4c3B(c3ccc(-n5c6ccccc6c6ccccc65)cc3N4c3cccc4c3c3ccccc3n4-c3ccccc3)c3cc(-c4ccccc4)c4oc5ccccc5c4c32)cc(C(C)(C)C)c1 ; CC(C)(C)c1cc(N2c3cccc4c3B(c3ccc(-n5c6ccccc6c6ccccc65)cc3N4c3cccc4c3-c3ccccc3C4(C)C)c3cc(-c4ccccc4)c4oc5ccccc5c4c32)cc(C(C)(C)C)c1 ; CC(C)(C)c1cc(N2c3cccc4c3B(c3ccc(-n5c6ccccc6c6ccccc65)cc3N4c3cccc4c3oc3ccccc34)c3cc(-c4ccccc4)c4oc5ccccc5c4c32)cc(C(C)(C)C)c1] 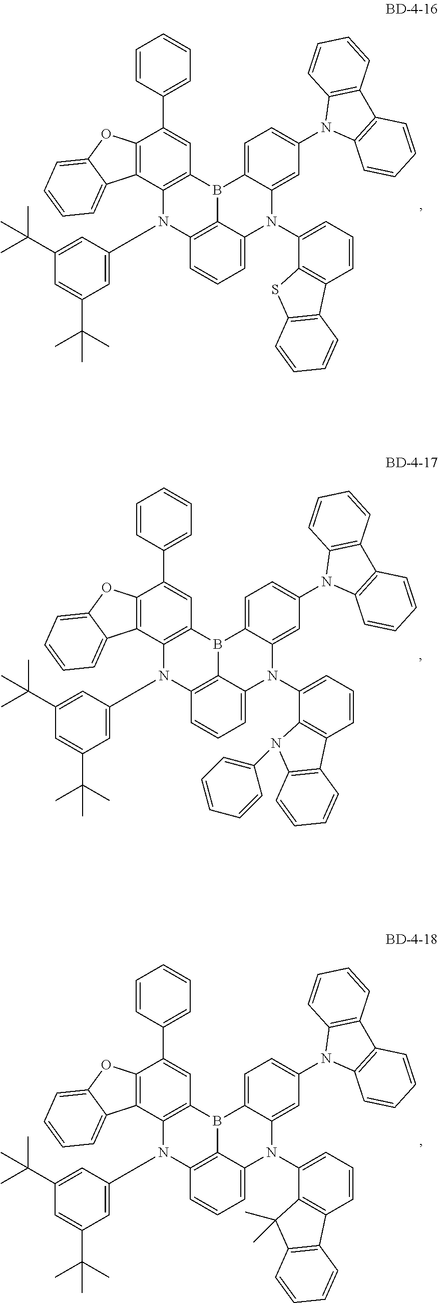 [SMILES: CC(C)(C)c1cc(N2c3cccc4c3B(c3ccc(-n5c6ccccc6c6ccccc65)cc3N4c3cccc4c3sc3ccccc34)c3cc(-c4ccccc4)c4oc5ccccc5c4c32)cc(C(C)(C)C)c1 ; CC(C)(C)c1cc(N2c3cccc4c3B(c3ccc(-n5c6ccccc6c6ccccc65)cc3N4c3cccc4c5ccccc5n(-c5ccccc5)c34)c3cc(-c4ccccc4)c4oc5ccccc5c4c32)cc(C(C)(C)C)c1 ; CC(C)(C)c1cc(N2c3cccc4c3B(c3ccc(-n5c6ccccc6c6ccccc65)cc3N4c3cccc4c3C(C)(C)c3ccccc3-4)c3cc(-c4ccccc4)c4oc5ccccc5c4c32)cc(C(C)(C)C)c1] 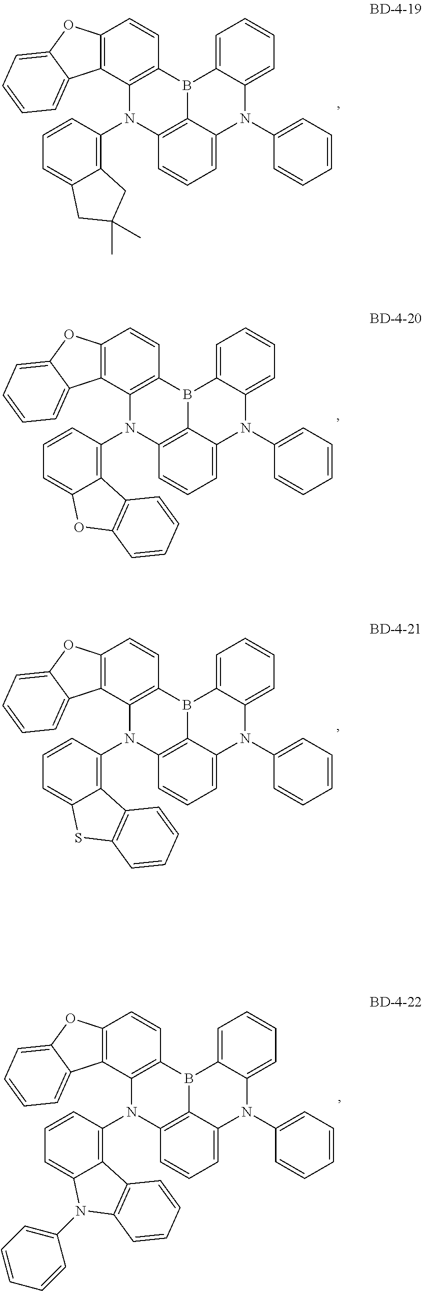 [SMILES: CC1(C)Cc2cccc(N3c4cccc5c4B(c4ccccc4N5c4ccccc4)c4ccc5oc6ccccc6c5c43)c2C1 ; c1ccc(N2c3ccccc3B3c4ccc5oc6ccccc6c5c4N(c4cccc5oc6ccccc6c45)c4cccc2c43)cc1 ; c1ccc(N2c3ccccc3B3c4ccc5oc6ccccc6c5c4N(c4cccc5sc6ccccc6c45)c4cccc2c43)cc1 ; c1ccc(N2c3ccccc3B3c4ccc5oc6ccccc6c5c4N(c4cccc5c4c4ccccc4n5-c4ccccc4)c4cccc2c43)cc1] 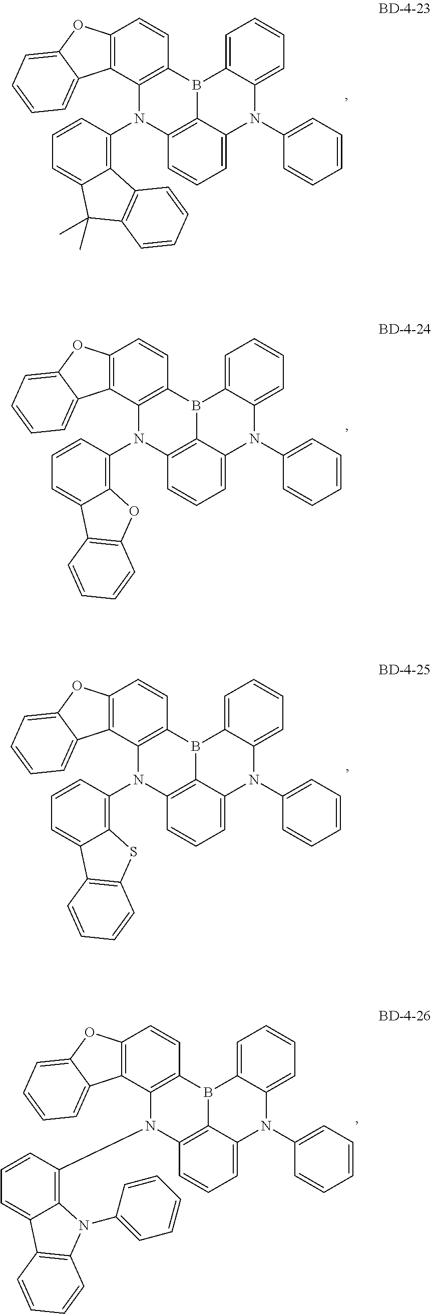 [SMILES: CC1(C)c2ccccc2-c2c(N3c4cccc5c4B(c4ccccc4N5c4ccccc4)c4ccc5oc6ccccc6c5c43)cccc21 ; c1ccc(N2c3ccccc3B3c4ccc5oc6ccccc6c5c4N(c4cccc5c4oc4ccccc45)c4cccc2c43)cc1 ; c1ccc(N2c3ccccc3B3c4ccc5oc6ccccc6c5c4N(c4cccc5c4sc4ccccc45)c4cccc2c43)cc1 ; c1ccc(N2c3ccccc3B3c4ccc5oc6ccccc6c5c4N(c4cccc5c6ccccc6n(-c6ccccc6)c45)c4cccc2c43)cc1] 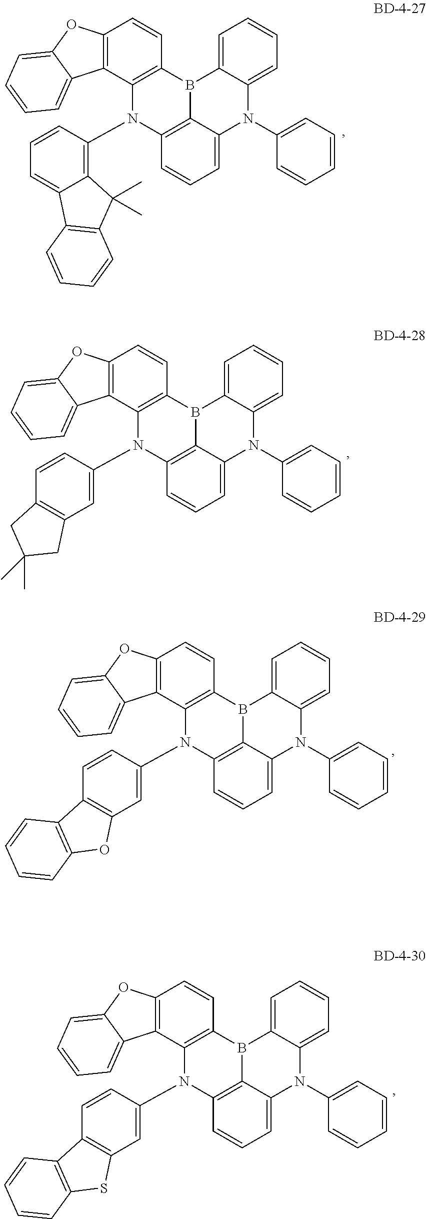 [SMILES: CC1(C)c2ccccc2-c2cccc(N3c4cccc5c4B(c4ccccc4N5c4ccccc4)c4ccc5oc6ccccc6c5c43)c21 ; CC1(C)Cc2ccc(N3c4cccc5c4B(c4ccccc4N5c4ccccc4)c4ccc5oc6ccccc6c5c43)cc2C1 ; c1ccc(N2c3ccccc3B3c4ccc5oc6ccccc6c5c4N(c4ccc5c(c4)oc4ccccc45)c4cccc2c43)cc1 ; c1ccc(N2c3ccccc3B3c4ccc5oc6ccccc6c5c4N(c4ccc5c(c4)sc4ccccc45)c4cccc2c43)cc1] 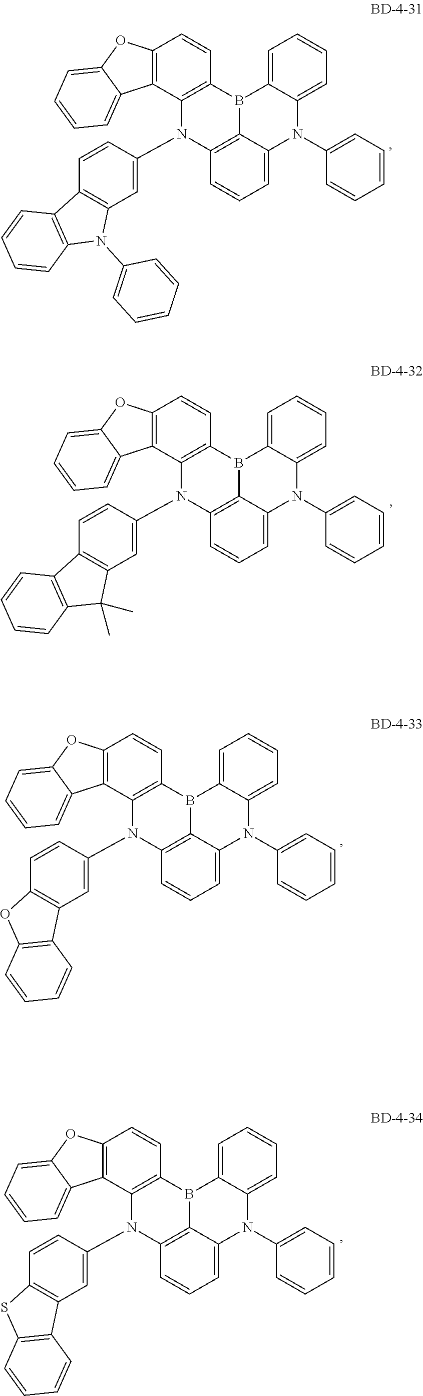 [SMILES: c1ccc(N2c3ccccc3B3c4ccc5oc6ccccc6c5c4N(c4ccc5c6ccccc6n(-c6ccccc6)c5c4)c4cccc2c43)cc1 ; CC1(C)c2ccccc2-c2ccc(N3c4cccc5c4B(c4ccccc4N5c4ccccc4)c4ccc5oc6ccccc6c5c43)cc21 ; c1ccc(N2c3ccccc3B3c4ccc5oc6ccccc6c5c4N(c4ccc5oc6ccccc6c5c4)c4cccc2c43)cc1 ; c1ccc(N2c3ccccc3B3c4ccc5oc6ccccc6c5c4N(c4ccc5sc6ccccc6c5c4)c4cccc2c43)cc1] 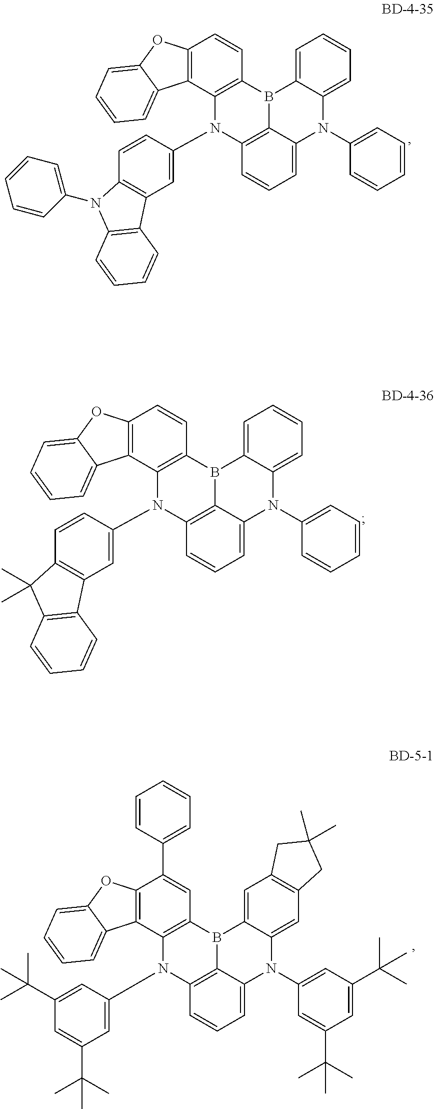 [SMILES: c1ccc(N2c3ccccc3B3c4ccc5oc6ccccc6c5c4N(c4ccc5c(c4)c4ccccc4n5-c4ccccc4)c4cccc2c43)cc1 ; CC1(C)c2ccccc2-c2cc(N3c4cccc5c4B(c4ccccc4N5c4ccccc4)c4ccc5oc6ccccc6c5c43)ccc21 ; CC1(C)Cc2cc3c(cc2C1)N(c1cc(C(C)(C)C)cc(C(C)(C)C)c1)c1cccc2c1B3c1cc(-c3ccccc3)c3oc4ccccc4c3c1N2c1cc(C(C)(C)C)cc(C(C)(C)C)c1] 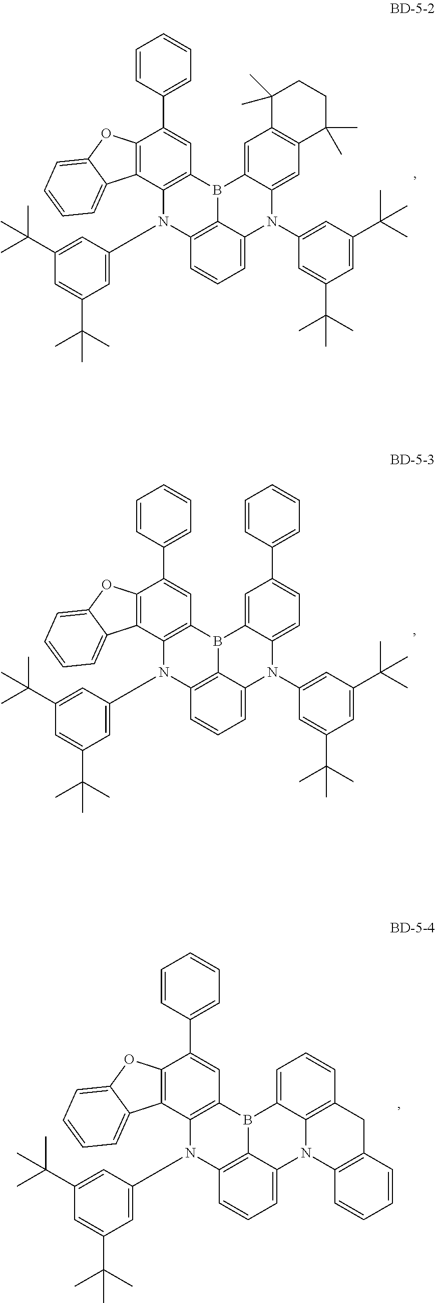 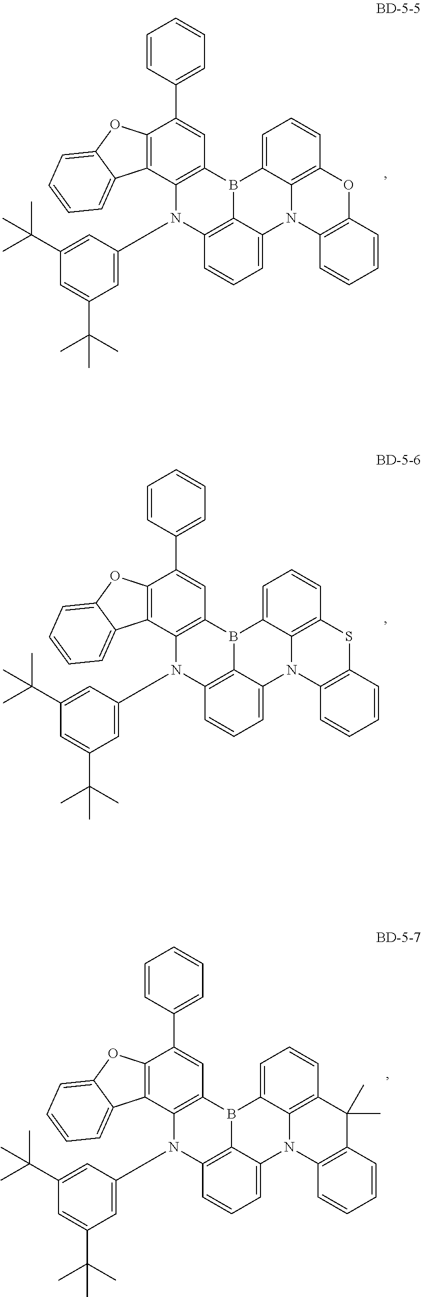 [SMILES: CC(C)(C)c1cc(N2c3cccc4c3B(c3cccc5c3N4c3ccccc3O5)c3cc(-c4ccccc4)c4oc5ccccc5c4c32)cc(C(C)(C)C)c1 ; CC(C)(C)c1cc(N2c3cccc4c3B(c3cccc5c3N4c3ccccc3S5)c3cc(-c4ccccc4)c4oc5ccccc5c4c32)cc(C(C)(C)C)c1 ; CC(C)(C)c1cc(N2c3cccc4c3B(c3cccc5c3N4c3ccccc3C5(C)C)c3cc(-c4ccccc4)c4oc5ccccc5c4c32)cc(C(C)(C)C)c1] 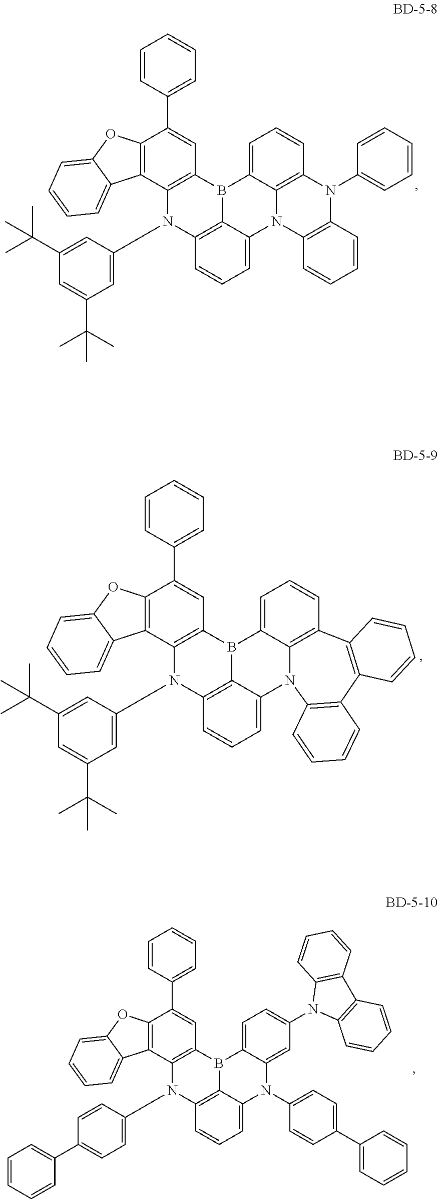 [SMILES: CC(C)(C)c1cc(N2c3cccc4c3B(c3cccc5c3N4c3ccccc3N5c3ccccc3)c3cc(-c4ccccc4)c4oc5ccccc5c4c32)cc(C(C)(C)C)c1 ; CC(C)(C)c1cc(N2c3cccc4c3B(c3cccc5c3N4c3ccccc3-c3ccccc3-5)c3cc(-c4ccccc4)c4oc5ccccc5c4c32)cc(C(C)(C)C)c1 ; c1ccc(-c2ccc(N3c4cc(-n5c6ccccc6c6ccccc65)ccc4B4c5cc(-c6ccccc6)c6oc7ccccc7c6c5N(c5ccc(-c6ccccc6)cc5)c5cccc3c54)cc2)cc1] 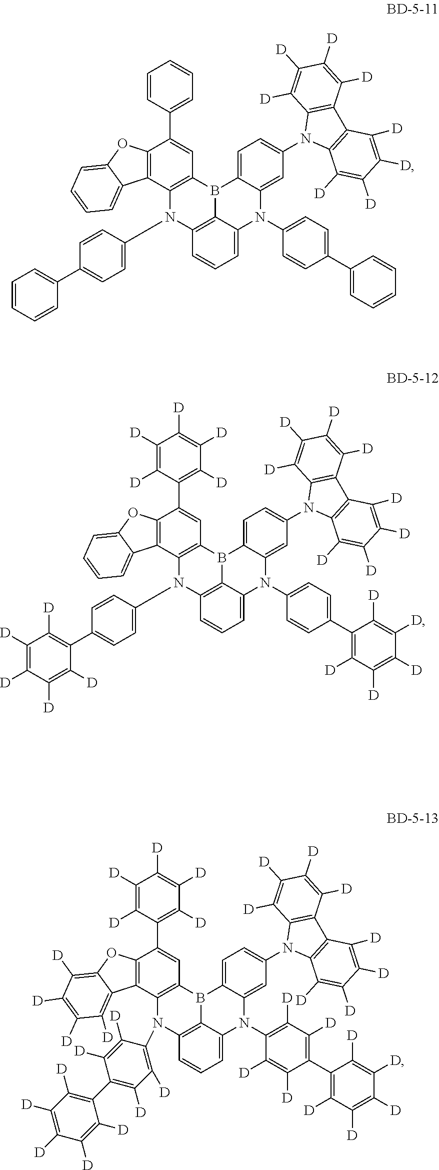 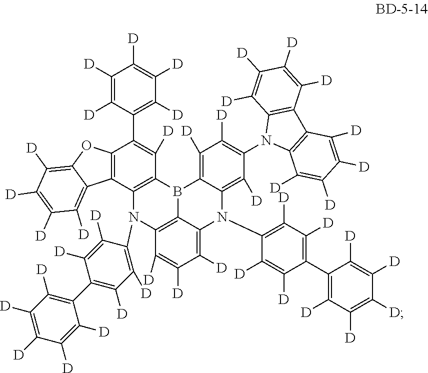
wherein optionally, hydrogens in the structures of Compound BD-1-1 to Compound BD-1-33, Compound BD-2-1 to Compound BD-2-19, Compound BD-3-1 to Compound BD-3-15, Compound BD-4-1 to Compound BD-4-36, and Compound BD-5-1 to Compound BD-5-13 can be partially or fully substituted with deuterium.

9. The organic electroluminescent device according to claim 1, wherein a maximum emission wavelength λ_{max-PL-1} of a photoluminescence spectrum of the fluorescent material is 450 nm to 500 nm;
preferably, the maximum emission wavelength λ_{max-PL-1} of the photoluminescence spectrum of the fluorescent material is 450 nm to 470 nm;
more preferably, the maximum emission wavelength λ_{max-PL-1} of the photoluminescence spectrum of the fluorescent material is 455 nm to 465 nm.

10. The organic electroluminescent device according to claim 1, wherein a full width at half maximum FWHM-_{PL-1} of a photoluminescence spectrum of the fluorescent material is less than or equal to 45 nm;
preferably, the full width at half maximum FWHM-_{PL-1} of the photoluminescence spectrum of the fluorescent material is less than or equal to 35 nm;
more preferably, the full width at half maximum FWHM-_{PL-1} of the photoluminescence spectrum of the fluorescent material is less than or equal to 25 nm.

11. The organic electroluminescent device according to claim 1, wherein the metal complex has a general formula of M(Lₐ)ₘ(L_{b})ₙ(L_{c})_{q};
Lₐ, L_{b}, and L_{c} are a first ligand, a second ligand, and a third ligand coordinated to the metal M, respectively; Lₐ, L_{b}, and L_{c} are identical or different;
the ligands Lₐ, L_{b}, and L_{c} can be optionally joined to form a multidentate ligand;
m is 1, 2, or 3, n is 0, 1, or 2, q is 0, 1, or 2, and m+n+q is equal to the oxidation state of the metal M; when m is greater than or equal to 2, multiple Lₐ are identical or different; when n is 2, two L_{b} are identical or different; when q is 2, two L_{c} are identical or different; and
the ligands L_{b} and L_{c} are, at each occurrence identically or differently, selected from a monoanionic bidentate ligand;
preferably, the ligands L_{b} and L_{c} are, at each occurrence identically or differently, selected from the group consisting of the following structures: 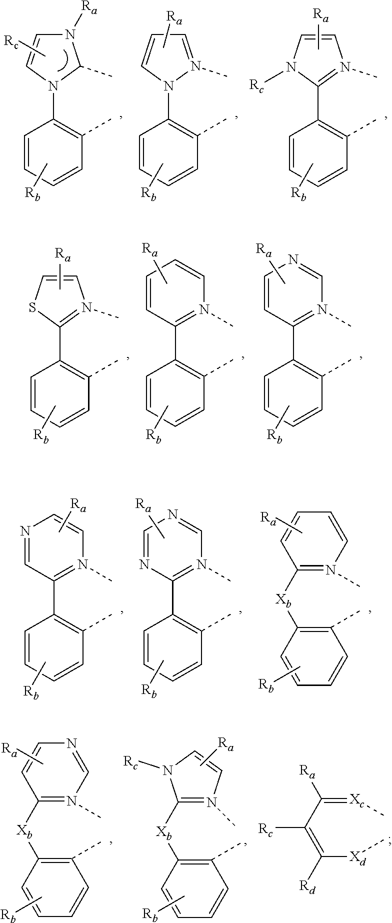
wherein
Rₐ and R_{b} represent, at each occurrence identically or differently, mono-substitution, multiple substitutions, or non-substitution;
X_{b} is, at each occurrence identically or differently, selected from the group consisting of: O, S, Se, NR_{N1}, and CR_{C1}R_{C2};
X_{c} and X_{d} are, at each occurrence identically or differently, selected from the group consisting of: O, S, Se, and NR_{N2};
Rₐ, R_{b}, R_{c}, R_{N1}, R_{N2}, R_{C1}, and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
adjacent substituents R, R_{b}, R_{c}, R_{N1}, R_{N2}, R_{C1}, and R_{C2} can be optionally joined to form a ring.

12. The organic electroluminescent device according to claim 11, wherein the metal M is selected from the group consisting of Cu, Ag, Au, Zn, Ru, Rh, Pd, Os, Ir, and Pt;
preferably, the metal M is selected from Ir, Pt, or Pd.

13. The organic electroluminescent device according to claim 11, wherein the metal complex has a structure represented by Formula 3: 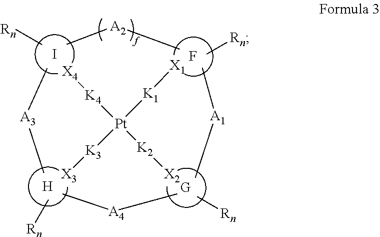
wherein in Formula 3,
the ring F, the ring G, the ring H, and the ring I are each independently selected from an unsaturated carbocyclic ring having 5 to 30 carbon atoms, an unsaturated heterocyclic ring having 1 to 30 carbon atoms, or a combination thereof;
f is selected from 0 or 1;
A₁ to A₄ are, at each occurrence identically or differently, selected from a single bond, O, S, Se, (SiR_{q}R_{q})_{y}, PR_{q}, NR_{q}, (CF_{q})_{y}, substituted or unsubstituted arylene having 6 to 30 carbon atoms, substituted or unsubstituted heteroarylene having 3 to 30 carbon atoms, or a combination thereof, wherein y is, at each occurrence identically or differently, selected from 1, 2, 3, 4, or 5;
X₁ to X₄ are each independently selected from C or N;
K₁ to K₄ are each independently selected from a single bond, O, or S;
Rₙ represents, at each occurrence identically or differently, mono-substitution, multiple substitutions, or non-substitution;
R_{q} and Rₙ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof, and
adjacent substituents R_{q}, Rₙ can be optionally joined to form a ring.

14. The organic electroluminescent device according to claim 13, wherein the metal complex has a structure represented by Formula 3-A: 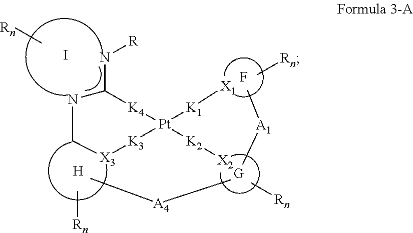
wherein in Formula 3-A,
the ring F, the ring G, and the ring H are each independently selected from an unsaturated carbocyclic ring having 5 to 30 carbon atoms, an unsaturated heterocyclic ring having 3 to 30 carbon atoms, or a combination thereof, and the ring I is selected from an unsaturated heterocyclic ring having 1 to 30 carbon atoms;
A₁ and A₄ are each independently selected from a single bond, O, S, Se, (SiR_{q}R_{q})_{y}, PR_{q}, NR_{q}, (CR_{q}R_{q})_{y}, substituted or unsubstituted arylene having 6 to 30 carbon atoms, substituted or unsubstituted heteroarylene having 3 to 30 carbon atoms, or a combination thereof, wherein y is, at each occurrence identically or differently, selected from 1, 2, 3, 4, or 5;
K₁ to K₄ are each independently selected from a single bond, O, or S;
X₁ to X₃ are each independently selected from C or N;
Rₙ represents, at each occurrence identically or differently, mono-substitution, multiple substitutions, or non-substitution;
R, R_{q}, and Rₙ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof, and
adjacent substituents R, R_{q}, Rₙ can be optionally joined to form a ring.

15. The organic electroluminescent device according to claim 14, wherein the ring F, the ring G, and the ring H are each independently selected from a five-membered unsaturated carbocyclic ring, an aromatic ring having 6 to 30 carbon atoms, or a heteroaromatic ring having 3 to 30 carbon atoms, and the ring I is, at each occurrence identically or differently, selected from an unsaturated heterocyclic ring having 3 to 30 carbon atoms;
preferably, the ring F, the ring G, and the ring H are each independently selected from a five-membered unsaturated carbocyclic ring, an aromatic ring having 6 to 18 carbon atoms, or a heteroaromatic ring having 3 to 18 carbon atoms, and the ring I is, at each occurrence identically or differently, selected from an unsaturated heterocyclic ring having 3 to 18 carbon atoms;
more preferably, the ring F, the ring G, and the ring H are each independently selected from a benzene ring, a pyridine ring, an indene ring, a fluorene ring, an indole ring, a carbazole ring, a benzofuran ring, a dibenzofuran ring, a benzosilole ring, a dibenzosilole ring, a benzothiophene ring, a dibenzothiophene ring, a dibenzoselenophene ring, a cyclopentadienyl ring, a furan ring, a thiophene ring, or a silole ring, and the ring I is, at each occurrence identically or differently, selected from an imidazole-carbene ring or a benzimidazole-carbene ring.

16. The organic electroluminescent device according to claim 14, wherein K₁ to K₄ are each selected from a single bond.

17. The organic electroluminescent device according to claim 1, wherein the metal complex has a structure represented by one of Formula 3-1 to Formula 3-20: 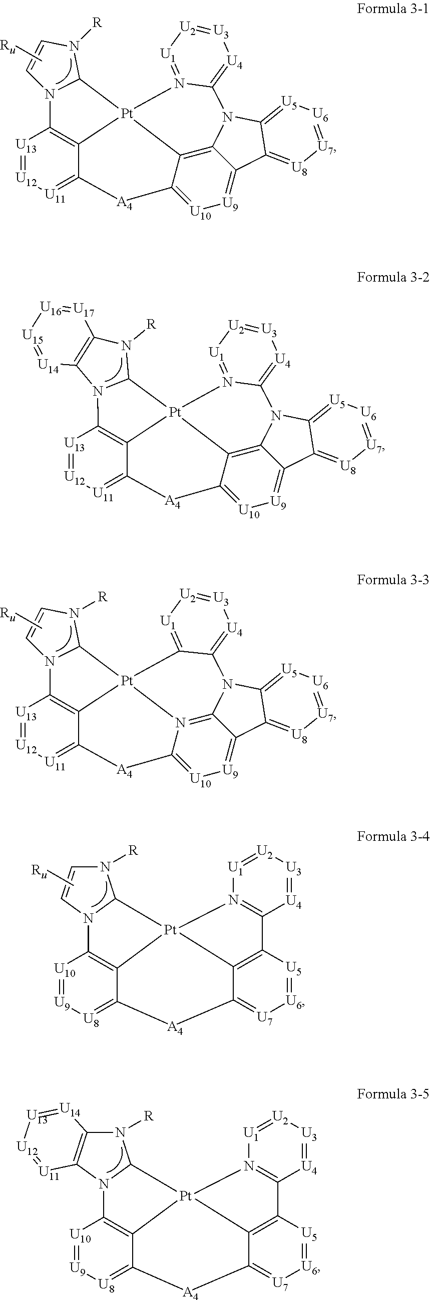 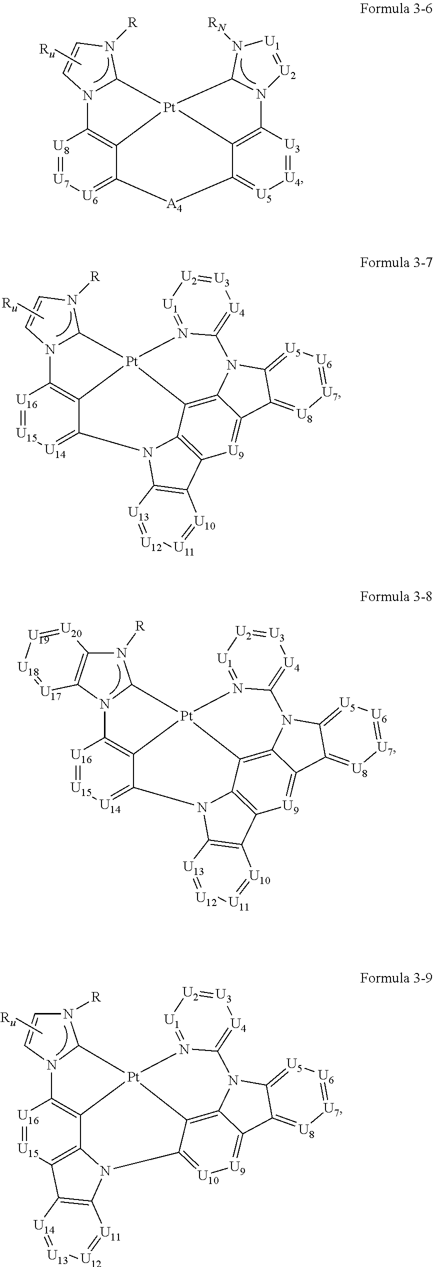 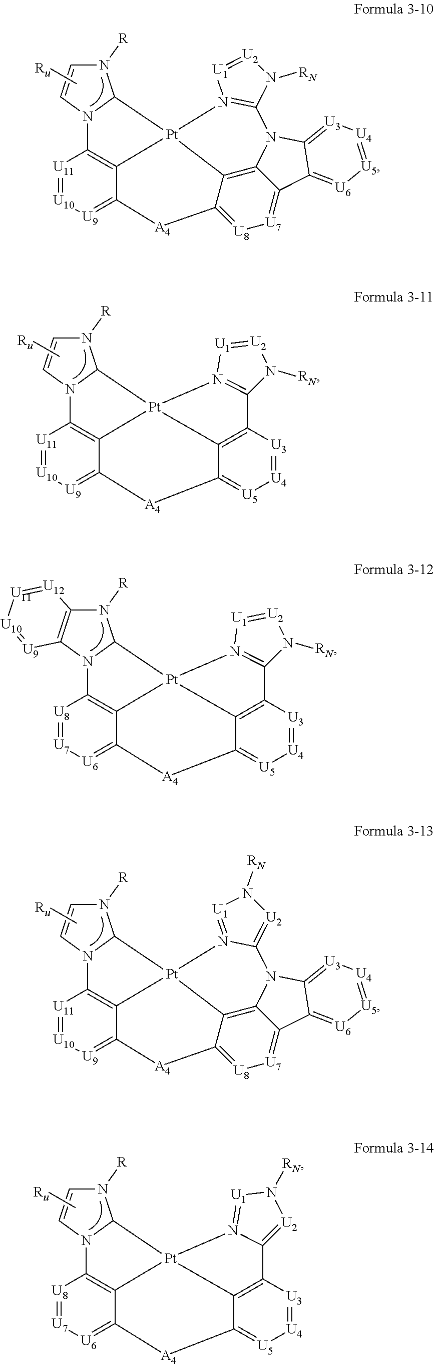 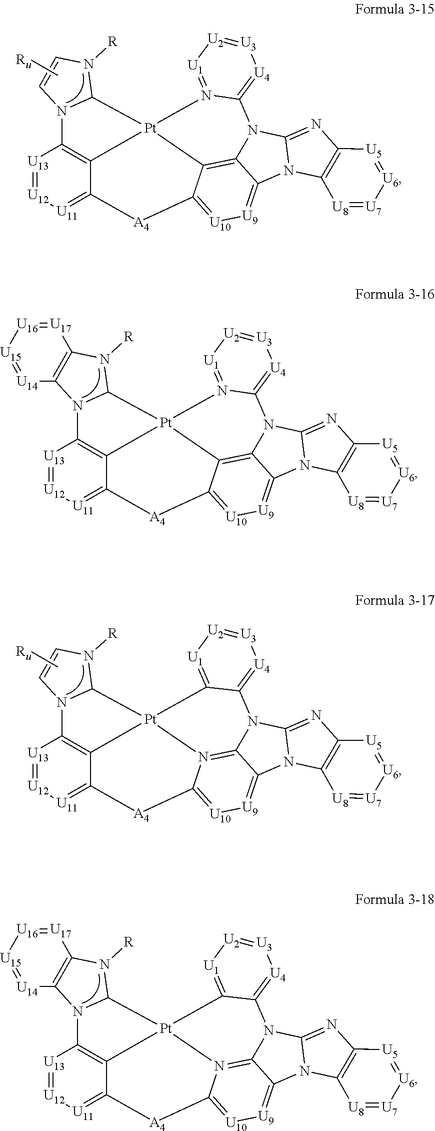 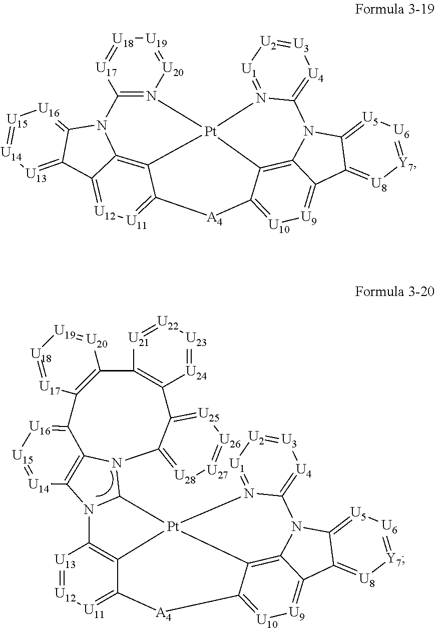
wherein
A₄ is, at each occurrence identically or differently, selected from a single bond, O, S, Se, (SiR_{q}R_{q})_{y}, PR_{q}, NR_{q}, substituted or unsubstituted arylene having 6 to 30 carbon atoms, substituted or unsubstituted heteroarylene having 3 to 30 carbon atoms, or a combination thereof, wherein y is, at each occurrence identically or differently, selected from 1, 2, or 3;
U₁ to U₂₈ are, at each occurrence identically or differently, selected from CRₙ or N;
Rᵤ represents, at each occurrence identically or differently, mono-substitution, multiple substitutions, or non-substitution;
R, R_{N}, R_{q}, Rᵤ, and Rₙ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof, and
adjacent substituents R, R_{N}, R_{q}, Rᵤ, and Rₙ can be optionally joined to form a ring;
preferably, the metal complex has a structure represented by Formula 3-1 or Formula 3-2;
more preferably, the substituent R has a structure represented by Formula 4: 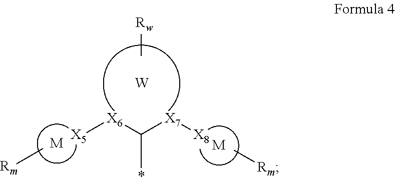
wherein in Formula 4,
the ring M and the ring W are, at each occurrence identically or differently, selected from an unsaturated carbocyclic ring having 5 to 30 carbon atoms, an unsaturated heterocyclic ring having 3 to 30 carbon atoms, or a combination thereof;
X₅ to X₈ are, at each occurrence identically or differently, selected from C or N;
“*” represents a position where Formula 4 is joined;
Rₘ and R_{w} represent, at each occurrence identically or differently, mono-substitution, multiple substitutions, or non-substitution;
Rₘ and R_{w} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof, and
adjacent substituents Rₘ, R_{w} can be optionally joined to form a ring;
most preferably, the substituent R has a structure represented by Formula 4-1: 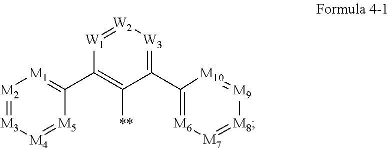
wherein in Formula 4-1,
M₁ to M₁₀ are each independently selected from CRₘ or N;
W₁ to W₃ are each independently selected from CR_{w} or N;
“**” represents a position where Formula 4-1 is joined;
Rₘ and R_{w} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
adjacent substituents Rₘ, R_{w} can be optionally joined to form a ring.

18. The organic electroluminescent device according to claim 1, wherein the metal complex is selected from the group consisting of BD1 to BD18: 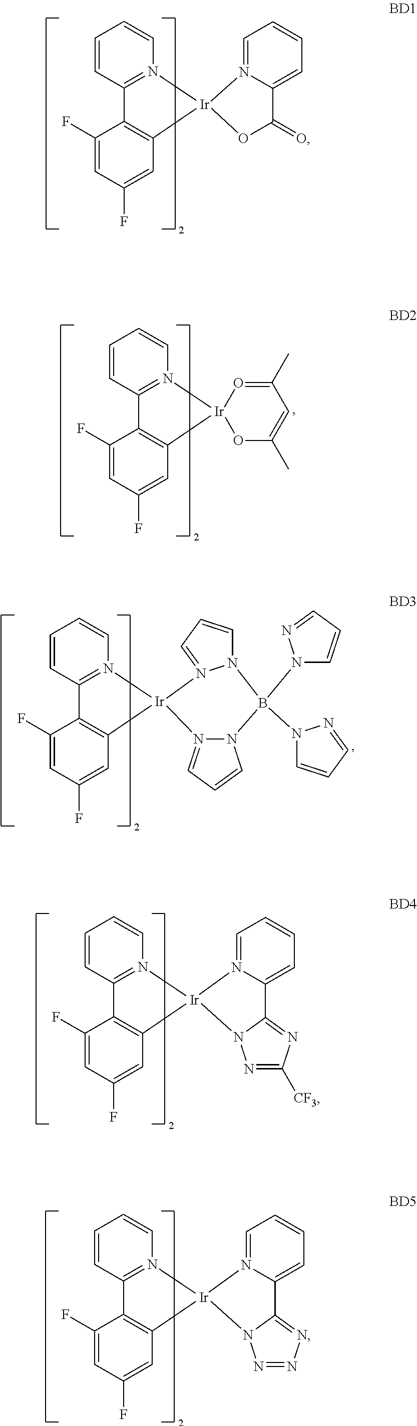 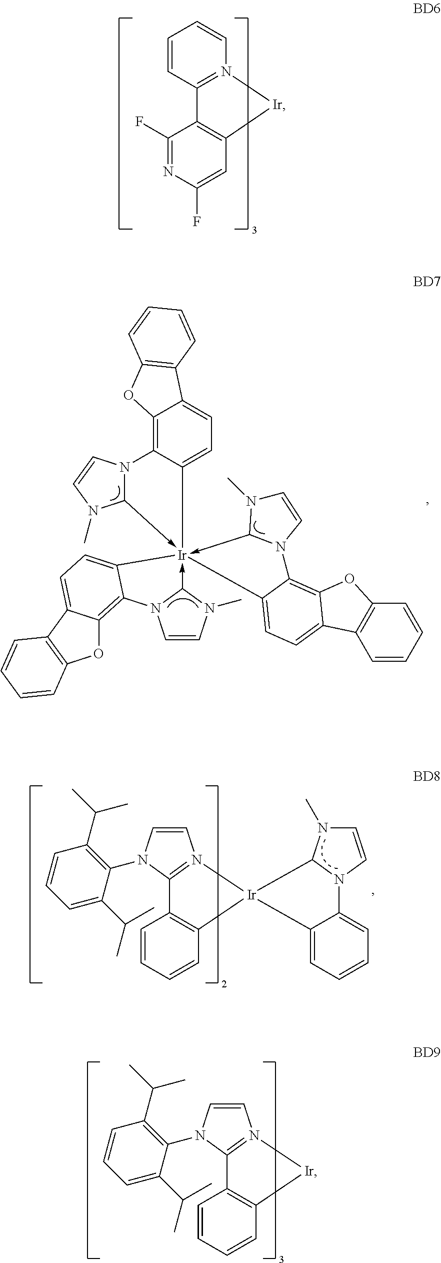 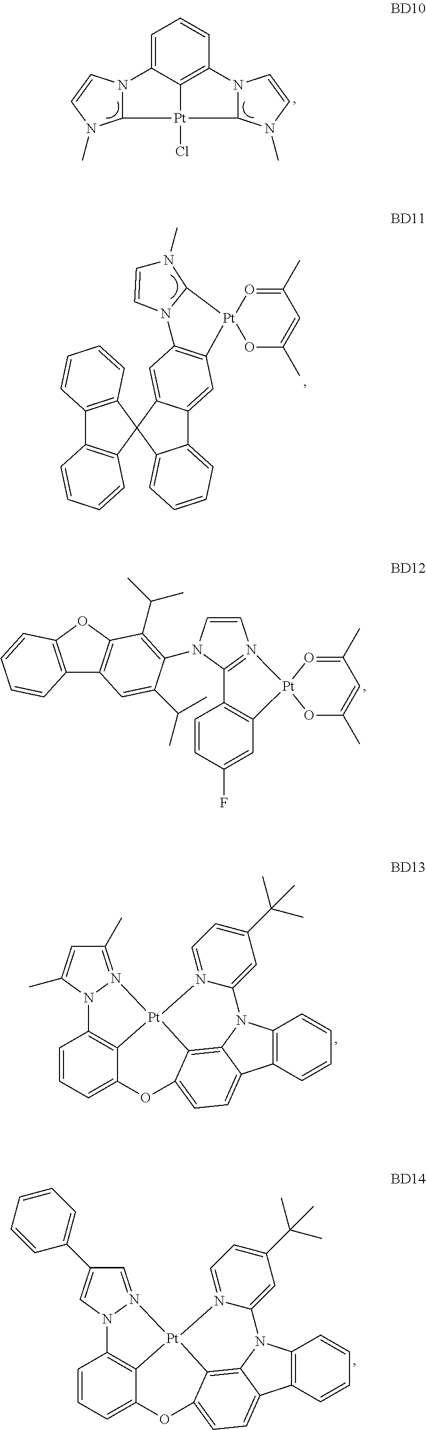 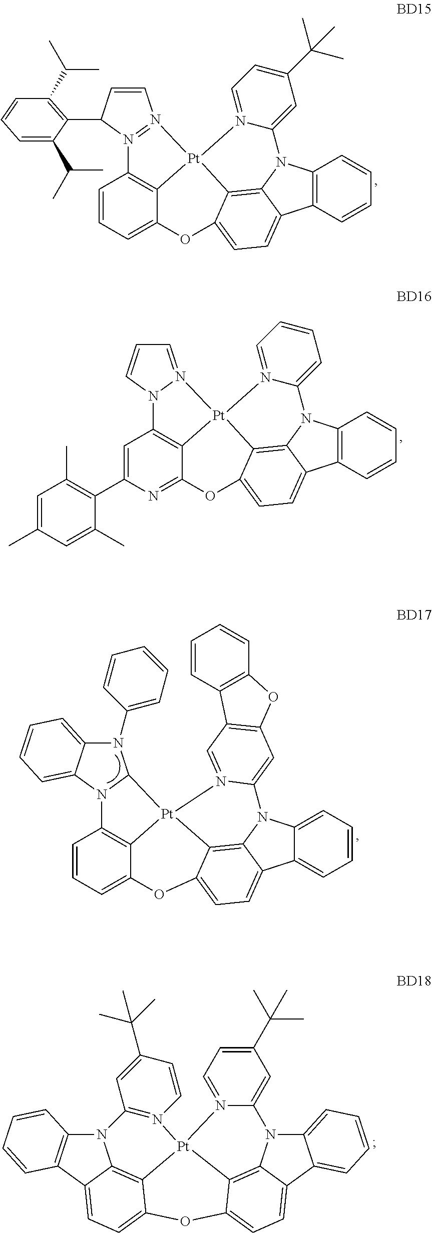
or the metal complex has a structure represented by Pt(Lₐ)(L_{b}), Lₐ and L_{b} are a first ligand and a second ligand coordinated to Pt, respectively, and Lₐ is selected from the group consisting of Lₐ1-1 to Lₐ1-25 and Lₐ2-1 to Lₐ2-6: 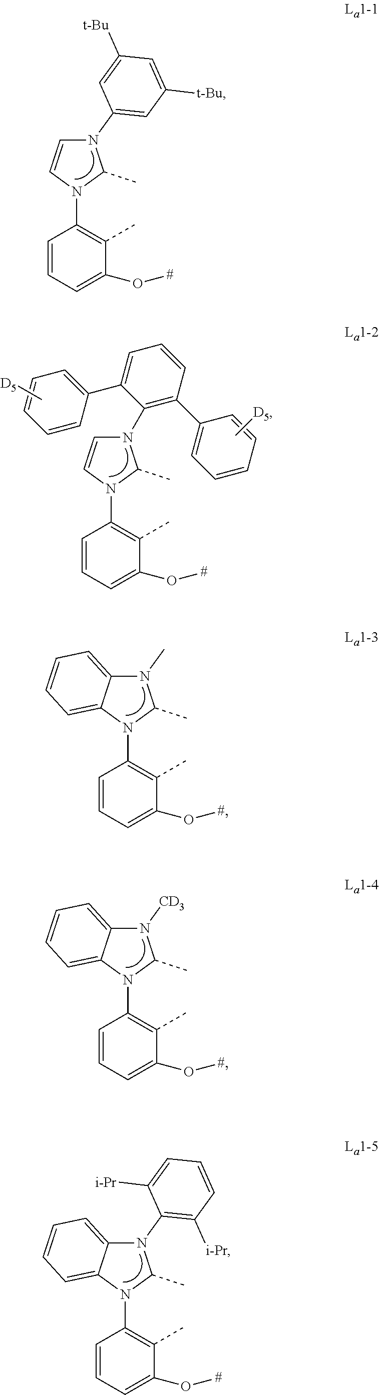 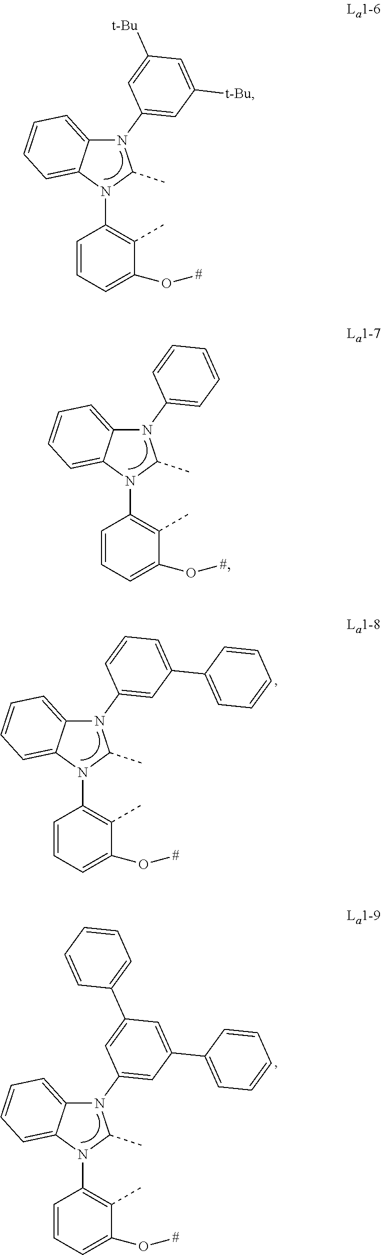 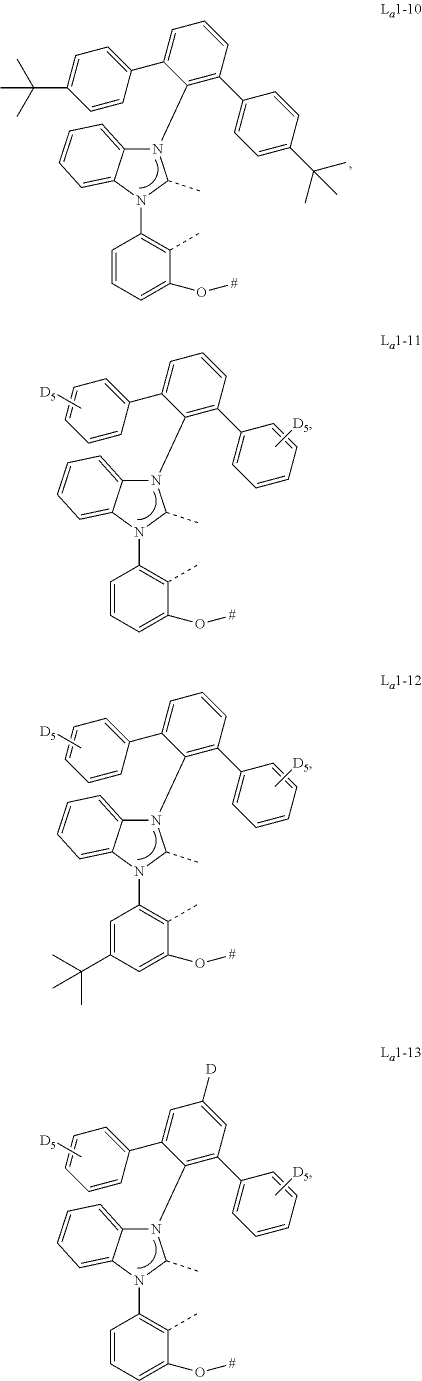 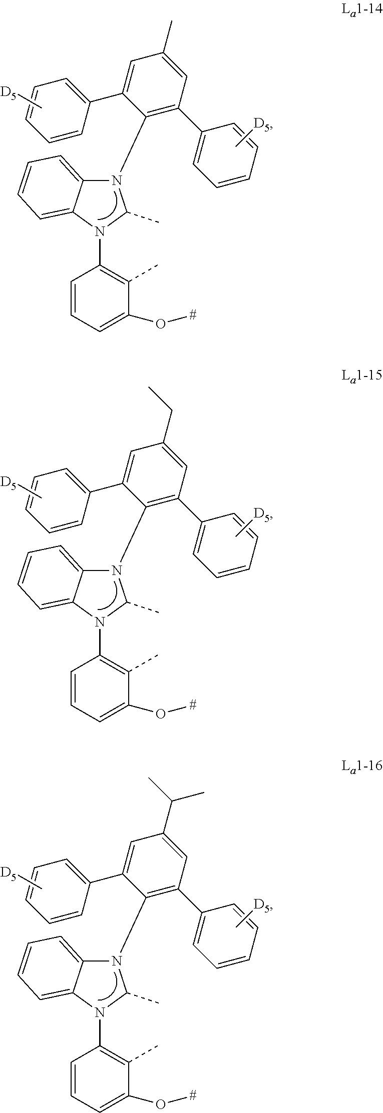 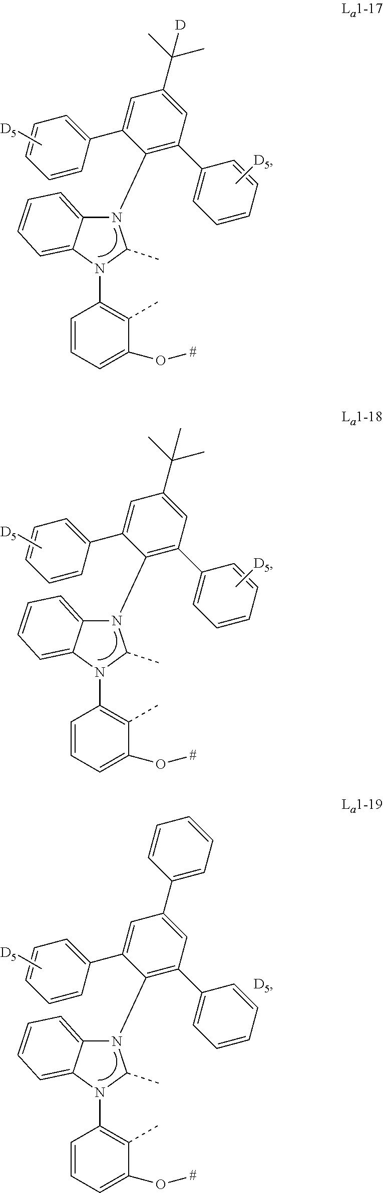 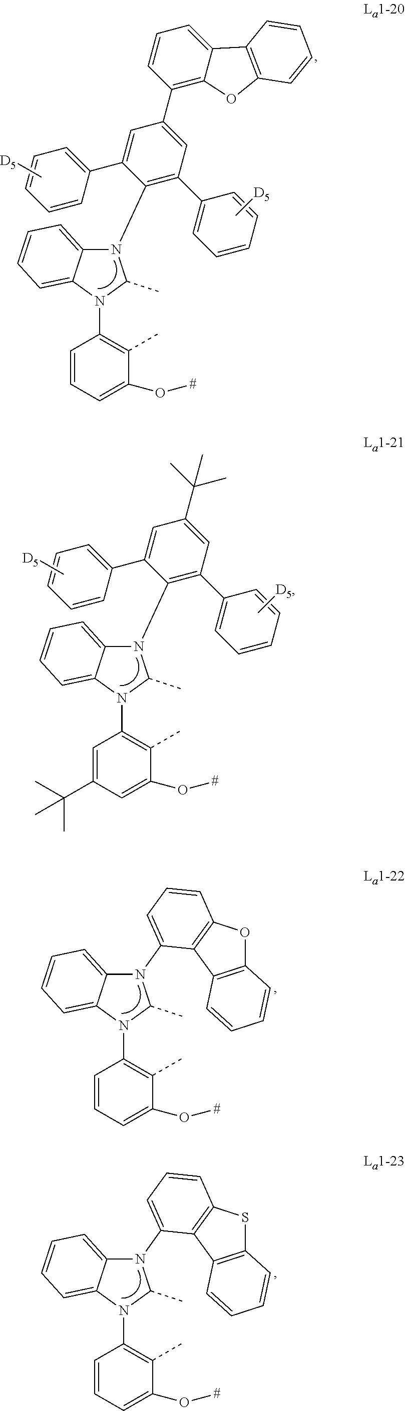 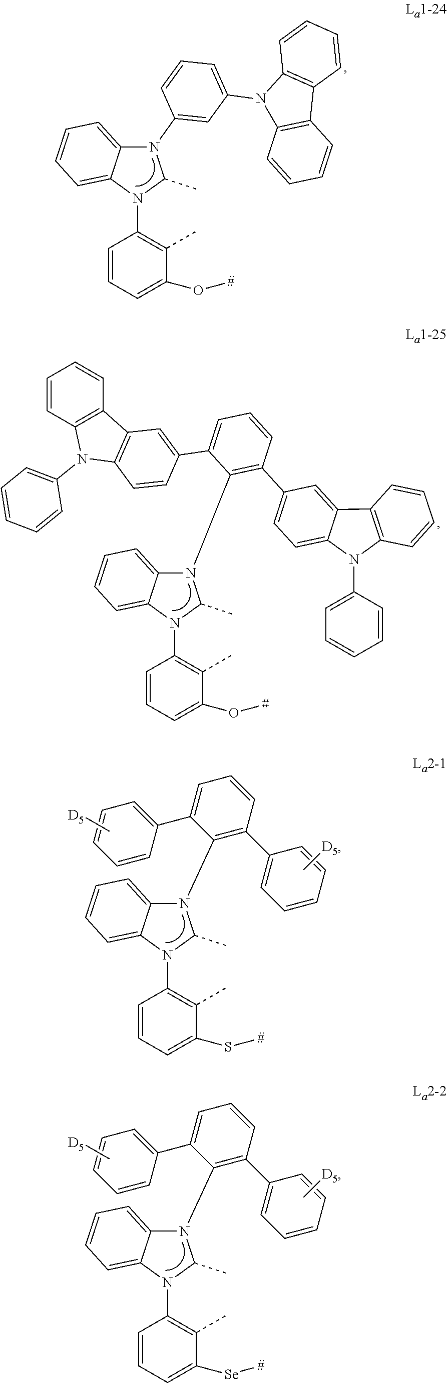 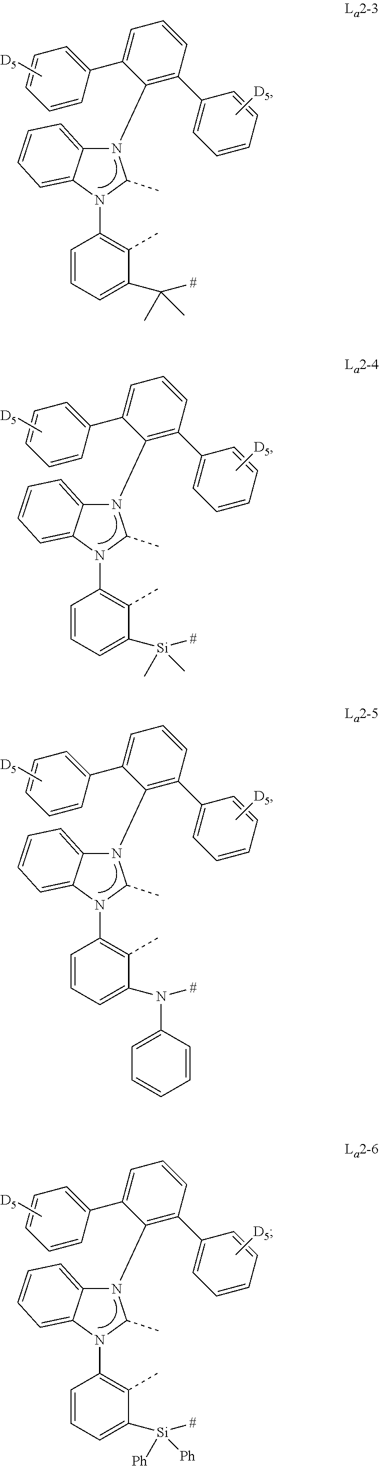
wherein “#” in the structures of Lₐ1-1 to Lₐ1-25 and Lₐ2-1 to Lₐ2-6 represents a position where L_{b} is joined;
L_{b} is selected from the group consisting of L_{b}1-1 to L_{b}1-8 and L_{b}2-1 to L_{b}2-22: [chemical structure] 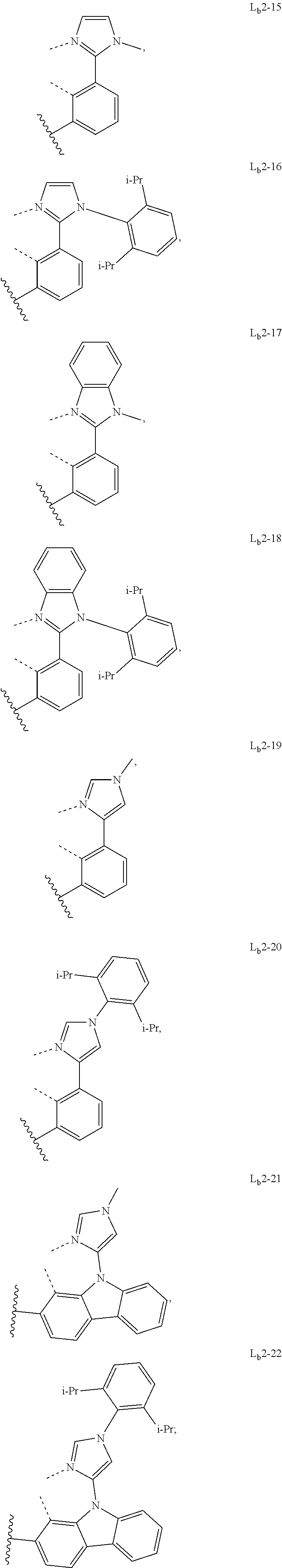
wherein “ [symbol] ” in the structures of L_{b}1-1 to L_{b}1-8 and L_{b}2-1 to L_{b}2-22 represents a position where Lₐ is joined,
preferably, the metal complex is selected from the group consisting of Pt1 to Pt81, wherein Pt1 to Pt81 each have the structure represented by Pt(Lₐ)(L_{b}), and Lₐ and L_{b} are selected from the structures shown in the following table, respectively:

| Metal | | | Metal | | |
|---|---|---|---|---|---|
| Complex No. | Lₐ | L_{b} | Complex No. | Lₐ | L_{b} |
| Pt1 | Lₐ1-6 | L_{b}1-1 | Pt2 | Lₐ1-6 | L_{b}1-2 |
| Pt3 | Lₐ1-6 | L_{b}1-3 | Pt4 | Lₐ1-6 | L_{b}1-4 |
| Pt5 | Lₐ1-6 | L_{b}1-5 | Pt6 | Lₐ1-6 | L_{b}1-6 |
| Pt7 | Lₐ1-6 | L_{b}1-7 | Pt8 | Lₐ1-6 | L_{b}1-8 |
| Pt9 | Lₐ1-11 | L_{b}1-1 | Pt10 | Lₐ1-11 | L_{b}1-2 |
| Pt11 | Lₐ1-11 | L_{b}1-3 | Pt12 | Lₐ1-11 | L_{b}1-4 |
| Pt13 | Lₐ1-11 | L_{b}1-5 | Pt14 | Lₐ1-11 | L_{b}1-6 |
| Pt15 | Lₐ1-11 | L_{b}1-7 | Pt16 | Lₐ1-11 | L_{b}1-8 |
| Pt17 | Lₐ1-12 | L_{b}1-1 | Pt18 | Lₐ1-12 | L_{b}1-2 |
| Pt19 | Lₐ1-12 | L_{b}1-3 | Pt20 | Lₐ1-12 | L_{b}1-4 |
| Pt21 | Lₐ1-12 | L_{b}1-5 | Pt22 | Lₐ1-12 | L_{b}1-6 |
| Pt23 | Lₐ1-12 | L_{b}1-7 | Pt24 | Lₐ1-12 | L_{b}1-8 |
| Pt25 | Lₐ1-18 | L_{b}1-1 | Pt26 | Lₐ1-18 | L_{b}1-2 |
| Pt27 | Lₐ1-18 | L_{b}1-3 | Pt28 | Lₐ1-18 | L_{b}1-4 |
| Pt29 | Lₐ1-18 | L_{b}1-5 | Pt30 | Lₐ1-18 | L_{b}1-6 |
| Pt31 | Lₐ1-18 | L_{b}1-7 | Pt32 | Lₐ1-18 | L_{b}1-8 |
| Pt33 | Lₐ1-18 | L_{b}2-1 | Pt34 | Lₐ1-18 | L_{b}2-2 |
| Pt35 | Lₐ1-18 | L_{b}2-3 | Pt36 | Lₐ1-18 | L_{b}2-4 |
| Pt37 | Lₐ1-18 | L_{b}2-5 | Pt38 | Lₐ1-18 | L_{b}2-6 |
| Pt39 | Lₐ1-18 | L_{b}2-7 | Pt40 | Lₐ1-18 | L_{b}2-8 |
| Pt41 | Lₐ1-18 | L_{b}2-9 | Pt42 | Lₐ1-18 | L_{b}2-10 |
| Pt43 | Lₐ1-18 | L_{b}2-11 | Pt44 | Lₐ1-18 | L_{b}2-12 |
| Pt45 | Lₐ1-18 | L_{b}2-13 | Pt46 | Lₐ1-18 | L_{b}2-14 |
| Pt47 | Lₐ1-18 | L_{b}2-15 | Pt48 | Lₐ1-18 | L_{b}2-16 |
| Pt49 | Lₐ1-18 | L_{b}2-17 | Pt50 | Lₐ1-18 | L_{b}2-18 |
| Pt51 | Lₐ1-18 | L_{b}2-19 | Pt52 | Lₐ1-18 | L_{b}2-20 |
| Pt53 | Lₐ1-18 | L_{b}2-21 | Pt54 | Lₐ1-18 | L_{b}2-22 |
| Pt55 | Lₐ1-1 | L_{b}1-3 | Pt56 | Lₐ1-2 | L_{b}1-3 |
| Pt57 | Lₐ1-3 | L_{b}1-3 | Pt58 | Lₐ1-4 | L_{b}1-3 |
| Pt59 | Lₐ1-5 | L_{b}1-3 | Pt60 | Lₐ1-7 | L_{b}1-3 |
| Pt61 | Lₐ1-8 | L_{b}1-3 | Pt62 | Lₐ1-9 | L_{b}1-3 |
| Pt63 | Lₐ1-10 | L_{b}1-3 | Pt64 | Lₐ1-13 | L_{b}1-3 |
| Pt65 | Lₐ1-14 | L_{b}1-3 | Pt66 | Lₐ1-15 | L_{b}1-3 |
| Pt67 | Lₐ1-16 | L_{b}1-3 | Pt68 | Lₐ1-17 | L_{b}1-3 |
| Pt69 | Lₐ1-19 | L_{b}1-3 | Pt70 | Lₐ1-20 | L_{b}1-3 |
| Pt71 | Lₐ1-21 | L_{b}1-3 | Pt72 | Lₐ1-22 | L_{b}1-3 |
| Pt73 | Lₐ1-23 | L_{b}1-3 | Pt74 | Lₐ1-24 | L_{b}1-3 |
| Pt75 | Lₐ1-25 | L_{b}1-3 | Pt76 | Lₐ2-1 | L_{b}1-3 |
| Pt77 | Lₐ2-2 | L_{b}1-3 | Pt78 | Lₐ2-3 | L_{b}1-3 |
| Pt79 | Lₐ2-4 | L_{b}1-3 | Pt80 | Lₐ2-5 | L_{b}1-3 |
| Pt81 | Lₐ2-6 | L_{b}1-3 | | | |

19. The organic electroluminescent device according to claim 1, wherein the organic layer is an emissive layer and the metal complex is a phosphorescent sensitizer;
preferably, the emissive layer comprises a first host compound and a second host compound;
more preferably, the first host compound and the second host compound are each independently selected from a compound comprising at least one chemical group selected from the group consisting of: benzene, pyridine, pyrimidine, triazine, carbazole, azacarbazole, indolocarbazole, dibenzothiophene, aza-dibenzothiophene, dibenzofuran, azadibenzofuran, dibenzoselenophene, triphenylene, azatriphenylene, fluorene, silafluorene, naphthalene, quinoline, isoquinoline, quinazoline, quinoxaline, phenanthrene, azaphenanthrene, and combinations thereof.

20. A display apparatus, comprising the organic electroluminescent device according to claim 1.
